(19) United States
(12) Patent Application Publication
(10) Pub. No.: US 2023/0264474 A1
(43) Pub. Date: Aug. 24, 2023

(54) INKJET PRINT HEAD AND MANUFACTURING METHOD THEREFOR

(71) Applicant: ROHM CO., LTD., Kyoto-shi, Kyoto (JP)

(72) Inventors: Eitaro KUROKAWA, Kyoto-shi, Kyoto (JP); Osamu MATSUSHIMA, Kyoto-shi, Kyoto (JP); Noriyuki SHIMOJI, Kyoto-shi, Kyoto (JP); Tatsuya SUZUKI, Kyoto-shi, Kyoto (JP); Daisuke NOTSU, Kyoto-shi, Kyoto (JP)

(21) Appl. No.: 18/003,713

(22) PCT Filed: Jul. 6, 2021
(86) PCT No.: PCT/JP2021/025510

§ 371 Date: Dec. 29, 2022

(30) Foreign Application Priority Data
Jul. 14, 2020 (JP) 2020-120871
Jul. 14, 2020 (JP) 2020-120872
Jul. 14, 2020 (JP) 2020-120873
Sep. 18, 2020 (JP) 2020-157862

(51) Int. Cl. B41J 2/14; H10N 30/20; H10N 30/87; H10N 30/88; H10N 30/082; B41J 2/16

(52) U.S. Cl. CPC B41J 2/14233; H10N 30/2047; H10N 30/87; H10N 30/88; H10N 30/082; B41J 2/1607; B41J 2/164

(57) ABSTRACT

An inkjet printing head includes a piezoelectric element that includes a lower electrode disposed on a movable film, a piezoelectric film formed on the lower electrode, and an upper electrode formed on the piezoelectric film, a hydrogen barrier film that covers, in a front surface of the piezoelectric element, at least, entireties of side surfaces of the upper electrode, the piezoelectric film, and the lower electrode, at least a part of an upper surface of the upper electrode, and an upper surface of the lower electrode, a first interlayer insulating film formed on a front surface other than an end surface of the hydrogen barrier film, a second interlayer insulating film formed so as to cover the end surface of the hydrogen barrier film and the first interlayer insulating film, and a wiring that is formed on the second interlayer insulating film and that is connected to the piezoelectric element.

### TECHNICAL FIELD

The present disclosure relates to an inkjet printing head and a method for manufacturing the inkjet printing head.

### BACKGROUND ART

Patent Literature 1 discloses an inkjet printing head. The inkjet printing head of Patent Literature 1 includes an actuator substrate (substrate), having a pressure chamber (pressure generating chamber) as an ink flow passage, a movable film (elastic film), formed on the actuator substrate, and a piezoelectric element, provided above the movable film. The inkjet printing head of Patent Literature 1 further includes a nozzle substrate (nozzle plate), bonded to a lower surface of the actuator substrate and having a nozzle opening (nozzle hole) in communication with the pressure chamber, and a protective substrate, bonded to an upper surface of the actuator substrate and covering the piezoelectric element. The piezoelectric element is constituted of a first electrode film (lower electrode) formed on the movable film, a second electrode film (upper electrode) disposed on the first electrode film, and a piezoelectric layer (piezoelectric film) sandwiched therebetween.

### CITATION LIST

### Patent Literature

Patent Literature 1: Japanese Patent Application Publication No. 2015-91668

### SUMMARY OF INVENTION

### Technical Problem

An object of the present disclosure is to provide an inkjet printing head whose wirings do not easily degrade even when a hydrogen barrier film is corroded by ink and to provide a method for manufacturing the inkjet printing head.

### Solution to Problem

An preferred embodiment of the present disclosure provides an inkjet printing head including an actuator substrate that has an ink flow passage including a pressure chamber, a movable film formation layer that is disposed on the pressure chamber and that includes a movable film defining a top surface portion of the pressure chamber, a piezoelectric element that includes a lower electrode disposed on the movable film, a piezoelectric film formed on the lower electrode, and an upper electrode formed on the piezoelectric film, a hydrogen barrier film that covers, in a front surface of the piezoelectric element, at least, entireties of side surfaces of the upper electrode, the piezoelectric film, and the lower electrode, at least a part of an upper surface of the upper electrode, and an upper surface of the lower electrode, a first interlayer insulating film formed on a front surface other than an end surface of the hydrogen barrier film, a second interlayer insulating film formed so as to cover the end surface of the hydrogen barrier film and the first interlayer insulating film, and a wiring that is formed on the second interlayer insulating film and that is connected to the piezoelectric element.

With the present arrangement, the end surface of the hydrogen barrier film does not contact the wiring, which makes it difficult to degrade the wiring even when the hydrogen barrier film is corroded by ink.

A preferred embodiment of the present disclosure provides a method for manufacturing an inkjet printing head that includes a step of forming a first hydrogen barrier material film, a lower electrode film, a piezoelectric material film, and an upper electrode film in this order on a substrate, a step of patterning the upper electrode film and the piezoelectric material film to an upper electrode pattern to form an upper electrode and a piezoelectric film, a step of patterning the lower electrode film and the first hydrogen barrier material film to a lower electrode pattern to form a lower electrode and a first hydrogen barrier film, a step of forming a second hydrogen barrier material film that covers an entire surface on the substrate and then forming a first interlayer insulation material film on an entire surface on the second hydrogen barrier material film, a step of patterning the second hydrogen barrier material film and the first interlayer insulation material film to a predetermined second hydrogen barrier film pattern to form a second hydrogen barrier film and a first interlayer insulating film, a step of forming a second interlayer insulating film that covers the second hydrogen barrier film and the first interlayer insulating film on the substrate, and a wiring formation step of forming an upper wiring one end of which is connected to the upper electrode and a lower wiring one end of which is connected to the lower electrode on the second interlayer insulating film.

### BRIEF DESCRIPTION OF DRAWINGS

The aforementioned or still other objects, features, and effects of the present invention will be clarified by the following description of preferred embodiments given below with reference to the accompanying drawings.

FIG. 1 is an illustrative plan view for describing an arrangement of an inkjet printing head according to a preferred embodiment of a first disclosure.

FIG. 2 is an illustrative plan view for describing an arrangement of the inkjet printing head according to the preferred embodiment of the first disclosure, and is a plan view from which a protective substrate is omitted.

FIG. 3 is an illustrative partially enlarged plan view showing an A portion of FIG. 1 in enlarged manner.

FIG. 4 is an illustrative partially enlarged plan view showing the A portion of FIG. 1 in enlarged manner, and is a plan view from which a protective substrate is omitted.

FIG. 5 is an illustrative sectional view taken along line V-V in FIG. 3.

FIG. 6 is an illustrative partially enlarged plan view showing a B portion of FIG. 5 in enlarged manner.

FIG. 7 is an illustrative partially enlarged sectional view showing a C portion of FIG. 6 in enlarged manner.

FIG. 8 is an illustrative sectional view taken along line VIII-VIII in FIG. 1.

FIG. 9 is an illustrative sectional view taken along line IX-IX in FIG. 3.

FIG. 10 is an illustrative plan view showing a pattern example of an interlayer insulating film of the inkjet printing head.

FIG. 11 is an illustrative plan view showing a pattern example of a passivation film of the inkjet printing head.

FIG. 12A is a sectional view showing an example of a manufacturing process of the inkjet printing head.

FIG. 12B is a sectional view showing a step subsequent to that of FIG. 12A.

FIG. 12C is a sectional view showing a step subsequent to that of FIG. 12B.

FIG. 12D is a sectional view showing a step subsequent to that of FIG. 12C.

FIG. 12E is a sectional view showing a step subsequent to that of FIG. 12D.

FIG. 12F is a sectional view showing a step subsequent to that of FIG. 12E.

FIG. 12G is a sectional view showing a step subsequent to that of FIG. 12F.

FIG. 12H is a sectional view showing a step subsequent to that of FIG. 12G.

FIG. 12I is a sectional view showing a step subsequent to that of FIG. 12H.

FIG. 12J is a sectional view showing a step subsequent to that of FIG. 12I.

FIG. 12K is a sectional view showing a step subsequent to that of FIG. 12J.

FIG. 12L is a sectional view showing a step subsequent to that of FIG. 12K.

FIG. 12M is a sectional view showing a step subsequent to that of FIG. 12L.

FIG. 12N is a sectional view showing a step subsequent to that of FIG. 12M.

FIG. 12O is a sectional view showing a step subsequent to that of FIG. 12N.

FIG. 12P is a sectional view showing a step subsequent to that of FIG. 12O.

FIG. 12Q is a sectional view showing a step subsequent to that of FIG. 12P.

FIG. 12R is a sectional view showing a step subsequent to that of FIG. 12Q.

FIG. 12S is a sectional view showing a step subsequent to that of FIG. 12R.

FIG. 12T is a sectional view showing a step subsequent to that of FIG. 12S.

FIG. 12U is a sectional view showing a step subsequent to that of FIG. 12T.

FIG. 12V is a sectional view showing a step subsequent to that of FIG. 12U.

FIG. 12W is a sectional view showing a step subsequent to that of FIG. 12V.

FIG. 12X is a sectional view showing a step subsequent to that of FIG. 12W.

FIG. 12Y is a sectional view showing a step subsequent to that of FIG. 12X.

FIG. 12Z1 is a sectional view showing a step subsequent to that of FIG. 12Y.

FIG. 12Z2 is a sectional view showing a step subsequent to that of FIG. 12Z1.

FIG. 12Z3 is a sectional view showing a step subsequent to that of FIG. 12Z2.

FIG. 12Z4 is a sectional view showing a step subsequent to that of FIG. 12Z3.

FIG. 12Z5 is a sectional view showing a step subsequent to that of FIG. 12Z4.

FIG. 13 is a plan view showing a semiconductor wafer serving as an original substrate of an actuator substrate.

FIG. 14A is a sectional view showing a part of a manufacturing process of a comparative example.

FIG. 14B is a sectional view showing a step subsequent to that of FIG. 14A.

FIG. 14C is a sectional view showing a step subsequent to that of FIG. 14B.

FIG. 14D is a sectional view showing a step subsequent to that of FIG. 14C.

FIG. 15 is an illustrative partially enlarged sectional view showing a D portion of FIG. 14D in enlarged manner.

FIG. 16 is an illustrative plan view for describing an arrangement of an inkjet printing head according to a preferred embodiment of the fourth disclosure.

FIG. 17 is an illustrative partially enlarged plan view showing an A portion of FIG. 16 in enlarged manner, and is a plan view that includes a protective substrate.

FIG. 18 is an illustrative partially enlarged plan view showing the A portion of FIG. 16 in enlarged manner, and is a plan view from which the protective substrate is omitted.

FIG. 19 is an illustrative sectional view taken along line XIX-XIX in FIG. 17.

FIG. 20 is an enlarged sectional view showing a nozzle hole of FIG. 19 in enlarged manner.

FIG. 21 is a plan view as viewed from arrow line XXI-XXI of FIG. 20.

FIG. 22 is an illustrative sectional view taken along line XXII-XXII in FIG. 20.

FIG. 23 is an illustrative sectional view taken along line XXIII-XXIII in FIG. 17.

FIG. 24 is an illustrative sectional view taken along line XXIV-XXIV in FIG. 17.

FIG. 25 is an illustrative plan view showing a pattern example of an insulating film of the inkjet printing head, and is a plan view corresponding to FIG. 17.

FIG. 26 is an illustrative plan view showing a pattern example of a passivation film of the inkjet printing head, and is a plan view corresponding to FIG. 17.

FIG. 27 is a bottom view of a region shown in FIG. 17 of the protective substrate.

FIG. 28 is a plan view of a semiconductor wafer serving as an original substrate of an actuator substrate.

FIG. 29A is a sectional view showing an example of a manufacturing process of the inkjet printing head.

FIG. 29B is a sectional view showing a step subsequent to that of FIG. 29A.

FIG. 29C is a sectional view showing a step subsequent to that of FIG. 29B.

FIG. 29D is a sectional view showing a step subsequent to that of FIG. 29C.

FIG. 29E is a sectional view showing a step subsequent to that of FIG. 29D.

FIG. 29F is a sectional view showing a step subsequent to that of FIG. 29E.

FIG. 29G is a sectional view showing a step subsequent to that of FIG. 29F.

FIG. 29H is a sectional view showing a step subsequent to that of FIG. 29G.

FIG. 29I is a sectional view showing a step subsequent to that of FIG. 29H.

FIG. 29J is a sectional view showing a step subsequent to that of FIG. 29I.

FIG. 29K is a sectional view showing a step subsequent to that of FIG. 29J.

FIG. 29L is a sectional view showing a step subsequent to that of FIG. 29K.

FIG. 29M is a sectional view showing a step subsequent to that of FIG. 29L.

FIG. 30A is a sectional view schematically showing a manufacturing process of a nozzle substrate aggregate.

FIG. 30B is a sectional view showing a step subsequent to that of FIG. 30A.

FIG. 30C is a sectional view showing a step subsequent to that of FIG. 30B.

FIG. 30D is a sectional view showing a step subsequent to that of FIG. 30C.

FIG. 30E is a sectional view showing a step subsequent to that of FIG. 30D.

FIG. 31 is a sectional view showing a modification example of a concave portion of a nozzle hole.

### DESCRIPTION OF PREFERRED EMBODIMENTS

### [1] With Respect to First Disclosure

### Description of Preferred Embodiment of First Disclosure

A preferred embodiment of the first disclosure provides an inkjet printing head including an actuator substrate that has an ink flow passage including a pressure chamber, a movable film formation layer that is disposed on the pressure chamber and that includes a movable film defining a top surface portion of the pressure chamber, a piezoelectric element that includes a lower electrode disposed on the movable film, a piezoelectric film formed on the lower electrode, and an upper electrode formed on the piezoelectric film, a hydrogen barrier film that covers, in a front surface of the piezoelectric element, at least, entireties of side surfaces of the upper electrode, the piezoelectric film, and the lower electrode, at least a part of an upper surface of the upper electrode, and an upper surface of the lower electrode, a first interlayer insulating film formed on a front surface other than an end surface of the hydrogen barrier film, a second interlayer insulating film formed so as to cover the end surface of the hydrogen barrier film and the first interlayer insulating film, and a wiring that is formed on the second interlayer insulating film and that is connected to the piezoelectric element.

With the present arrangement, the end surface of the hydrogen barrier film does not contact the wiring, which makes it difficult to degrade the wiring even when the hydrogen barrier film is corroded by ink.

In a preferred embodiment of the first disclosure, the lower electrode includes a main electrode portion that contacts a lower surface of the piezoelectric film and an extension portion that extends from the main electrode portion to a region outside the piezoelectric film.

In a preferred embodiment of the first disclosure, the wiring includes an upper wiring connected to the upper electrode and a lower wiring connected to the lower electrode.

In a preferred embodiment of the first disclosure, an upper contact hole that exposes a part of the upper surface of the upper electrode is formed in the hydrogen barrier film formed on the upper surface of the upper electrode, the first interlayer insulating film, and the second interlayer insulating film, and an end portion of the upper wiring is connected to the upper electrode via the upper contact hole, and a lower contact hole that exposes a part of the upper surface of the lower electrode is formed in the hydrogen barrier film formed on the upper surface of the lower electrode, the first interlayer insulating film, and the second interlayer insulating film, and an end portion of the lower wiring is connected to the lower electrode via the lower contact hole.

In a preferred embodiment of the first disclosure, the hydrogen barrier film is also formed on a lower surface of the lower electrode.

In a preferred embodiment of the first disclosure, the inkjet printing head further includes a passivation film that is formed on the second interlayer insulating film and that covers the wiring.

In a preferred embodiment of the first disclosure, the top surface portion of the pressure chamber has a rectangular shape that is long in a predetermined first direction in a plan view as viewed from a normal direction with respect to a principal surface of the movable film, and the upper electrode and the piezoelectric film each have a rectangular shape that is long in the first direction, and each have a peripheral edge receded further toward the interior of the pressure chamber than the movable film.

In a preferred embodiment of the first disclosure, the lower electrode has a rectangular shape that is long in the first direction in the plan view, and a length in a longitudinal direction of the lower electrode is longer than a length in a longitudinal direction of the piezoelectric film, and is shorter than a length in a longitudinal direction of the movable film, and both end edges of the lower electrode are disposed at inner sides at intervals respectively from the respective corresponding end edges of the movable film, and a length in a lateral direction of the lower electrode is longer than a length in a lateral direction of the piezoelectric film, and is longer than a length in a lateral direction of the movable film, and both side edges of the lower electrode are disposed at outer sides at intervals respectively from the respective corresponding side edges of the movable film.

In a preferred embodiment of the first disclosure, a plurality of the pressure chambers are provided and the piezoelectric element is provided for each pressure chamber, and in the plan view, the actuator substrate has a plurality of pressure chamber columns formed therein at intervals in the first direction, with each pressure chamber column being constituted of a plurality of the pressure chambers provided at intervals in a second direction orthogonal to the first direction.

In a preferred embodiment of the first disclosure, the inkjet printing head further includes a nozzle substrate that is bonded to a front surface of the actuator substrate at an opposite side of a front surface on the movable film side, that defines a bottom surface portion of the pressure chamber, and that has a nozzle hole in communication with the pressure chamber, and a protective substrate that is disposed on a side opposite to the nozzle substrate with respect to the actuator substrate and that is joined to the actuator substrate so as to cover the piezoelectric element, and, in the inkjet printing head, the protective substrate has a housing concave that is opened toward the actuator substrate and that houses the piezoelectric element and an ink passage in communication with the ink flow passage.

A preferred embodiment of the first disclosure provides a method for manufacturing an inkjet printing head that includes a step of forming a first hydrogen barrier material film, a lower electrode film, a piezoelectric material film, and an upper electrode film in this order on a substrate, a step of patterning the upper electrode film and the piezoelectric material film to an upper electrode pattern to form an upper electrode and a piezoelectric film, a step of patterning the lower electrode film and the first hydrogen barrier material film to a lower electrode pattern to form a lower electrode and a first hydrogen barrier film, a step of forming a second hydrogen barrier material film that covers an entire surface on the substrate and then forming a first interlayer insulation material film on an entire surface on the second hydrogen barrier material film, a step of patterning the second hydrogen barrier material film and the first interlayer insulation material film to a predetermined second hydrogen barrier film pattern to form a second hydrogen barrier film and a first interlayer insulating film, a step of forming a second interlayer insulating film that covers the second hydrogen barrier film and the first interlayer insulating film on the substrate, and a wiring formation step of forming an upper wiring one end of which is connected to the upper electrode and a lower wiring one end of which is connected to the lower electrode on the second interlayer insulating film.

In a preferred embodiment of the first disclosure, the wiring formation step includes a step of forming an upper contact hole that exposes a part of an upper surface of the upper electrode and a lower contact hole that exposes a part of an upper surface of the lower electrode, the upper and lower contact holes penetrating continuously through the second interlayer insulating film, the first interlayer insulating film, and the second hydrogen barrier film, a step of forming a wiring film on the second interlayer insulating film including an inside of the upper contact hole and the lower contact hole, and a step of patterning the wiring film to form the upper wiring and the lower wiring.

In a preferred embodiment of the first disclosure, the method for manufacturing an inkjet printing head further includes a step of, after completing the wiring formation step, forming a passivation film that covers the upper wiring and the lower wiring on a front surface of the second interlayer insulating film.

### Detailed Description of Preferred Embodiment of First Disclosure

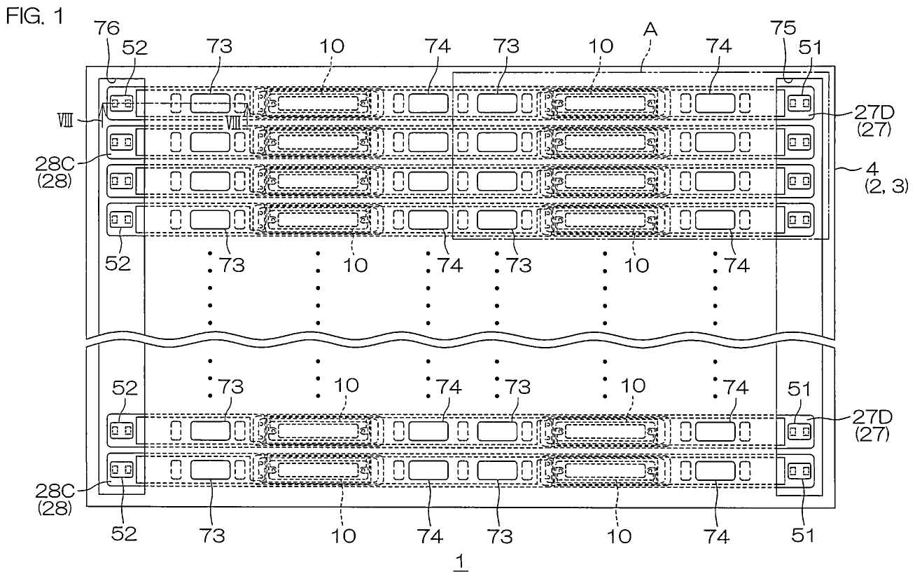

A preferred embodiment of the first disclosure will be hereinafter described in detail with reference to FIG. 1 to FIG. 15.

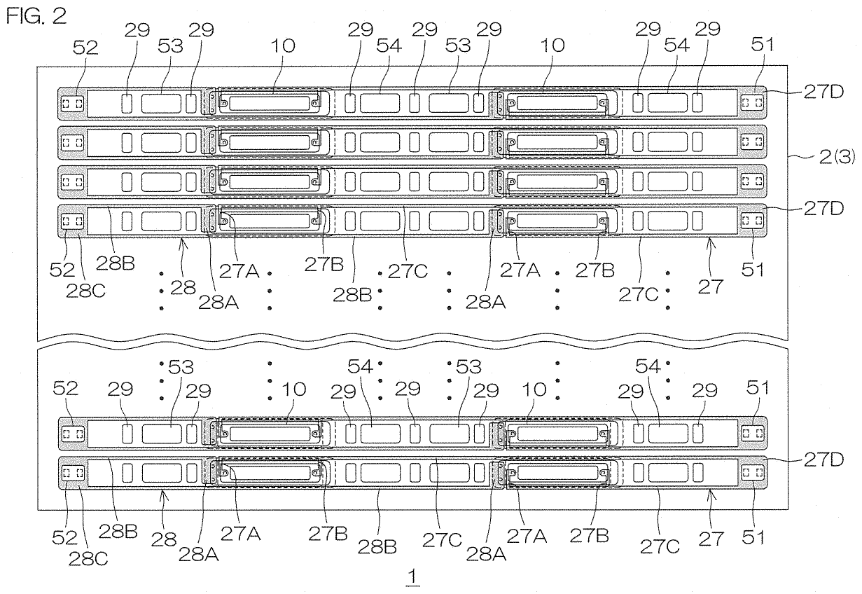

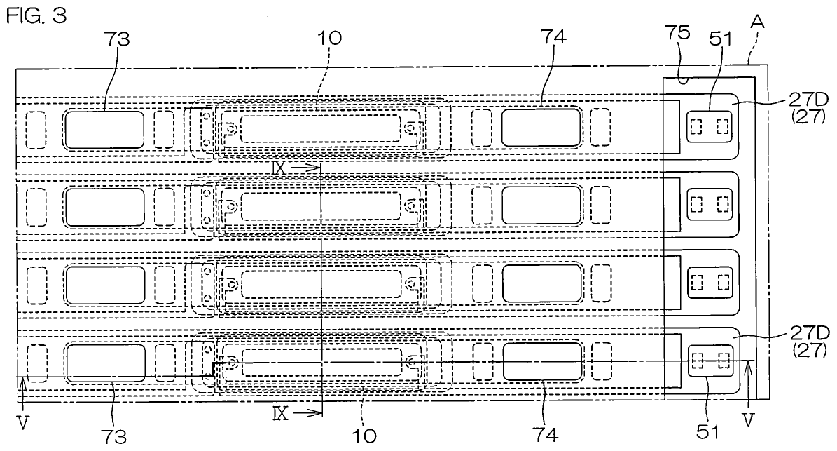

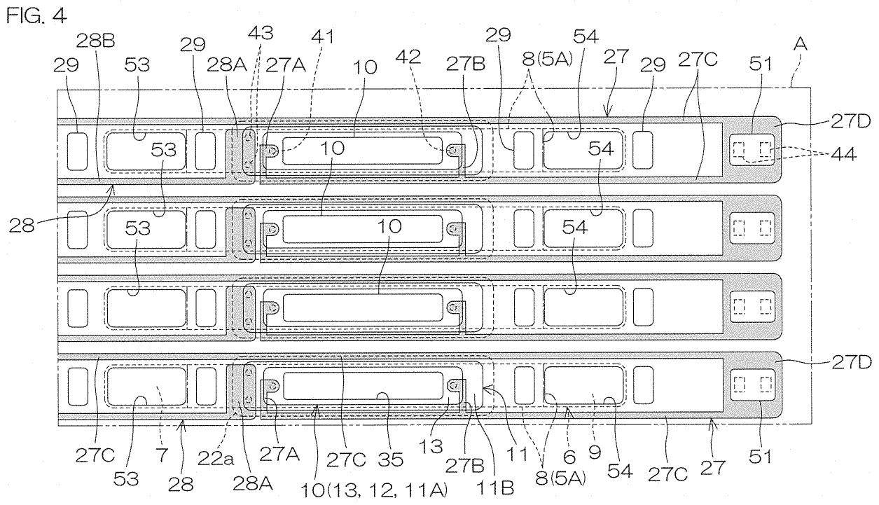

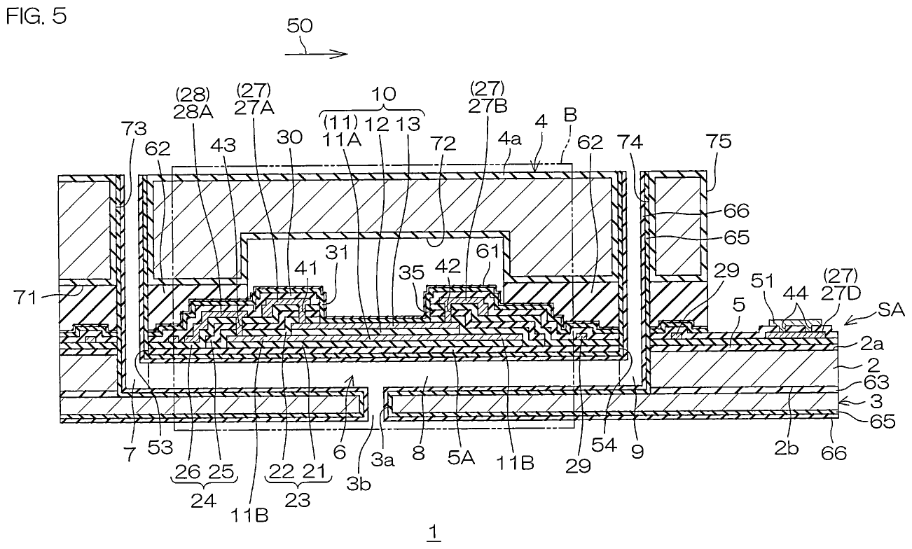

FIG. 1 is an illustrative plan view for describing an arrangement of an inkjet printing head according to the preferred embodiment of the first disclosure. FIG. 2 is an illustrative plan view for describing an arrangement of the inkjet printing head according to the preferred embodiment of the first disclosure, and is a plan view from which a protective substrate is omitted. FIG. 3 is an illustrative partially enlarged plan view showing an A portion of FIG. 1 in enlarged manner. FIG. 4 is an illustrative partially enlarged plan view showing the A portion of FIG. 1 in enlarged manner, and is a plan view from which a protective substrate is omitted.

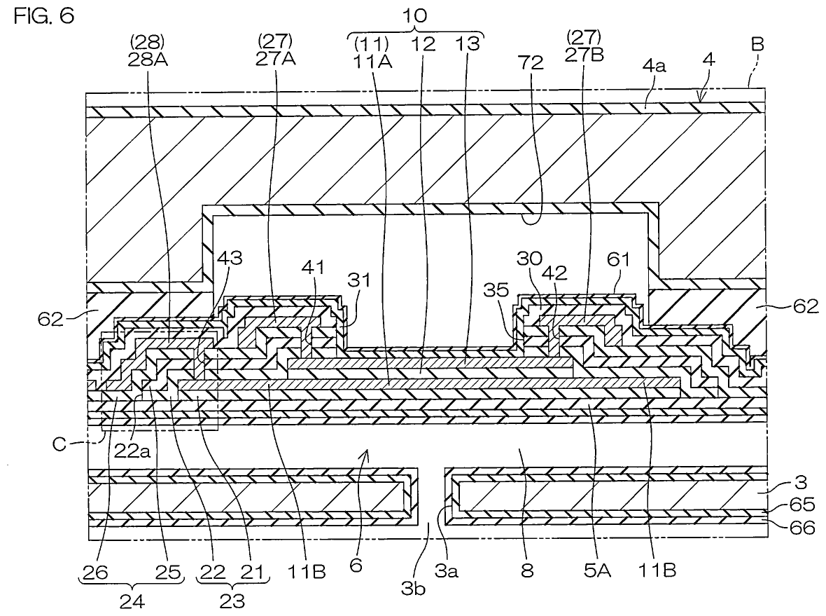

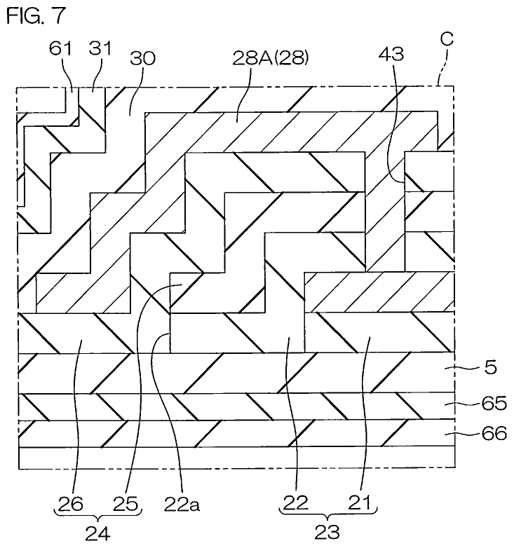

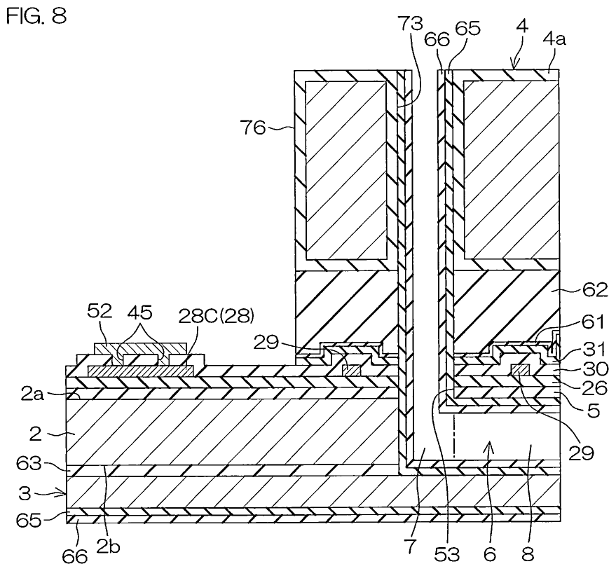

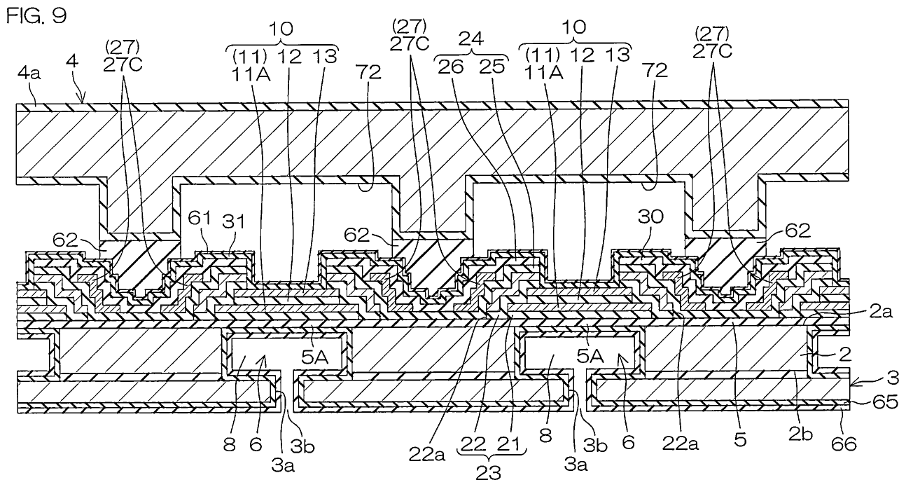

FIG. 5 is an illustrative sectional view taken along line V-V in FIG. 3. FIG. 6 is an illustrative partially enlarged plan view showing a B portion of FIG. 5 in enlarged manner. FIG. 7 is an illustrative partially enlarged sectional view showing a C portion of FIG. 6 in enlarged manner. FIG. 8 is an illustrative sectional view taken along line VIII-VIII in FIG. 1. FIG. 9 is an illustrative sectional view taken along line IX-IX in FIG. 3.

An arrangement of an inkjet printing head 1 will be schematically described with reference to FIG. 5 to FIG. 7.

The inkjet printing head 1 includes a substrate assembly SA, which includes an actuator substrate 2 and a piezoelectric element 10, a nozzle substrate 3, and a protective substrate 4.

The actuator substrate 2 is constituted, for example, of a silicon (Si) substrate. In the present preferred embodiment, the actuator substrate 2 has a thickness of approximately 70 μm. A movable film formation layer 5 is laminated on a front surface 2a of the actuator substrate 2. In the actuator substrate 2, an ink flow passage 6 in which ink is circulated. In the present preferred embodiment, the ink flow passage 6 is formed so as to penetrate through the actuator substrate 2. The ink flow passage 6 is formed to be elongate along an ink flow direction 50 indicated by an arrow in FIG. 5.

The ink flow passage 6 is constituted of an ink inflow portion 7, a pressure chamber 8, and an ink outflow portion 9. The ink inflow portion 7 is disposed at an upstream side end portion (a left end portion in FIG. 5) in the ink flow direction 50, and the ink outflow portion 9 is disposed at a downstream side end portion (a right end portion in FIG. 5) in the ink flow direction 50. The pressure chamber 8 is disposed between the ink inflow portion 7 and the ink outflow portion 9, and is in communication with the ink inflow portion 7 and with the ink outflow portion 9. The boundary between the ink inflow portion 7 and the pressure chamber 8 and the boundary between the pressure chamber 8 and the ink outflow portion 9 are each indicated by an alternate long and short dashed line in FIG. 5.

The nozzle substrate 3 is constituted, for example, of a silicon (Si) substrate. In the present preferred embodiment, the nozzle substrate 3 has a thickness of approximately 50 μm. The nozzle substrate 3 is adhered to a rear surface 2b of the actuator substrate 2 via an adhesive layer 63. The nozzle substrate 3, together with the actuator substrate 2 and the movable film formation layer 5, defines the ink flow passage 6. More specifically, the nozzle substrate 3 defines a bottom surface portion of the ink flow passage 6.

A nozzle hole 3a in communication with the pressure chamber 8 is formed in the nozzle substrate 3. The nozzle hole 3a penetrates through the nozzle substrate 3, and has an ink discharge port 3b on a side opposite to the pressure chamber 8. When a volume change occurs in a pressure chamber 8, the ink retained in the pressure chamber 8 passes through the nozzle hole 3a, and is discharged from the ink discharge port 3b.

A top roof portion of the ink flow passage 6 in the movable film formation layer 5 constitutes a movable film 5A. The movable film 5A (movable film formation layer 5) is constituted, for example, of a silicon oxide (SiO₂) film formed on the actuator substrate 2. The movable film 5A (movable film formation layer 5) may be constituted, for example, of a laminated film of a silicon (Si) film formed on the actuator substrate 2, a silicon oxide (SiO₂) film formed on the silicon film, and a silicon nitride (SiN) film formed on the silicon oxide film. In the present specification, the movable film 5A refers to a top roof portion of the movable film formation layer 5 that defines the top surface portion of the pressure chamber 8. Therefore, portions of the movable film formation layer 5 besides the top roof portion of the pressure chamber 8 do not constitute the movable film 5A.

The movable film 5A has a thickness of, for example, approximately 0.4 μm to 2 μm. If the movable film 5A is constituted of a silicon oxide film, a thickness of the silicon oxide film may be approximately 1.5 μm. If the movable film 5A is constituted of a laminated film of a silicon oxide film and a silicon nitride film, a thickness of each of the silicon oxide film and the silicon nitride film may be approximately 0.7 μm.

The pressure chamber 8 is defined by the movable film 5A, the actuator substrate 2, and the nozzle substrate 3, and is formed to a substantially rectangular parallelepiped shape in the present preferred embodiment. The pressure chamber 8 has a length, for example, of approximately 700 μm and a width, for example, of approximately 54 μm. The ink inflow portion 7 is in communication with one end portion in a longitudinal direction of the pressure chamber 8, and the ink outflow portion 9 is in communication with the other end portion in the longitudinal direction of the pressure chamber 8.

A first hydrogen barrier film 21 is formed on a front surface of the movable film 5A. The first hydrogen barrier film 21 is constituted, for example, of Al₂O₃ (alumina). The first hydrogen barrier film 21 has a thickness of approximately 50 nm to 100 nm. In the present preferred embodiment, the thickness of the first hydrogen barrier film 21 is approximately 80 nm. The piezoelectric element 10 is disposed on a front surface of the first hydrogen barrier film 21 at a position above the movable film 5A. The piezoelectric element 10 includes a lower electrode 11 formed on the first hydrogen barrier film 21, a piezoelectric film 12 formed on the lower electrode 11, and an upper electrode 13 formed on the piezoelectric film 12. In other words, the piezoelectric element 10 is arranged by sandwiching the piezoelectric film 12 from above and below by the upper electrode 13 and the lower electrode 11. The piezoelectric element 10 has rectangular shapes that are elongate in the ink flow direction 50 in a plan view.

The upper electrode 13 has, for example, a two-layer structure with an IrO₂ (iridium oxide) film and an Ir (iridium) film being laminated successively from the piezoelectric film 12 side. The upper electrode 13 may be constituted, for example, of a single film of platinum (Pt). The upper electrode 13 has a thickness, for example, of approximately 80 nm.

As the piezoelectric film 12, for example, a PZT (PbZrₓTi₁₋ₓO₃: lead zirconate titanate) film formed by a sol-gel method or a sputtering method may be applied. Such a piezoelectric film 12 is constituted of a sintered body of a metal oxide crystal. The piezoelectric film 12 is formed to be of the same shape as the upper electrode 13 in a plan view. The piezoelectric film 12 has a thickness, for example, of approximately 2 μm.

The first hydrogen barrier film 21 mentioned above prevents degradation of characteristics of the piezoelectric film 12 due to hydrogen reduction. Also, the first hydrogen barrier film 21 prevents the escaping of metal elements (Pb, Zr, and Ti in the case where the piezoelectric film 12 is PZT) from the piezoelectric film 12, keeps the piezoelectric characteristics of the piezoelectric film 12 in a satisfactory state, and prevents the metal from diffusing into the movable film 5A when the piezoelectric film 12 is formed.

The lower electrode 11 has, for example, a two-layer structure with a TiO₂ (titanium oxide) film and a Pt (platinum) film being laminated successively from the first hydrogen barrier film 21 side. Besides this, the lower electrode 11 may be formed of a single film that is an Au (gold) film, a Cr (chromium) layer, or a Ni (nickel) layer, etc. The lower electrode 11 has a main electrode portion 11A in contact with a lower surface of the piezoelectric film 12, and an extension portion 11B extending to a region outside the piezoelectric film 12. The lower electrode 11 has a thickness, for example, of approximately 200 nm.

A second hydrogen barrier film 22 is formed on the first hydrogen barrier film 21 so as to cover an exposed surface of the piezoelectric element 10. The second hydrogen barrier film 22 is constituted, for example, of Al₂O₃ (alumina). The second hydrogen barrier film 22 has a thickness, for example, of approximately 50 nm to 100 nm. In the present preferred embodiment, the thickness of the second hydrogen barrier film 22 is, for example, approximately 80 nm.

The second hydrogen barrier film 22 is provided to prevent degradation of characteristics of the piezoelectric film 12 due to hydrogen reduction. The first hydrogen barrier film 21 and the second hydrogen barrier film 22 constitutes a hydrogen barrier film 23 covering the entirety of the piezoelectric element 10. However, as described later, the hydrogen barrier film 23 has an opening 35, and contact holes 41, 42, and 43, which are formed to expose a part of the piezoelectric element 10.

An interlayer insulating film 24 is formed on the movable film formation layer 5 so as to cover an exposed surface of the movable film formation layer 5 and an exposed surface of the hydrogen barrier film 23. The interlayer insulating film 24 is constituted of a first interlayer insulating film 25 and a second interlayer insulating film 26.

The first interlayer insulating film 25 is formed on an upper surface of the hydrogen barrier film 23 (in more detail, on an upper surface of the second hydrogen barrier film 22). In other words, the first interlayer insulating film 25 is formed of the same pattern as the second hydrogen barrier film 22.

The second interlayer insulating film 26 is formed on the movable film formation layer 5 so as to cover the exposed surface of the movable film formation layer 5 and an exposed surface of the first interlayer insulating film 25. Therefore, in a region in which the hydrogen barrier film 23 is not present, the first interlayer insulating film 25 is not formed, and only the second interlayer insulating film 26 of the interlayer insulating film 24 is formed.

The first interlayer insulating film 25 and the second interlayer insulating film 26 are each constituted, for example, of a SiO₂ film formed by using TEOS (tetraethoxysilane) as a raw material. Each of the first and second interlayer insulating films 25 and 26 may be, for example, a SiO₂ film, a low-hydrogen SiN film, or the like. The first interlayer insulating film 25 has a thickness, for example, of approximately 20 nm to 100 nm. In the present preferred embodiment, the thickness of the first interlayer insulating film 25 is, for example, approximately 50 nm. The second interlayer insulating film 26 has a thickness, for example, of approximately 100 nm to 200 nm. In the present preferred embodiment, the thickness of the second interlayer insulating film 26 is, for example, approximately 150 nm.

An upper wiring 27, a lower wiring 28, and a dummy wiring 29 (see FIG. 2 and FIG. 8) are formed on the second interlayer insulating film 26. These wirings 27, 28, and 29 are constituted, for example, of a laminated film with a TiN film and an Al film being laminated successively from the interlayer insulating film 26 side. Each of these wirings 27, 28, and 29 has a thickness, for example, of approximately 500 nm.

The upper wiring 27 includes a first upper contact portion 27A, a second upper contact portion 27B, an upper connection wiring portion 27C (see FIG. 2 and FIG. 4), and an upper pad portion 27D (see FIG. 2 and FIG. 4). The first upper contact portion 27A is connected to one end portion of the upper electrode 13 (an upstream side end portion in the ink flow direction 50). The second upper contact portion 27B is connected to the other end portion of the upper electrode 13 (a downstream side end portion in the ink flow direction 50). The upper connection wiring portion 27C connects the first and second upper contact portions 27A and 27B to the upper pad portion 27D.

A first upper contact hole 41 that penetrates continuously through both the interlayer insulating film 24 and the second hydrogen barrier film 22 is formed between the first upper contact portion 27A and the upper electrode 13. One end portion of the first upper contact portion 27A enters into the first upper contact hole 41, and is connected to the upper electrode 13 inside the first upper contact hole 41. As shown in FIG. 4, the first upper contact portion 27A extends from above the upper electrode 13 toward the outside of the end portion of the upper electrode 13 along a longitudinal direction of the upper electrode 13, and then extends in one direction along a lateral direction of the upper electrode 13, and is connected to the upper connection wiring portion 27C outside the pressure chamber 8.

Likewise, a second upper contact hole 42 that penetrates continuously through both the interlayer insulating film 24 and the second hydrogen barrier film 22 is formed between the second upper contact portion 27B and the upper electrode 13. One end portion of the second upper contact portion 27B enters into the second upper contact hole 42, and is connected to the upper electrode 13 inside the second upper contact hole 42. The second upper contact portion 27B extends from above the upper electrode 13 toward the outside of the other end portion of the upper electrode 13 along the longitudinal direction of the upper electrode 13, and then extends in one direction along the lateral direction of the upper electrode 13, and is connected to the upper connection wiring portion 27C outside the pressure chamber 8. The upper pad portion 27D is formed in a region outside the pressure chamber 8. The upper connection wiring portion 27C is connected to the upper pad portion 27D.

The lower wiring 28 includes a lower contact portion 28A, a lower connection wiring portion 28B (see FIG. 2), and a lower pad portion 28C (see FIG. 2 and FIG. 8). The lower contact portion 28A is connected to one end portion of the lower electrode 11 (an upstream side end portion in the ink flow direction 50). The lower connection wiring portion 28B connects the lower contact portion 28A to the lower pad portion 28C.

A pair of lower contact holes 43 that penetrate continuously through both the interlayer insulating film 24 and the second hydrogen barrier film 22 are formed between the lower contact portion 28A and the lower electrode 11 (in detail, the extension portion 11B). The pair of lower contact holes 43 are disposed at intervals in a lateral direction of the lower electrode 11.

The lower contact portion 28A enters into each of the pair of lower contact holes 43, and is connected to the lower electrode 11 inside each of the lower contact holes 33. The lower contact portion 28A crosses an outer edge of the pressure chamber 8 from above the lower electrode 11, and extends outside the pressure chamber 8, and is connected to the lower connection wiring portion 28B. The lower pad portion 28C (see FIG. 2 and FIG. 8) is formed in a region outside the pressure chamber 8. The lower connection wiring portion 28B is connected to the lower pad portion 28C.

The dummy wiring 29 is a wiring that is electrically connected neither to the upper wiring 27 nor to the lower wiring 28. The dummy wiring 29 is formed in the same step as the step of forming the upper wiring 27 and the lower wiring 28.

A passivation film 30 that covers the upper wiring 27, the lower wiring 28, the dummy wiring 29, and the second interlayer insulating film 26 is formed on the second interlayer insulating film 26. The passivation film is constituted, for example, of a SiO₂ film. The passivation film 30 may be a SiN film. The passivation film may have a thickness, for example, of approximately 500 nm.

An opening 35 that exposes a central portion of the upper electrode 13 is formed in the second hydrogen barrier film 22, in the interlayer insulating film 24, and in the passivation film 30. The opening 35 is formed to enlarge the displacement of the movable film 5A.

A pair of upper pad openings 44 that expose a part of the upper pad portion 27D is formed in the passivation film 30. The pair of upper pad openings 44 are formed at intervals in a direction along the ink flow direction 50 above the upper pad portion 27D. An upper electrode pad 51 that covers the pair of upper pad openings 44 is formed on the passivation film 30. The upper electrode pad 51 enters into each of the pair of upper pad openings 44, and is connected to the upper pad portion 27D inside each of the upper pad openings 44.

A pair of lower pad openings 45 that expose a part of the lower pad portion 28C is formed in the passivation film 30 as shown in FIG. 8. The pair of lower pad openings 45 are formed at intervals in a direction along the ink flow direction 50 above the lower pad portion 28C. A lower electrode pad 52 that covers the pair of lower pad openings 45 is formed on the passivation film 30. The lower electrode pad 52 enters into each of the pair of lower pad openings 45, and is connected to the lower pad portion 28C inside each of the lower pad openings 45.

The upper electrode pad 51 and the lower electrode pad 52 are each constituted, for example, of a laminated film with a TiW film and an Au film being laminated successively from the passivation film 30 side (pad portion 27D, pad portion 28C side). Each of the pads 51 and 52 has a thickness, for example, of approximately 0.6 μm.

A first liquid contact film (ink resistance film) 31 having ink resistance is formed on entireties of a front surface of the passivation film 30 and an inner surface (side surface and bottom surface) of the opening 35 except a predetermined region including the upper electrode pad 51 and a predetermined region including the lower electrode pad 52. The bottom surface of the opening 35 is an upper surface of the upper electrode 13, and therefore a part of the first liquid contact film 31 is formed in contact with the upper surface of the upper electrode 13 facing the opening 35. The first liquid contact film 31 is formed to protect the piezoelectric element 10 from ink. The first liquid contact film 31 is, for example, a SiTaO film. The first liquid contact film 31 may be TaO film.

Preferably, the first liquid contact film 31 has a thickness of not less than 5 nm and not more than 100 nm, and, more preferably has a thickness of not less than 10 nm and not more than 50 nm. The reason is that there is a concern that a function cannot be achieved as a protective film if the film thickness is thinner than 5 nm, and there is a concern that the displacement of the movable film 5A will be hindered if the film thickness is thicker than 100 nm. In the present preferred embodiment, the thickness of the first liquid contact film 31 is, for example, approximately 20 nm.

A first ink inflow passage 53 that penetrates through the first liquid contact film 31, the passivation film 30, the second interlayer insulating film 26, and the movable film formation layer 5 is formed at a position corresponding to an ink inflow portion 7 side end portion of the ink flow passage 6. A first ink outflow passage 54 that penetrates through the first liquid contact film 31, the passivation film 30, the second interlayer insulating film 26, and the movable film formation layer 5 is formed at a position corresponding to an ink outflow portion 9 side end portion of the ink flow passage 6.

An adhesion strengthening film 61 is formed on the first liquid contact film 31. The adhesion strengthening film 61 is formed to raise adhesive properties between the substrate assembly SA and an adhesive agent layer 62 when the protective substrate 4 is bonded to the substrate assembly SA by means of the adhesive agent layer 62.

The protective substrate 4 is constituted, for example, of a silicon substrate. In the present preferred embodiment, the protective substrate 4 has a thickness of approximately 400 μm. An oxide film 4a is formed on an entirety of a front surface of the protective substrate 4 excluding an outer peripheral side surface of the protective substrate 4. The protective substrate 4 is disposed on the substrate assembly SA so as to cover the piezoelectric element 10. The protective substrate 4 is bonded to the substrate assembly SA via the adhesion strengthening film 61 and the adhesive agent layer 62.

The protective substrate 4 has a housing concave 72 at a facing surface 71 that faces the substrate assembly SA. The piezoelectric element 10 is housed in the housing concave 72. Also, a second ink inflow passage 73 in communication with the first ink inflow passage 53 and a second ink outflow passage 74 in communication with the first ink outflow passage 54 are formed in the protective substrate 4, the adhesion strengthening film 61, and the adhesive agent layer 62. Further, the protective substrate 4 has formed therein a first opening portion 75 and a second opening portion 76 (see FIG. 1) that are arranged to expose the upper electrode pad 51 and the lower electrode pad 52, respectively.

The second ink inflow passage 73, the second ink outflow passage 74, the first opening portion 75, and the second opening portion 76 penetrate through the protective substrate 4. An ink tank (not shown) storing ink is disposed above the protective substrate 4.

A second liquid contact film 65 is formed on inner surfaces of the second ink inflow passage 73, the first ink inflow passage 53, the ink flow passage 6, the first ink outflow passage 54, the second ink outflow passage 74, and the nozzle holes 3a and 43 and on a front surface (lower surface) of the nozzle substrate 3 on a side opposite to the ink flow passage 6 side. The second liquid contact film 65 is, for example, a SiTaO film. The second liquid contact film 65 may be a TaO film. The second liquid contact film 65 has a thickness, for example, of approximately 50 nm.

A water-repellent film 66 is formed on an entire front surface of the second liquid contact film 65. The water-repellent film 66 is constituted of a film the raw material of which is, for example, a compound including an alkyl fluoride radical. The water-repellent film 66 has a thickness, for example, of approximately 10 nm.

The piezoelectric element 10 is formed at a position facing the pressure chamber 8 across the movable film 5A and the first hydrogen barrier film 21. That is, the piezoelectric element 10 is formed to contact a front surface of the first hydrogen barrier film 21 on a side opposite to the pressure chamber 8. Ink circulates via the second ink inflow passage 73, the first ink inflow passage 53, the ink flow passage 6, the first ink outflow passage 54, and the second ink outflow passage 74 from the ink tank. The pressure chamber 8 is thereby always filled with ink.

The movable film 5A defines the top surface portion of the pressure chamber 8, and faces the pressure chamber 8. The movable film 5A is supported by a peripheral portion of the pressure chamber 8 of the actuator substrate 2 and has flexibility enabling deformation in a direction facing the pressure chamber 8 (in other words, in the thickness direction of the movable film 5A).

The lower wiring 28 and the upper wiring 27 are connected to a drive circuit (not shown). Specifically, the upper electrode pad 51 and the drive circuit are connected via a connecting metal member (not shown). The lower electrode pad 52 (see FIG. 2 and FIG. 8) and the drive circuit are connected together via a connecting metal member (not shown). When a drive voltage is applied from the drive circuit to the piezoelectric element 10, the piezoelectric film 12 deforms due to an inverse piezoelectric effect. The movable film 5A is thereby made to deform together with the piezoelectric element 10 to thereby bring about a volume change of the pressure chamber 8 and the ink inside the pressure chamber 8 is pressurized. The pressurized ink passes through the nozzle hole 3a and is discharged as microdroplets from the ink discharge port 3b.

The ink inflow portion 7 (ink inflow passages 53 and 73) of FIG. 5 may be the ink outflow portion 9 (ink outflow passages 54 and 74), and the ink outflow portion 9 (ink outflow passages 54 and 74) of FIG. 5 may be the ink inflow portion 7 (ink inflow passages 53 and 73). In other words, the direction of ink circulation may be an opposite direction.

The arrangement of the inkjet printing head 1 will be described in more detail with reference to FIG. 1 to FIG. 9. In the following description, the left side of FIG. 1 is referred to as “left,” the right side of FIG. 1 is referred to as “right,” the lower side of FIG. 1 is referred to as “front,” and the upper side of FIG. 1 is referred to as “rear.”

The shape in a plan view of the inkjet printing head 1 is oblong as shown in FIG. 1. In the present preferred embodiment, the planar shapes and sizes of the actuator substrate 2, the protective substrate 4, and the nozzle substrate 3 are substantially the same as the planar shape and size of the inkjet printing head 1.

In a plan view, a plurality of columns, each of which is a column of a plurality of piezoelectric elements aligned in stripe form at intervals in a front-rear direction (hereinafter, referred to as “piezoelectric element column”), are provided at intervals in a left-right direction on the actuator substrate 2. For descriptive convenience, let it be supposed that two piezoelectric element columns are provided in the present preferred embodiment.

The ink flow passage 6 (pressure chamber 8) is formed for each piezoelectric element 10 in the actuator substrate 2 as shown in FIG. 4. Therefore, in a plan view, two ink flow passage columns (pressure chamber columns), each of which is constituted of a plurality of the ink flow passages 6 (pressure chambers 8) aligned in stripe form at intervals in the front-rear direction, are provided at intervals in the left-right direction in the actuator substrate 2.

The first ink inflow passage 53 and the first ink outflow passage 54 are provided for the plurality of ink flow passages 6 of each ink flow passage column. The first ink inflow passage 53 is disposed on the ink inflow portion 7. The first ink outflow passage 54 is disposed on the ink outflow portion 9. With respect to the single ink flow passage 6, the first ink inflow passage 53 is disposed on a left end portion of the single ink flow passage 6, and the first ink outflow passage 54 is disposed on the right side of the single ink flow passage 6 in the present preferred embodiment.

The first ink inflow passage 53 (ink inflow portion 7) and the first ink outflow passage 54 (ink outflow portion 9) may be disposed in an opposite manner in the left-right direction between the ink flow passage column on the left side and the ink flow passage column on the right side. In other words, the ink flow direction 50 may be mutually opposite between the ink flow passage column on the left side and the ink flow passage column on the right side.

In each of the ink flow passage columns, the plurality of ink flow passages 6 are formed at equal intervals that are minute intervals (for example, of approximately 30 μm to 350 μm) in a width direction thereof. Each ink flow passage 6 is elongate along the ink flow direction 50. The ink flow passage 6 is constituted of the ink inflow portion 7 in communication with the first ink inflow passage 53, the ink outflow portion 9 in communication with the first ink outflow passage 54, and the pressure chamber 8 in communication with the ink inflow portion 7 and with the ink outflow portion 9.

The pressure chamber 8 is a region between the first ink inflow passage 53 (ink inflow portion 7) and the first ink outflow passage 54 (ink outflow portion 9) of the ink flow passage 6 shown by a broken line in FIG. 4. The pressure chamber 8 has an oblong shape that is elongate along the ink flow direction 50 in a plan view. That is, the top surface portion of the pressure chamber 8 has two side edges along the ink flow direction 50 and two end edges along a direction orthogonal to the ink flow direction 50. The pressure chamber 8 (ink flow passage 6) has a width slightly larger than the ink inflow portion 7 and the ink outflow portion 9 in a plan view.

The piezoelectric element 10 has a rectangular shape that is long in the longitudinal direction of the pressure chamber 8 (movable film 5A) in a plan view. The length in a longitudinal direction of the piezoelectric element 10 is shorter than the length in the longitudinal direction of the pressure chamber 8 (movable film 5A). Respective end edges along a lateral direction of the piezoelectric element 10 are disposed at inner sides at predetermined intervals respectively from the respective corresponding end edges of the movable film 5A. Also, the width in the lateral direction of the piezoelectric element is narrower than the width in a lateral direction of the movable film 5A. Respective side edges along the longitudinal direction of the piezoelectric element 10 are disposed at inner sides at predetermined intervals respectively from the respective corresponding side edges of the movable film 5A.

The lower electrode 11 has a rectangular shape that is long in the longitudinal direction of the pressure chamber 8 (movable film 5A) in a plan view. The lower electrode 11 includes the main electrode portion 11A that constitutes the piezoelectric element 10 and that has a rectangular shape in a plan view and the extension portion 11B that has been drawn out from a peripheral edge of the main electrode portion 11A in a direction along a front surface of the movable film formation layer 5 and that has a rectangular annular shape in a plan view. The length in a longitudinal direction of the main electrode portion 11A is shorter than the length in the longitudinal direction of the movable film 5A. Respective end edges of the main electrode portion 11A are disposed at inner sides at predetermined intervals respectively from the respective corresponding end edges of the movable film 5A. Also, the width in a lateral direction of the main electrode portion 11A is narrower than the width in the lateral direction of the movable film 5A. Respective side edges of the main electrode portion 11A are disposed at inner sides at predetermined intervals respectively from the respective corresponding side edges of the movable film 5A.

Respective end edges of the extension portion 11B (respective end edges of the lower electrode 11) are disposed at inner sides at predetermined intervals respectively from the respective corresponding end edges of the movable film 5A. Respective side edges of the extension portion 11B (respective side edges of the lower electrode 11) are disposed at outer sides at predetermined intervals respectively from the respective corresponding side edges of the movable film 5A.

In a plan view, the upper electrode 13 is formed to a rectangular shape of the same pattern as the main electrode portion 11A of the lower electrode 11. That is, the length in the longitudinal direction of the upper electrode 13 is shorter than the length in the longitudinal direction of the movable film 5A. Respective end edges of the upper electrode 13 are disposed at inner sides at predetermined intervals respectively from the respective corresponding end edges of the movable film 5A. Also, the width in the lateral direction of the upper electrode 13 is narrower than the width in the lateral direction of the movable film 5A. Respective side edges of the upper electrode 13 are disposed at inner sides at predetermined intervals respectively from the respective corresponding side edges of the movable film 5A.

In a plan view, the piezoelectric film 12 is formed to a rectangular shape of the same pattern as the upper electrode 13. That is, the length in the longitudinal direction of the piezoelectric film 12 is shorter than the length in a longitudinal direction of the movable film 5A. Respective end edges of the piezoelectric film 12 are disposed at inner sides at predetermined intervals respectively from the respective corresponding end edges of the movable film 5A. Also, the width in a lateral direction of the piezoelectric film 12 is narrower than the width in the lateral direction of the movable film 5A. Respective side edges of the piezoelectric film 12 are disposed at inner sides at predetermined intervals respectively from the respective corresponding side edges of the movable film 5A. A lower surface of the piezoelectric film 12 contacts an upper surface of the main electrode portion 11A of the lower electrode 11, and an upper surface of the piezoelectric film 12 contacts a lower surface of the upper electrode 13.

In FIG. 1 and FIG. 2, the upper electrode pad 51 and the lower electrode pad 52 are provided one by one for each pair of piezoelectric elements adjoining in the right-left direction (hereinafter, referred to as “a right-left pair of piezoelectric elements 10”).

The upper electrode pad 51 is disposed at the right side of the right-hand first ink outflow passage 54 in the right-left pair of piezoelectric elements 10. The upper electrode pad 51 is disposed in the first opening portion 75 of the protective substrate 4. The upper pad portion 27D (upper wiring 27) electrically connected to the upper electrode pad 51 is disposed below the upper electrode pad 51.

The lower electrode pad 52 is disposed at the left side of the left-hand first ink inflow passage 53 in the right-left pair of piezoelectric elements 10. The lower electrode pad 52 is disposed in the second opening portion 76 of the protective substrate 4. The lower pad portion 28C (lower wiring 28) electrically connected to the lower electrode pad 52 is disposed below the lower electrode pad 52.

A plurality of the upper electrode pads 51 corresponding to the right-left pairs of piezoelectric elements 10 are arranged side by side in a line in the front-rear direction at the right side of the right-hand piezoelectric element column in a plan view as shown in FIG. 1 and FIG. 2. Also, a plurality of the lower electrode pads 52 corresponding to the right-left pairs of piezoelectric elements 10 are arranged side by side in a line in the front-rear direction at the left side of the left-hand piezoelectric element column in a plan view as shown in FIG. 1 and FIG. 2.

In the right-hand piezoelectric element 10 of the right-left pair of piezoelectric elements 10, the first upper contact portion 27A and the second upper contact portion 27B of the upper wiring 27 are connected to the upper pad portion 27D via the upper connection wiring portion 27C disposed at the front side of the right-left pair of piezoelectric elements 10. The upper connection wiring portion 27C extends rightwardly from a left end of the right-hand piezoelectric element 10 at the front side of the right-left pair of piezoelectric elements 10, and is connected to the upper pad portion 27D.

In the right-hand piezoelectric element 10 of the right-left pair of piezoelectric elements 10, the lower contact portion 28A of the lower wiring 28 is electrically connected to a left end portion of the lower electrode 11 of the right-hand piezoelectric element 10. The lower contact portion 28A is connected to the lower pad portion 28C via the lower connection wiring portion 28B disposed at the front side of the right-left pair of piezoelectric elements 10. The lower connection wiring portion 28B extends leftwardly from a left end of the lower electrode 11 of the right-hand piezoelectric element 10 at the front side of the right-left pair of piezoelectric elements 10, and is connected to the lower pad portion 28C.

In the left-hand piezoelectric element 10 of the right-left pair of piezoelectric elements 10, the first upper contact portion 27A and the second upper contact portion 27B of the upper wiring 27 are connected to the upper pad portion 27D via the upper connection wiring portion 27C disposed at the rear side of the right-left pair of piezoelectric elements 10. The upper connection wiring portion 27C extends rightwardly from a left end of the left-hand piezoelectric element 10 at the rear side of the right-left pair of piezoelectric elements 10, and is connected to the upper pad portion 27D.

In the left-hand piezoelectric element 10 of the right-left pair of piezoelectric elements 10, the lower contact portion 28A of the lower wiring 28 is electrically connected to the left end portion of the lower electrode 11 of the left-hand piezoelectric element 10. The lower contact portion 28A is connected to the lower pad portion 28C via the lower connection wiring portion 28B disposed at the rear side of the right-left pair of piezoelectric elements 10. The lower connection wiring portion 28B extends leftwardly from a left end of the lower electrode 11 of the left-hand piezoelectric element 10 at the rear side of the right-left pair of piezoelectric elements 10, and is connected to the lower pad portion 28C.

The passivation film 30 has the upper pad opening 44 (see FIG. 5) formed to expose a part of the upper pad portion 27D of the upper wiring 27. The upper electrode pad 51 is provided on the passivation film 30 so as to cover the upper pad opening 44. The upper electrode pad 51 is connected to the upper wiring 27 inside the upper pad opening 44.

The passivation film 30 has the lower pad opening (see FIG. 8) formed to expose a part of the lower pad portion 28C of the lower wiring 28. The lower electrode pad 52 is provided on the passivation film 30 so as to cover the lower pad opening 45. The lower electrode pad 52 is connected to the lower wiring 28 inside the lower pad opening 45.

A plurality of the second ink inflow passages 73 in communication with the plurality of first ink inflow passages 53 and a plurality of the second ink outflow passages 74 in communication with the plurality of first ink outflow passages 54 are formed in the protective substrate 4 as shown in FIG. 1, FIG. 3, FIG. 5, and FIG. 8. In each of the left-hand and right-hand piezoelectric element columns, the plurality of second ink inflow passages 73 are disposed in a line at intervals in the front-rear direction, and the plurality of second ink outflow passages 74 are disposed in a line at intervals in the front-rear direction.

The second ink inflow passage 73 has a rectangular shape of the same pattern as the first ink inflow passage 53 on the actuator substrate 2 side in a plan view. In each of the left-hand and right-hand piezoelectric element columns, the second ink inflow passage 73 matches the first ink inflow passage 53 in a plan view. The second ink outflow passage 74 has a rectangular shape of the same pattern as the first ink outflow passage 54 on the actuator substrate 2 side in a plan view. In each of the left-hand and right-hand piezoelectric element columns, the second ink outflow passage 74 matches the first ink outflow passage 54 in a plan view.

Also, the protective substrate 4 has the first opening portion 75 formed to expose all the upper electrode pads 51 and the second opening portion 76 formed to expose all the lower electrode pads 52. These opening portions 75 and 76 are formed in a rectangular shape that is long in the front-rear direction in a plan view.

In a plan view, the dummy wiring 29 is disposed at both right and left sides of the second ink inflow passage 73 (first ink inflow passage 53), and is disposed at both right and left sides of the second ink outflow passage 74 (first ink outflow passage 54). The dummy wiring 29 constitutes a pedestal that supports the protective substrate 4 and that raises adhesiveness with a facing surface of the protective substrate 4.

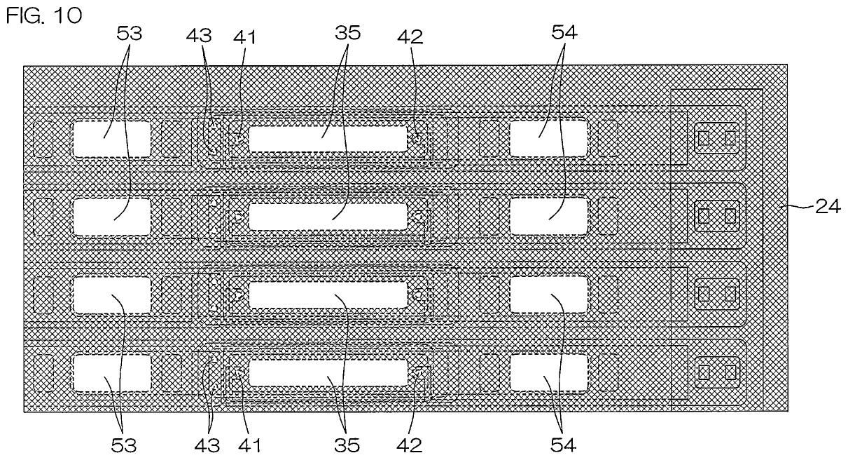

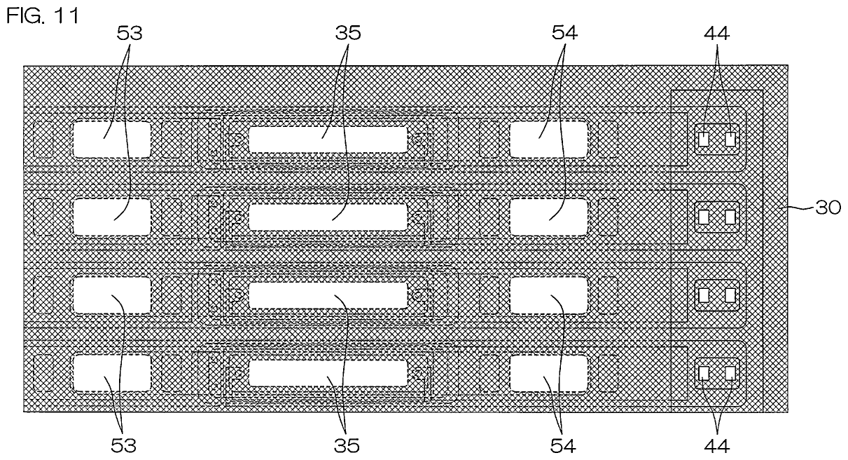

FIG. 10 is an illustrative plan view showing a pattern example of the interlayer insulating film 24 of the inkjet printing head 1 mentioned above. FIG. 11 is an illustrative plan view showing a pattern example of the passivation film 30 of the inkjet printing head mentioned above.

In the present preferred embodiment, above the actuator substrate 2, the interlayer insulating film 24 and the passivation film 30 are formed on substantially an entirety of an outer region of the housing concave 72 of the protective substrate 4 in a plan view. However, in this region, the first ink inflow passage 53, the first ink outflow passage 54, and the lower contact hole 43 are formed in the interlayer insulating film 24. The lower contact hole 43 is also formed in the second hydrogen barrier film 22. In this region, the first ink inflow passage 53, the first ink outflow passage 54, the upper pad opening 44, and the lower pad opening 45 are formed in the passivation film 30.

In the region of the protective substrate 4 at inner sides of the housing concave 72, the interlayer insulating film 24 and the passivation film 30 are formed only at its peripheral edge portion including both its end portions (upper wiring region) in which the upper wiring 27 (upper contact portions 27A and 27B) is present. In this region, the second hydrogen barrier film 22 is likewise formed only at the peripheral edge portion.

Also, in this region, the passivation film 30 is formed so as to cover an upper surface and a side surface of the upper wiring 27 on the interlayer insulating film 24. In other words, the opening 35 is formed in the second hydrogen barrier film 22, in the interlayer insulating film 24, and in the passivation film 30 in a region, which excludes the peripheral edge portion including the upper wiring region, of the inner region of the housing concave 72 in a plan view. The first upper contact hole 41 and the second upper contact hole 42 are additionally formed in the second hydrogen barrier film 22 and in the interlayer insulating film 24.

The second hydrogen barrier film 22 may be present inside the opening 35. In other words, the second hydrogen barrier film 22 may be formed on an entirety of the upper surface of the upper electrode 13. In this case, the bottom surface of the opening 35 is the upper surface of the upper electrode 13, and therefore a part of the first liquid contact film 31 is formed in contact with the upper surface of the second hydrogen barrier film 22 facing the opening 35.

A description will be given of an outline of a method for manufacturing the inkjet printing head 1.

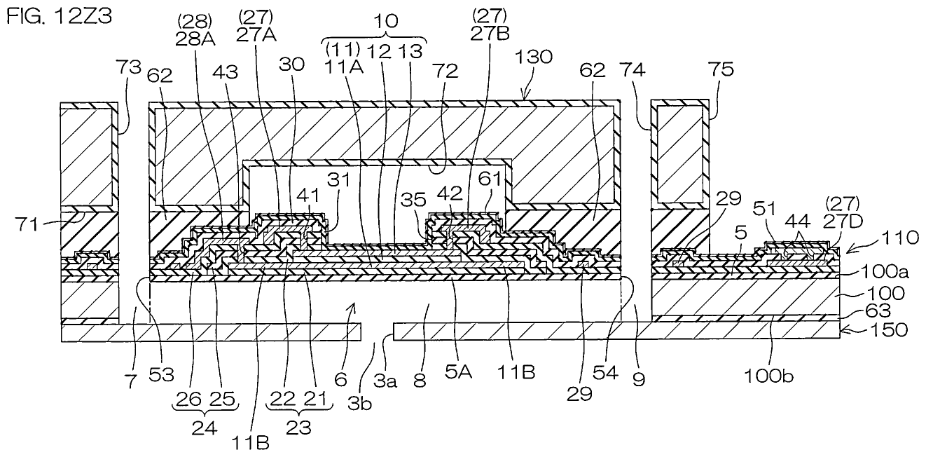

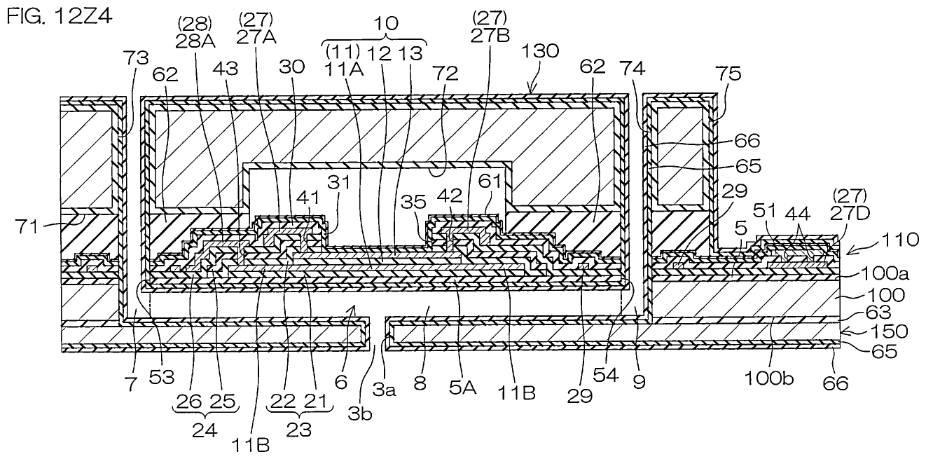

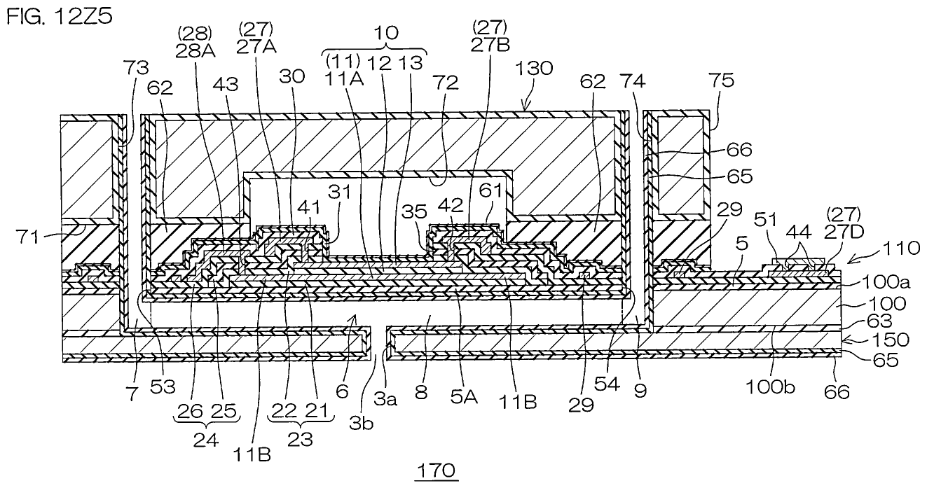

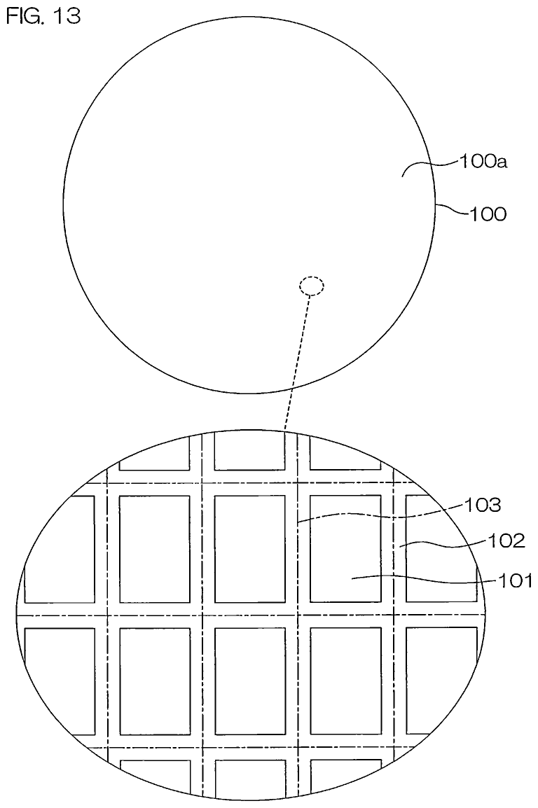

FIG. 13 is a plan view of a semiconductor wafer serving as an original substrate of an actuator substrate, and a partial region of the semiconductor wafer is shown in enlarged manner.

A semiconductor wafer (actuator wafer) 100 serving as an original substrate of the actuator substrate 2 is constituted, for example, of a silicon wafer. A front surface 100a of the actuator wafer 100 corresponds to a front surface 2a of the actuator substrate. A plurality of functional-element forming regions 101 are aligned and set in a matrix manner on the front surface 100a of the actuator wafer 100. A scribe region 102 (boundary region) is provided between the adjoining functional-element forming regions 101. The scribe region 102 is a belt-shaped region having a substantially constant width, and extends in two directions that perpendicularly intersect each other, and is formed in a grid-shaped manner. An intended cutting line 103 is set in the scribe region 102.

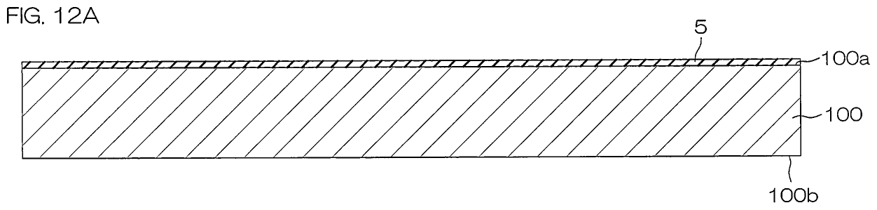

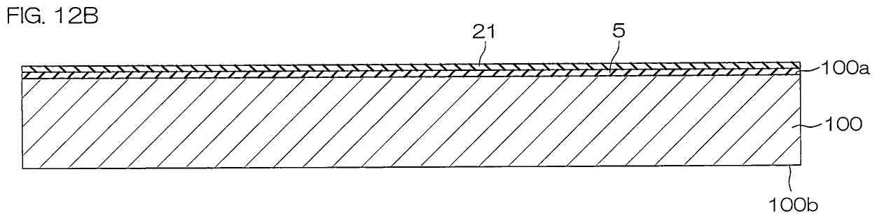

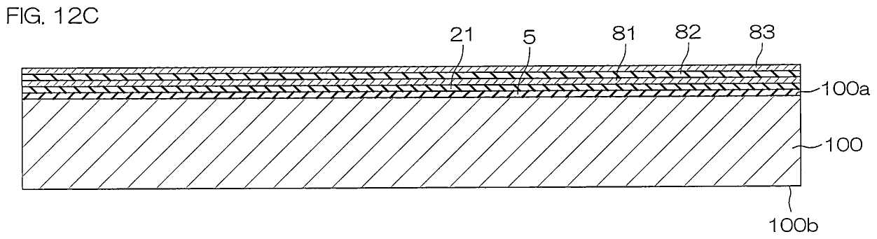

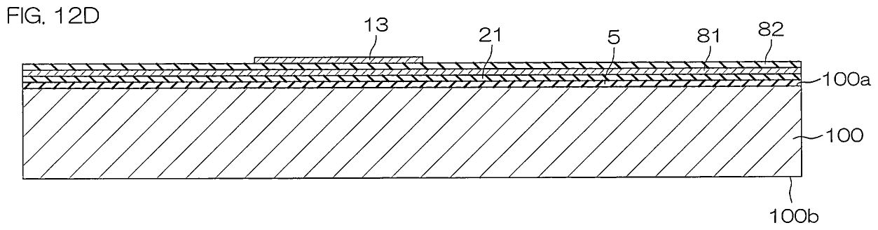

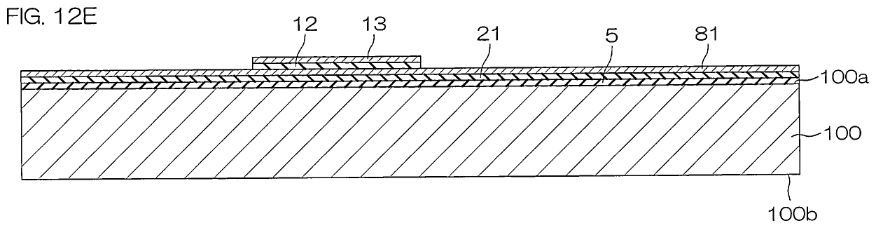

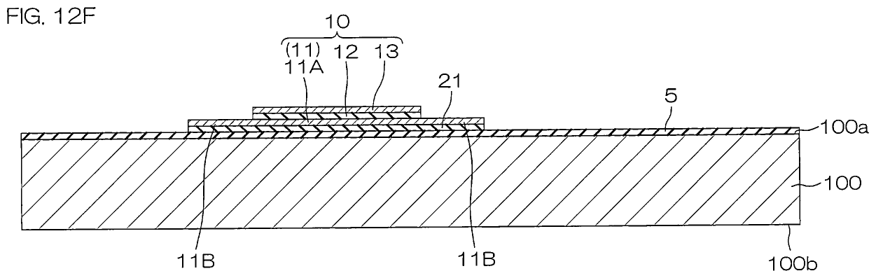

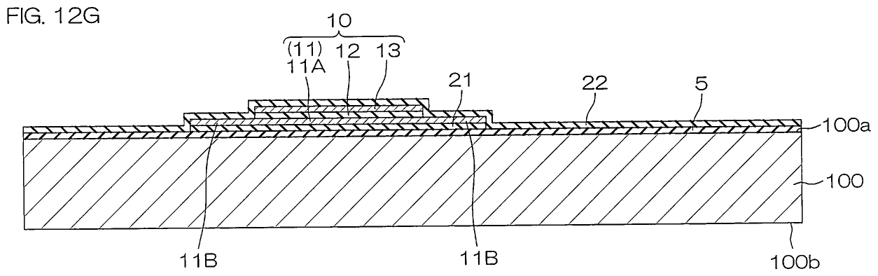

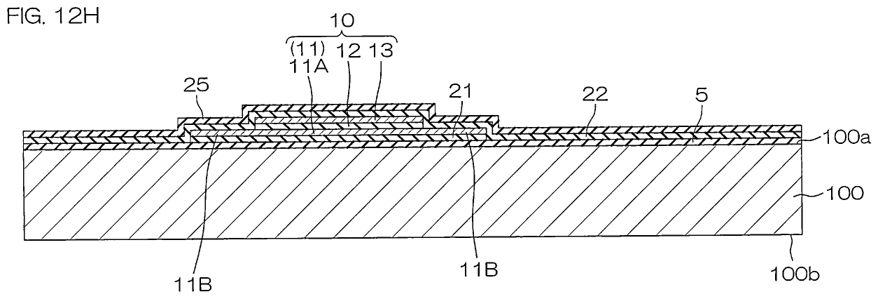

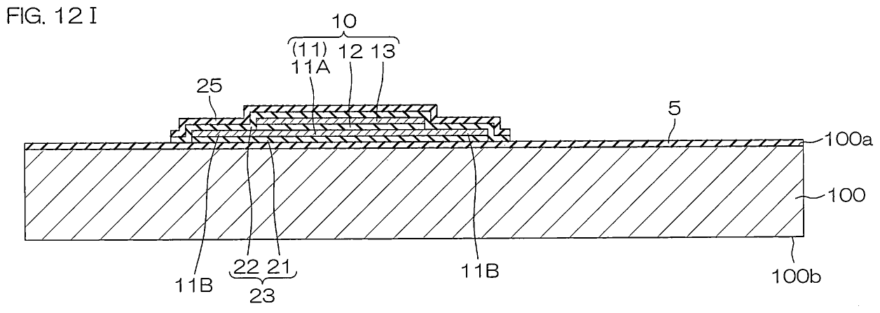

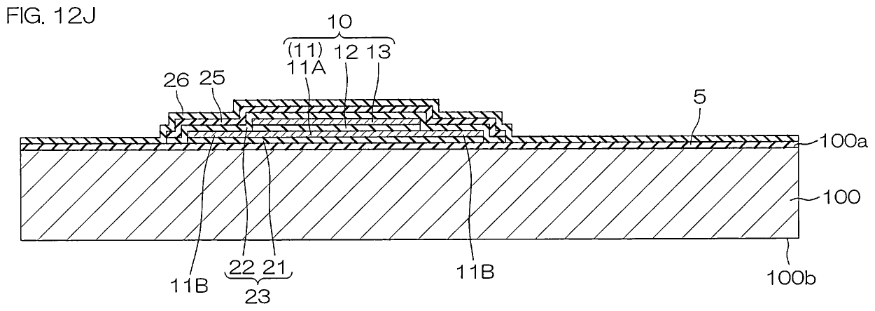

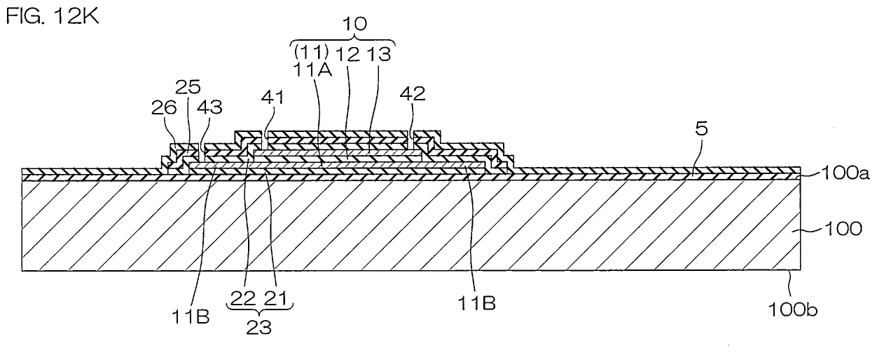

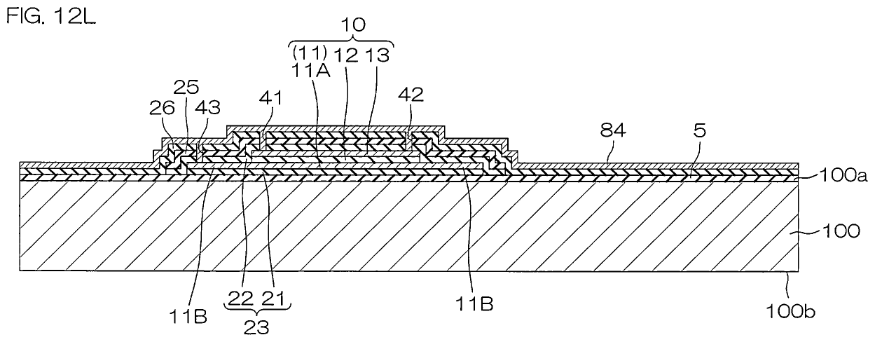

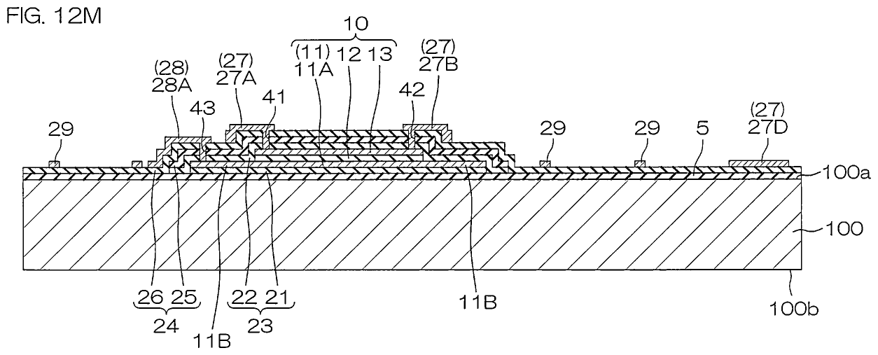

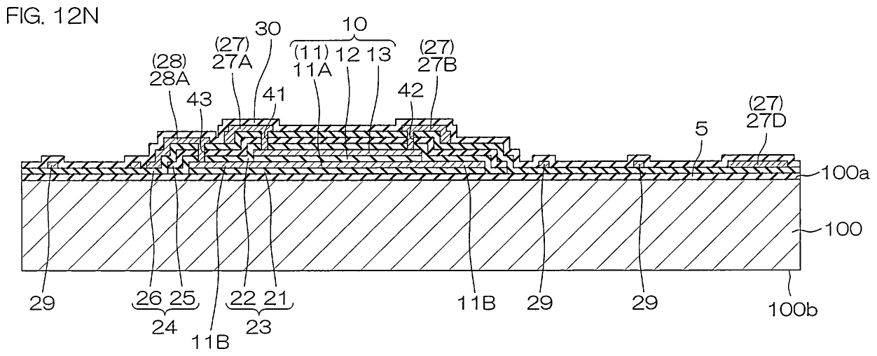

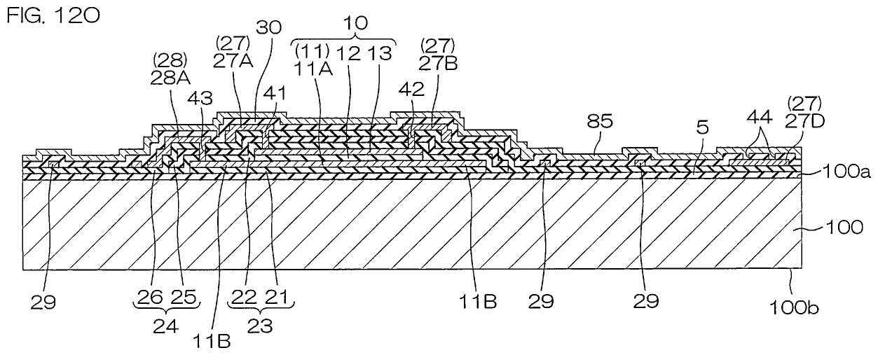

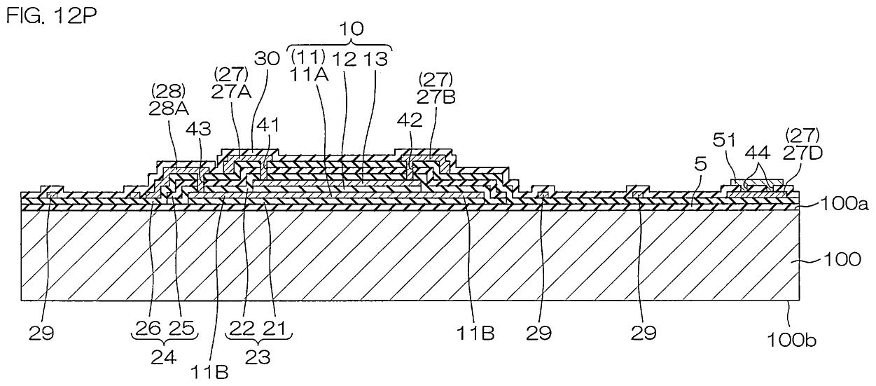

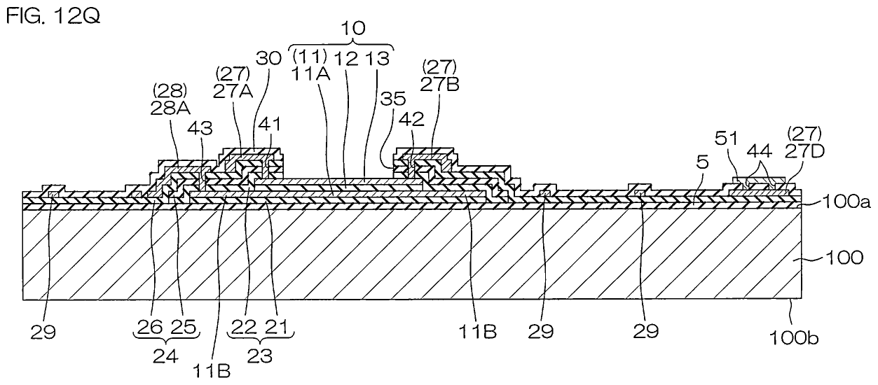

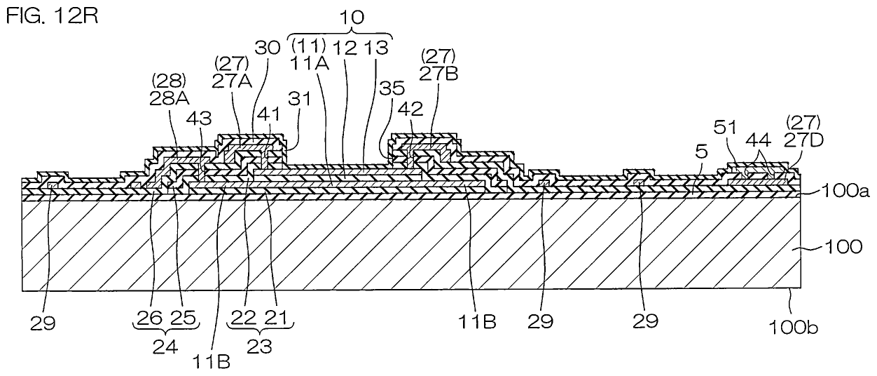

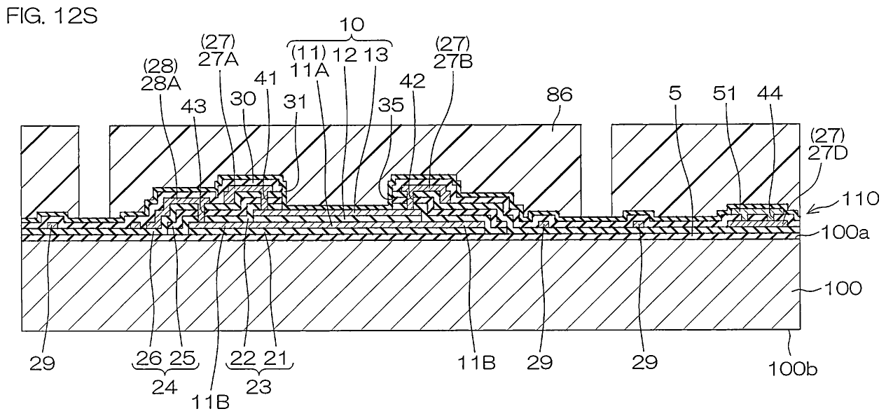

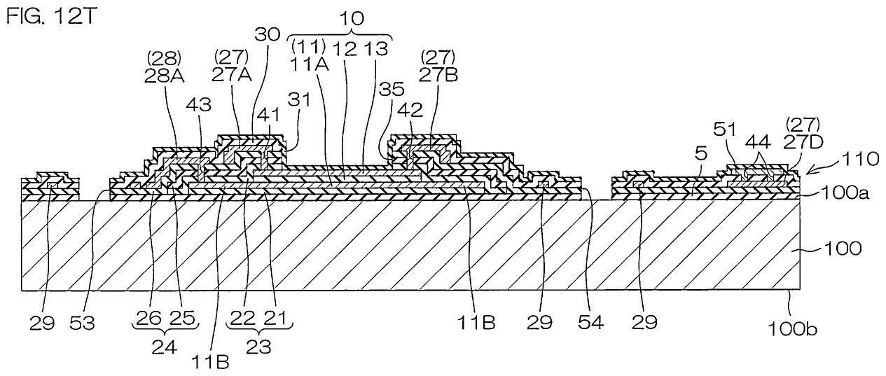

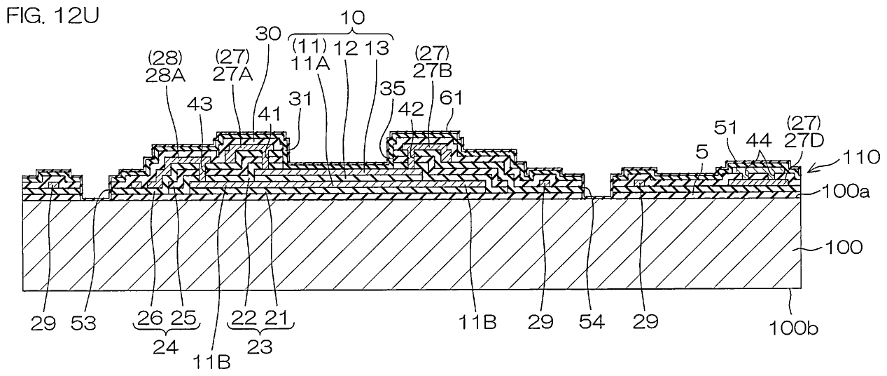

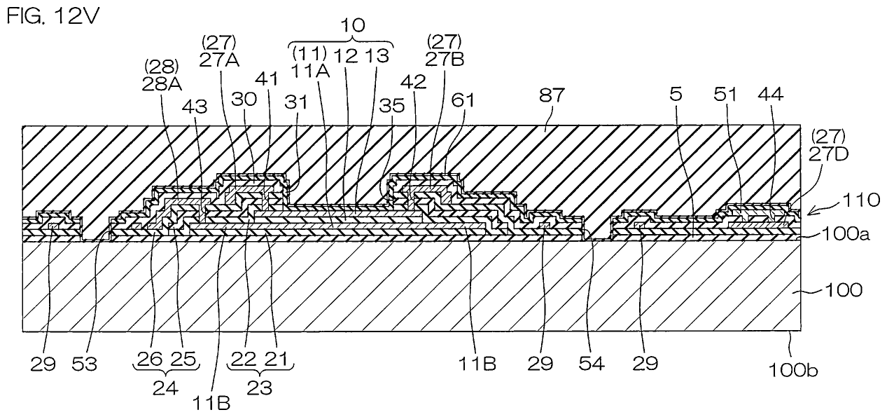

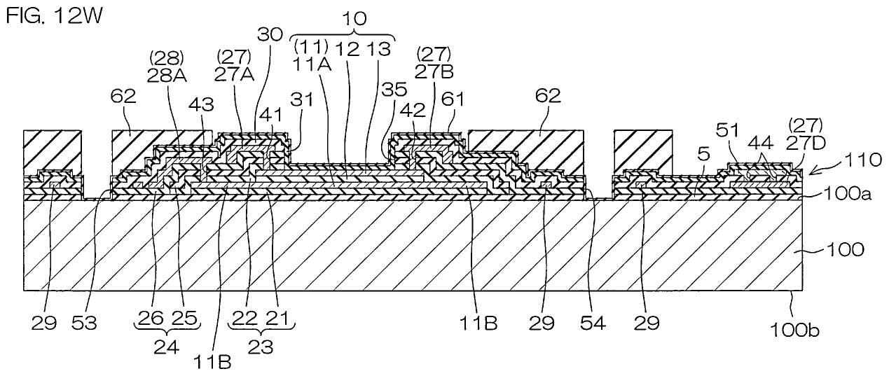

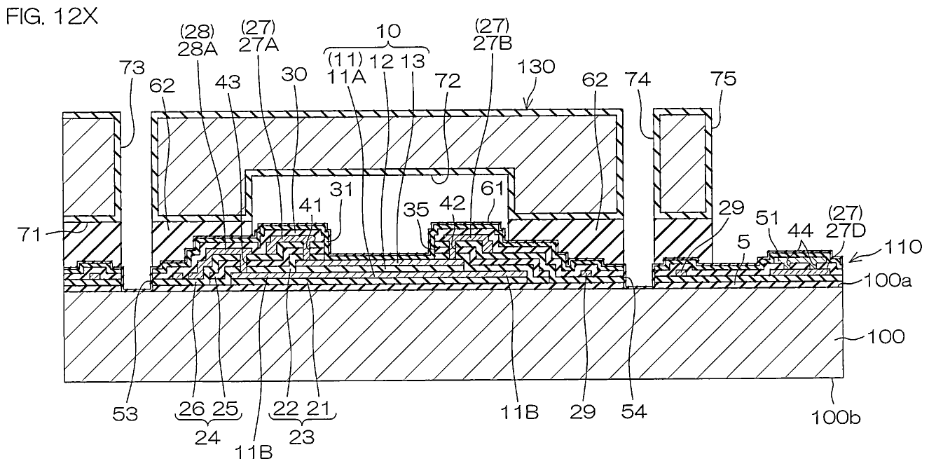

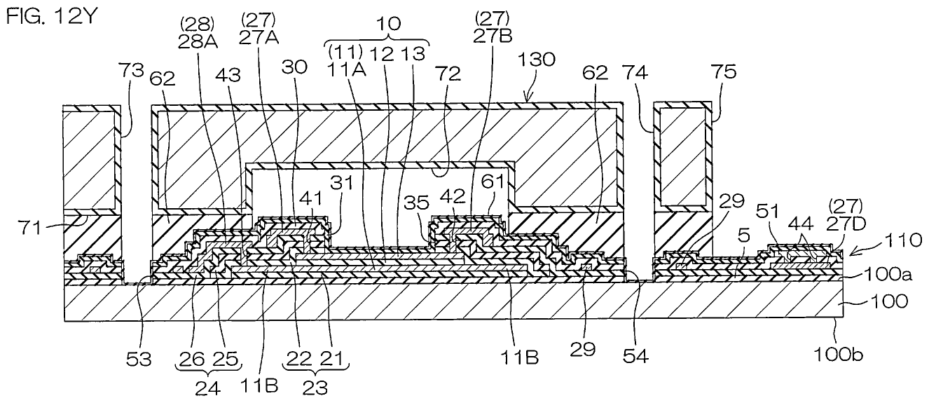

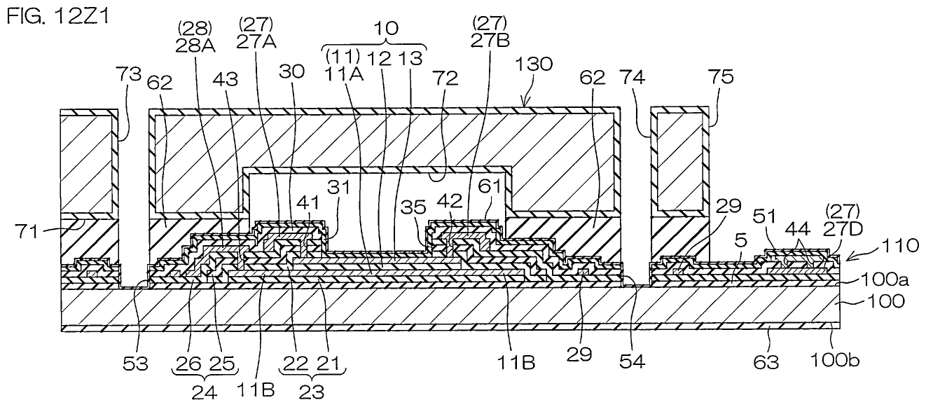

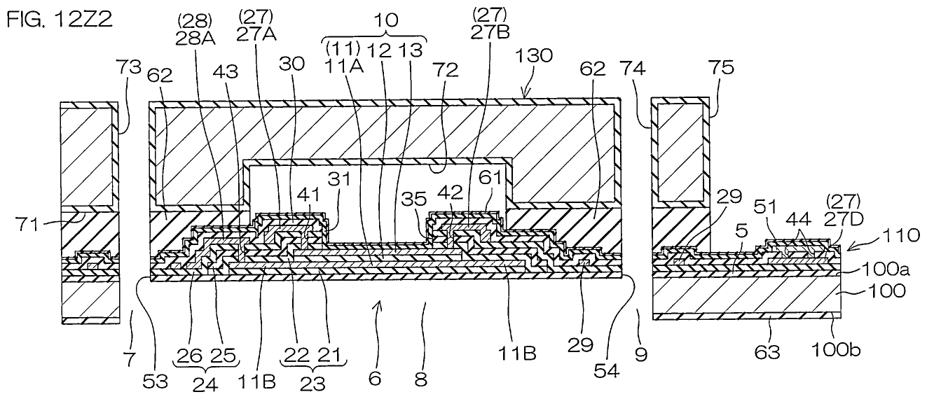

A substrate assembly aggregate (SA aggregate) 110 (see FIG. 12T) in which an arrangement of substrate assemblies SA is formed is created on each of the functional-element forming regions 101 by applying a necessary process onto the actuator wafer 100. Note that the ink flow passage 6, the second liquid contact film 65, and the water-repellent film 66 are not formed in the substrate assembly aggregate (SA aggregate) 110.

A protective substrate aggregate 130 (see FIG. 12X) that integrally includes a plurality of protective substrates 4 corresponding to each of the functional-element forming regions 101 of the substrate assembly aggregate 110 is prepared beforehand. Note that the second liquid contact film 65 and the water-repellent film 66 are not formed in the protective substrate aggregate 130. The protective substrate aggregate 130 is created by applying a necessary process onto a semiconductor wafer (wafer for the protective substrate) serving as an original substrate of the protective substrate 4. The wafer for the protective substrate is constituted, for example, of a silicon wafer.

Also, a nozzle substrate aggregate 150 (see FIG. 12Z3) that integrally includes a plurality of nozzle substrates 3 corresponding to each of the functional-element forming regions 101 of the substrate assembly aggregate 110 is prepared beforehand. Note that the second liquid contact film 65 and the water-repellent film 66 are not formed in the nozzle substrate aggregate 150. The nozzle substrate aggregate 150 is created by applying a necessary process onto a semiconductor wafer (nozzle wafer) serving as an original substrate of the nozzle substrate 3. The nozzle wafer is constituted, for example, of a silicon wafer.

When the substrate assembly aggregate 110 is created, the protective substrate aggregate 130 is bonded to the substrate assembly aggregate 110. Next, the ink flow passage 6 is formed in the substrate assembly aggregate 110. Next, the nozzle substrate aggregate 150 is bonded to the substrate assembly aggregate 110. An intermediate united body (see FIG. 12Z3) to which the substrate assembly aggregate 110 having the ink flow passage 6, the protective substrate aggregate 130, and the nozzle substrate aggregate 150 are bonded is thereby obtained.

Next, the second liquid contact film 65 and the water-repellent film 66 are formed in the intermediate united body. An inkjet printing head aggregate 170 (see FIG. 12Z5) is thereby obtained.

Thereafter, the inkjet printing head aggregate 170 is cut (diced) by a dicing blade along the intended cutting line 103. Individual inkjet printing heads (chips) 1 including the functional-element forming region 101 are thereby cut out. As a result, the inkjet printing head 1 has the scribe region 102 at a peripheral edge portion, and has the functional-element forming region 101 in a central region surrounded by the scribe region 102.

A method for manufacturing the inkjet printing head 1 will be hereinafter described in detail.

FIG. 12A to FIG. 12Z5 are sectional views each of which shows a manufacturing process of the inkjet printing head 1 and each of which is a sectional view corresponding to the cutting plane of FIG. 5.

First, the actuator wafer 100 is prepared as shown in FIG. 12A. Note that a wafer that has a thickness thicker than a thickness of an end-product actuator substrate 2 is used as the actuator wafer 100. Then, the movable film formation layer 5 is formed on the front surface 100a of the actuator wafer 100. Specifically, a silicon oxide film (for example, of 1.5 μm thickness) is formed on the front surface 100a of the actuator wafer 100. If the movable film formation layer 5 is constituted of a laminated film of a silicon oxide film and a silicon nitride film, a silicon oxide film (for example, of 0.7 μm thickness) is formed on the front surface 100a of the actuator wafer 100, and a silicon nitride film (for example, of 0.7 μm thickness) is formed on the silicon oxide film.

Next, the first hydrogen barrier film (first hydrogen barrier material film) 21 is formed on the movable film formation layer 5 as shown in FIG. 12B. The first hydrogen barrier film 21 is constituted, for example, of an Al₂O₃ film (for example, of 50 nm to 100 nm thickness). The first hydrogen barrier film 21 prevents degradation of characteristics of the piezoelectric film 12 due to hydrogen reduction. Also, the first hydrogen barrier film 21 prevents metal elements from escaping from the piezoelectric film 12 to be formed later. When metal elements escape, the piezoelectric film 12 may degrade in piezoelectric characteristics. Also, when metal elements that have escaped become mixed in the silicon layer constituting the movable film 5A (movable film 5A), the movable film 5A may degrade in durability.

Next, a lower electrode film 81, which is a material layer of the lower electrode 11, is formed on the first hydrogen barrier film 21 as shown in FIG. 12C. The lower electrode film 81 is constituted, for example, of a Pt/TiO₂ laminated film having a TiO₂ film (for example, of nm to 40 nm thickness) as a lower layer and a Pt film (for example, of 10 nm to 400 nm thickness) as an upper layer. Such a lower electrode film 81 may be formed by a sputtering method.

Next, a piezoelectric material film 82, which is a material of the piezoelectric film 12, is formed on an entire surface on the lower electrode film 81. Specifically, a piezoelectric material film 82 of, for example, 1 μm to 3 μm thickness is formed by, for example, the sol-gel method. Such a piezoelectric material film 82 is constituted of a sintered body of metal-oxide crystal grains.

Next, an upper electrode film 83, which is a material of the upper electrode 13, is formed on an entire surface of the piezoelectric material film 82. The upper electrode film 83 may, for example, be a single film of platinum (Pt). The upper electrode film 83 is constituted, for example, of an IrO₂/Ir laminated film having an IrO₂ film (for example, of 40 nm to 160 nm thickness) as a lower layer, and an Ir film (for example, of 40 nm to 160 nm thickness) as an upper layer. Such an upper electrode film 83 may be formed by the sputtering method.

Next, patterning of the upper electrode film 83, the piezoelectric material film 82, the lower electrode film 81, and the first hydrogen barrier film 21 is performed as shown in FIGS. 12D to 14F. First, a resist mask (not shown) with a pattern of the upper electrode 13 is formed by photolithography. Then, as shown in FIG. 12D and FIG. 12E, the upper electrode film 83 and the piezoelectric material film 82 are etched successively using the resist mask as a mask to form the upper electrode 13 and the piezoelectric film 12 of the upper electrode pattern.

Next, after peeling off the resist mask, a resist mask (not shown) with a pattern of the lower electrode 11 is formed by photolithography. Then, as shown in FIG. 12F, the lower electrode film 81 and the first hydrogen barrier film 21 are etched successively using the resist mask as a mask to form the lower electrode 11 and the first hydrogen barrier film 21 of the lower electrode pattern. The lower electrode 11, constituted of the main electrode portion 11A and the extension portion 11B, is thereby formed. The piezoelectric element 10, constituted of the main electrode portion 11A of the lower electrode 11, the piezoelectric film 12, and the upper electrode 13, is thereby formed.

Next, after peeling off the resist mask, the second hydrogen barrier film (second hydrogen barrier material film) 22 covering the entire surface is formed as shown in FIG. 12G. The second hydrogen barrier film 22 may be an Al₂O₃ film formed by the sputtering method and has a thickness, for example, of 50 nm to 100 nm.

Next, the first interlayer insulating film (first interlayer insulation material film) 25 is formed on an entire surface on the second hydrogen barrier film 22 as shown in FIG. 12H. The first interlayer insulating film 25 may be a SiO₂ film formed by using TEOS as a raw material and has a thickness, for example, of approximately 20 nm to 100 nm.

Next, a resist mask (not shown) with a pattern of the first interlayer insulating film 25 is formed by photolithography. Then, as shown in FIG. 12I, the first interlayer insulating film 25 and the second hydrogen barrier film 22 are etched successively using the resist mask as a mask, and the first interlayer insulating film 25 and the second hydrogen barrier film 22 are patterned to a predetermined second hydrogen barrier film pattern. The piezoelectric element 10 is thereby covered by the hydrogen barrier film 23 constituted of the first hydrogen barrier film 21 and the second hydrogen barrier film 22.

Next, after peeling off the resist mask, the second interlayer insulating film 26 covering an entire surface is formed as shown in FIG. 12J. The second interlayer insulating film 26 may be a SiO₂ film formed by using TEOS as a raw material, and has a thickness, for example, of approximately 100 nm to 200 nm.

Next, the first upper contact hole 41, the second upper contact hole 42, and the lower contact hole 43 that penetrate continuously through the second interlayer insulating film 26, the first interlayer insulating film 25, and the second hydrogen barrier film 22 are formed by photolithography and etching as shown in FIG. 12K.

Next, as shown in FIG. 12L, a wiring film 84 that constitutes the upper wiring 27, the lower wiring 28, and the dummy wiring 29 is formed by the sputtering method on the second interlayer insulating film 26 including an inside of each of the contact holes 41, 42, and 43.

Next, as shown in FIG. 12M, the wiring film 84 is patterned by photolithography and etching to form the upper wiring 27, the lower wiring 28, and the dummy wiring 29 at the same time.

Next, as shown in FIG. 12N, the passivation film that covers each of the wirings 27, 28, and 29 is formed on the front surface of the second interlayer insulating film 26. The passivation film 30 is constituted, for example, of a SiO₂ film. The passivation film 30 is formed, for example, by plasma CVD.

Next, a resist mask (not shown), having openings corresponding respectively to the upper and lower pad openings 44 and 45, is formed by photolithography, and the passivation film 30 is etched using the resist mask as a mask. The pad openings 44 and 45 are thereby formed in the passivation film 30 as shown in FIG. 12O. After peeling off the resist mask, a metal film 85 that constitutes the upper electrode pad 51 and the lower electrode pad 52 is formed on the passivation film 30 by the sputtering method. The metal film 85 is a laminated film constituted, for example, of a TiW film as a lower layer and an Au film as an upper layer.

Next, as shown in FIG. 12P, the metal film 85 for the pads is patterned by photolithography and etching to form the upper electrode pad 51 connected to the upper wiring 27 and the lower electrode pad 52 connected to the lower wiring 28 on the passivation film 30.

Next, after peeling off the resist mask, a resist mask (not shown), having an opening corresponding to the opening 35, is formed by photolithography, and the passivation film 30, the interlayer insulating film 24, and the second hydrogen barrier film 22 are etched successively using the resist mask as a mask. The opening 35 that exposes a central portion of the upper surface of the upper electrode 13 is thereby formed in the passivation film 30, in the interlayer insulating film 24, and in the second hydrogen barrier film 22 as shown in FIG. 12Q.

Next, after peeling off the resist mask, the first liquid contact film 31 that covers an entire surface is formed as shown in FIG. 12R. The first liquid contact film 31 is formed, for example, by an ALD (Atomic Layer Deposition) method or an MOCVD method. The film-forming temperature is, for example, approximately 80° C. to 350° C. The first liquid contact film 31 is, for example, a SiTaO film. The thickness of the first liquid contact film 31 is, for example, approximately 5 nm to 100 nm.

Next, a resist mask 86, having openings corresponding respectively to the first ink inflow passage 53 and the first ink outflow passage 54, is formed by photolithography as shown in FIG. 12S. The first liquid contact film 31, the passivation film 30, the second interlayer insulating film 26, and the movable film formation layer 5 are etched successively using the resist mask as a mask. The first ink inflow passage 53 and the first ink outflow passage 54 that penetrate through the first liquid contact film 31, the passivation film 30, the second interlayer insulating film 26, and the movable film formation layer 5 are thereby formed as shown in FIG. 12T. The substrate assembly aggregate 110 is thereby created.

Next, after peeling off the resist mask, an adhesion strengthening agent is applied onto an entire front surface by a spin coating method as shown in FIG. 12U. Thereafter, baking treatment is performed to bake the adhesion strengthening agent. The adhesion strengthening film 61 that covers the entire surface is thereby formed. The adhesion strengthening agent is, for example, AP9000C (trade name) manufactured by Dow Electronic Materials, and has a thickness, for example, of approximately 10 nm. Preferably, the baking condition is 140° C. or more under air atmosphere.

Next, an adhesive agent is applied onto an entire surface on the adhesion strengthening film 61 by the spin coating method as shown in the FIG. 12V. Thereafter, baking treatment is performed to bake the adhesive agent. An adhesive-agent material layer 87 is thereby formed on the entire surface on the adhesion strengthening film 61. In the present preferred embodiment, a photosensitive adhesive agent is used as the adhesive agent. The photosensitive adhesive agent is, for example, CYCLOTENE™ 6505 (trade name) manufactured by Dow Electronic Materials, and has a thickness, for example, of 1 μm to 7 μm. Preferably, the baking condition is 90° C. or more and is less than 150° C. under air atmosphere. The reason why the baking condition is, preferably, less than 150° C. is that there is a concern that the adhesive agent will be oxidized if baking treatment is performed at 150° C. or more under air atmosphere.

Next, the adhesive-agent material layer 87 is patterned by the adhesive-agent material layer 87 being exposed and developed as shown in the FIG. 12W. Portions of the adhesive-agent material layer 87, which correspond to the opening 35 of the actuator substrate 2, to the first ink inflow passage 53, to the first ink outflow passage 54, and to the first and second opening portions 75 and 76 of the protective substrate 4, are thereby removed. The adhesive agent layer 62 is thereby selectively formed on the adhesion strengthening film 61.

Next, the protective substrate aggregate 130 is bonded to the substrate assembly aggregate 110 via the adhesive agent layer 62 as shown in FIG. 12X. At this time, these are bonded so that the second ink inflow passage 73 and the second ink outflow passage 74 of the protective substrate aggregate 130 matches the first ink inflow passage 53 and the first ink outflow passage 54 of the substrate assembly aggregate 110, respectively.

Next, as shown in FIG. 12Y, rear surface grinding is performed for thinning the actuator wafer 100. The actuator wafer 100 is made thin by the actuator wafer 100 being ground from its rear surface 100b. For example, the actuator wafer 100 with a thickness of approximately 625 μm in the initial state may be thinned to a thickness of approximately 70 μm.

Next, the adhesive layer 63 is formed on the entire surface of the rear surface 100b of the actuator wafer 100 as shown in FIG. 12Z1. The adhesive layer 63 may be constituted, for example, of an adhesion strengthening film that is applied onto the rear surface 100b of the actuator wafer 100 and an adhesive agent layer that is applied onto the adhesion strengthening film. The adhesion strengthening film is, for example, AP3000C (trade name) manufactured by Dow Electronic Materials, and has a thickness, for example, of approximately 100 Å. In this case, after coating the adhesion strengthening film, baking treatment is performed. Also, the adhesive agent is, for example, CYCLOTENE™ 3022 (trade name) manufactured by Dow Electronic Materials, and has a thickness, for example, of approximately 1.2 μm. In this case, after coating the adhesive agent, baking treatment is performed.

Next, a resist mask (not shown), having an opening corresponding to the ink flow passage 6, is formed on a front surface (lower surface) of the adhesive layer 63 by photolithography. Then, the actuator wafer 100 is etched from its rear surface 100b using the resist mask as a mask. The ink flow passage 6 (ink inflow portion 7, pressure chamber 8, and ink outflow portion 9) is thereby formed in the actuator wafer 100 as shown in FIG. 12Z2. Also, as a result of the etching, the adhesion strengthening film 61 on the side and bottom surfaces of the first ink inflow passage 53 and the adhesion strengthening film 61 on the side and bottom surfaces of the first ink outflow passage 54 are also removed.

Next, the nozzle substrate aggregate 150 is adhered to the rear surface 100b of the actuator wafer 100 as shown in FIG. 12Z3. The substrate assembly aggregate 110 in which the laminated films 65 and 66 of the second liquid contact film 65 and the water-repellent film 66 are not formed, the protective substrate aggregate 130 in which the laminated films 65 and 66 are not formed, and the nozzle substrate aggregate 150 in which the laminated films 65 and 66 are not formed are thereby united together. An intermediate united body is thereby obtained.

Next, the second liquid contact film 65 is formed on an entirety of an exposed surface of the intermediate united body, including inner surfaces of the second ink inflow passage 73, the first ink inflow passage 53, the ink flow passage 6, the first ink outflow passage 54, the second ink outflow passage 74, and the nozzle hole 3a, as shown in FIG. 12Z4. The second liquid contact film 65 is, for example, a SiTaO film. The second liquid contact film 65 may be a TaO film. The second liquid contact film 65 has a thickness of approximately 50 nm.

Thereafter, the water-repellent film 66 is formed on an entire surface on the second liquid contact film 65. The water-repellent film 66 is constituted, for example, of a film the raw material of which is a compound including an alkyl fluoride radical. The water-repellent film 66 has a thickness of approximately 10 nm.

Next, the laminated films 65 and 66 of the second liquid contact film 65 and the water-repellent film 66 of an upper surface of the protective substrate aggregate 130 and the laminated films 65 and 66 facing the first opening portion 75 and the second opening portion 76 of the protective substrate aggregate 130 are removed by photolithography and etching as shown in FIG. 12Z5. Further, as a result of the etching, the laminated film of the first liquid contact film 31 and the passivation film 30 in the first and second opening portions 75 and 76 of the protective substrate aggregate 130 is removed. As a result, an upper surface of the upper electrode pad 51 is exposed to the first opening portion 75, and an upper surface of the lower electrode pad 52 is exposed to the second opening portion 76.

The inkjet printing head aggregate 170 constituted of the substrate assembly aggregate 110, the protective substrate aggregate 130, and the nozzle substrate aggregate 150 is thereby obtained. Thereafter, the inkjet printing head aggregate 170 is cut by the dicing blade along the intended cutting line 103. That is, a step of individually cutting out the inkjet printing head 1 is performed.

When this step is completed, the actuator wafer 100 in the substrate assembly aggregate 110 becomes the actuator substrate 2 of each individual inkjet printing head 1. Also, the protective substrate aggregate 130 becomes the protective substrate 4 of each individual inkjet printing head 1. Also, the nozzle substrate aggregate 150 becomes the nozzle substrate 3 of each individual inkjet printing head 1. An individual piece of the inkjet printing head 1 having a structure shown in FIG. 1 to FIG. 9 is thus obtained.

In a method for manufacturing an inkjet printing head according to the present preferred embodiment, the nozzle substrate aggregate 150 is bonded to the substrate assembly aggregate 110 to which the protective substrate aggregate 130 is fixed for creating the inkjet printing head aggregate 170. Then, the inkjet printing head aggregate 170 is diced for individually cutting out the inkjet printing head 1. Therefore, it is possible to manufacture the inkjet printing head 1 more efficiently than, for example, in a case in which each individual substrate assembly SA is manufactured, and then the nozzle substrate 3 is individually bonded to each individual substrate assembly SA for manufacturing the inkjet printing head.

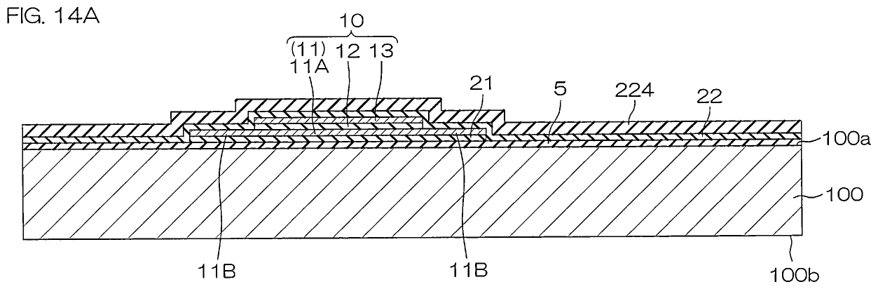

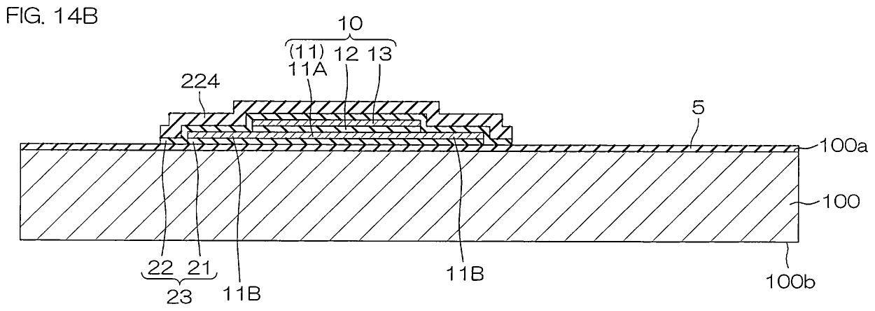

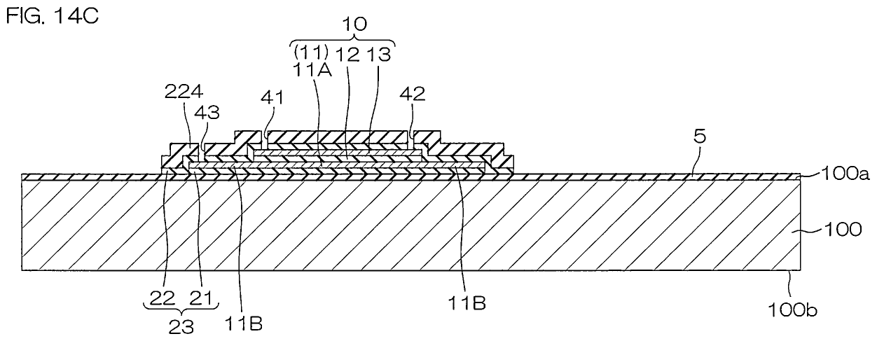

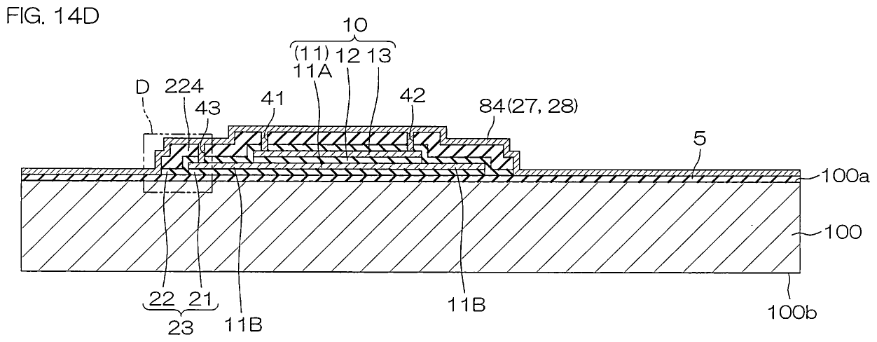

FIG. 14A to FIG. 14D are sectional views each of which shows a part of a manufacturing process of a comparative example.

The comparative example differs from the preferred embodiment of FIG. 5 in the arrangement of the interlayer insulating film. The interlayer insulating film of the comparative example is constituted of a single layer, i.e., a single interlayer insulating film 224 whose pattern in a plan view is the same as the pattern of the first interlayer insulating film 25 of the preferred embodiment. The interlayer insulating film 224 of the comparative example has a thickness substantially equal to a thickness obtained by adding the thickness of the first interlayer insulating film 25 and the thickness of the second interlayer insulating film 26 of the preferred embodiment together.

FIG. 14A corresponds to FIG. 12H of the preferred embodiment. That is, the interlayer insulating film 224 is formed on an entire surface on the second hydrogen barrier film (second hydrogen barrier material film) in FIG. 14A. The interlayer insulating film 224 may be a SiO₂ film formed by using TEOS as a raw material, and has a thickness, for example, of approximately 50 nm.

Next, a resist mask (not shown) with a pattern of the interlayer insulating film 224 is formed by photolithography. Then, as shown in FIG. 14B, the interlayer insulating film 224 and the second hydrogen barrier film 22 are etched successively using the resist mask as a mask, and the interlayer insulating film 224 and the second hydrogen barrier film 22 are patterned to a predetermined second hydrogen barrier film pattern. The piezoelectric element 10 is thereby covered by the hydrogen barrier film 23 constituted of the first hydrogen barrier film 21 and the second hydrogen barrier film 22.

Next, the first upper contact hole 41, the second upper contact hole 42, and the lower contact hole 43, which penetrate continuously through the second interlayer insulating film 26, the first interlayer insulating film 25, and the second hydrogen barrier film 22, are formed by photolithography and etching as shown in FIG. 14C.

Next, the wiring film 84 is formed on the second interlayer insulating film 26 including the inside of each of the contact holes 41, 42, and 43 by the sputtering method as shown in FIG. 14D. Thereafter, the wiring film 84 is patterned to form the upper wiring 27, the lower wiring 28, and the dummy wiring 29 each of which has the same pattern as that of the preferred embodiment.

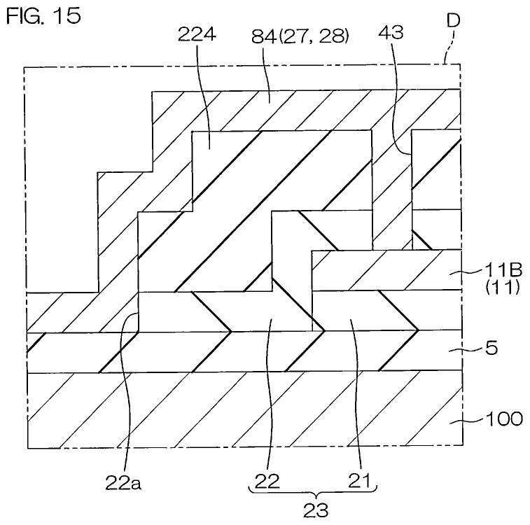

FIG. 15 is an enlarged sectional view showing a D portion of FIG. 14D in enlarged manner.

In the comparative example, an outer peripheral end surface 22a of the second hydrogen barrier film 22 contacts the wiring film 84. That is, in the comparative example, the upper wiring 27 and the lower wiring 28 contacts the outer peripheral end surface 22a of the second hydrogen barrier film 22 in addition to the fact that the upper contact portion that connects the upper wiring 27 to the upper electrode 13 and the lower contact portion that connects the lower wiring 28 to the lower electrode 11 contacts the second hydrogen barrier film 22.

On the other hand, in the present preferred embodiment, the second interlayer insulating film 26 is present between the outer peripheral end surface 22a of the second hydrogen barrier film 22 and the wirings 27, 28 as shown in FIG. 6, FIG. 7, and FIG. 9, and therefore the outer peripheral end surface 22a of the second hydrogen barrier film 22 does not contact the wirings 27 and 28. That is, in the present preferred embodiment, the wirings 27 and 28 are brought into non-contact with the second hydrogen barrier film 22 by means of the second interlayer insulating film 26, except for the upper contact portions 27A and 27B and the lower contact portion 28A.

In other words, in the present preferred embodiment, a region in which the wirings 27, 28 and the second hydrogen barrier film 22 are in contact with each other is enabled to be smaller than in the comparative example. This makes it difficult for the wirings 27 and 28 to degrade even when the hydrogen barrier film 23 is corroded by ink that has infiltrated onto the front surface of the substrate assembly SA from a bonded portion or the like between the protective substrate 4 and the substrate assembly SA.

The first hydrogen barrier film 21 is not necessarily required to be formed. Likewise, in this case, the outer peripheral end surface of the second hydrogen barrier film 22 does not come into contact with the wirings 27 and 28, and therefore the same effect can be obtained.

Also, in the present preferred embodiment, the opening 35 to expose the central portion of the upper electrode 13 is formed in the laminated film constituted of the second hydrogen barrier film 22, the interlayer insulating film 24, and the passivation film 30, and therefore it is possible to make the displacement of the movable film 5A larger than in a case in which the opening is not formed.

Also, in the present preferred embodiment, the first liquid contact film 31 is formed so as to cover the upper surface of the upper electrode 13. This makes it possible to restrain the piezoelectric element 10 from being degenerated by ink that has infiltrated onto the front surface of the substrate assembly SA from the bonded portion or the like between the protective substrate 4 and the substrate assembly SA.

Particularly in the present preferred embodiment, the opening 35 to expose the central portion of the upper electrode 13 is formed in the laminated film constituted of the second hydrogen barrier film 22, the interlayer insulating film 24, and the passivation film 30, and therefore ink infiltrates into the piezoelectric element 10 from the opening 35 more easily than in a case in which the opening 35 is not formed. In the present preferred embodiment, the first liquid contact film 31 is formed on an entirety of the inner surface (side surface and bottom surface) of the opening 35. The first liquid contact film 31 has an effect of preventing ink that has infiltrated into the opening 35 from infiltrating into the piezoelectric element 10. This makes it possible to effectively restrain the piezoelectric element 10 from being degraded by ink even when ink infiltrates into the opening 35 (in detail, infiltrates onto the front surface of the first liquid contact film 31 formed on the inner surface of the opening 35).

The second hydrogen barrier film 22 is formed at the central portion of the upper electrode 13, and the first liquid contact film 31 is likewise formed on an entirety of the inner surface (side surface and bottom surface) of the opening 35 in a case in which the opening 35 is formed only in the interlayer insulating film 24 and the passivation film 30. Therefore, it is possible to effectively restrain the piezoelectric element 10 from being degraded by ink even when ink infiltrates into the opening 35.

Also, in a case in which the opening 35 is not formed in the laminated film of the second hydrogen barrier film 22, the interlayer insulating film 24, and the passivation film 30, the first liquid contact film 31 is formed on the front surface of the passivation film 30 on the upper surface of the upper electrode 13. Likewise, in this case, it is possible to restrain the piezoelectric element 10 from being degraded by ink because of the first liquid contact film 31.

Also, in the present preferred embodiment, the protective substrate 4 is bonded to the actuator substrate 2 (substrate assembly SA) by means of the adhesion strengthening film 61 formed on the actuator substrate 2 (the substrate assembly SA) side and the photosensitive adhesive agent layer 62 formed on the adhesion strengthening film 61. A photosensitive adhesive agent is used as the adhesive agent, and therefore the patterning of the adhesive agent layer 62 becomes easy. This makes it possible to simplify a step of bonding the protective substrate 4 to the actuator substrate 2.

Also, the adhesion strengthening film 61 is formed on the actuator substrate 2 side, and therefore it is possible to raise adhesive properties between the protective substrate 4 and the actuator substrate 2, and is possible to restrain ink from infiltrating from a bonded portion between the protective substrate 4 and the actuator substrate 2 to the front surface side of the substrate assembly SA.

Also, the adhesion strengthening agent is applied to the actuator substrate 2 side (front surface of the substrate assembly SA) by the spin coating method, and therefore it is possible to form the front surface of the adhesion strengthening film 61 so as to be a less-rugged flat surface. Also, the photosensitive adhesive agent is applied onto the adhesion strengthening layer 61 by the spin coating method, and therefore it is possible to form the front surface of the adhesive agent layer 62 so as to be a less-rugged flat surface. This makes it more difficult to generate air bubbles in the bonded portion between the protective substrate 4 and the actuator substrate 2 than in a case in which the adhesive agent is applied by a stamp method. Therefore, it is possible to effectively restrain ink from infiltrating from the bonded portion between the protective substrate 4 and the actuator substrate 2 to the front surface side of the substrate assembly SA.

The preferred embodiment of the first disclosure has been described as above, and yet the first disclosure can be embodied in other preferred embodiments.

Although the number of piezoelectric element columns (pressure chamber columns) provided at the actuator substrate 2 is two, only one piezoelectric element column (pressure chamber column) or three or more piezoelectric element columns may be provided.

Also, although, in the preferred embodiment described above, the first hydrogen barrier film 21 is formed between the movable film formation layer 5 and the lower electrode 11, the first hydrogen barrier film 21 may be omitted.

Also, although, in the preferred embodiment described above, PZT was cited as an example of the material of the piezoelectric film, a piezoelectric material besides this that is constituted of a metal oxide as represented by lead titanate (PbPO₃), potassium niobate (KNbO₃), lithium niobate (LiNbO₃), or lithium tantalate (LiTaO₃), etc., may be applied instead.

### [2] With Respect to Second Disclosure

A second disclosure described below can be extracted from the description of the specification concerning the preferred embodiment of the first disclosure mentioned above and from the description of FIGS. 1 to 15.

### [2-1] Object of Second Disclosure

An object of the second disclosure is to provide an inkjet printing head capable of restraining a piezoelectric element from being degraded by ink and to provide a method for manufacturing the inkjet printing head.

### [2-2] Arrangement of Second Disclosure

A1. An inkjet printing head including,

an actuator substrate that has an ink flow passage including a pressure chamber,

a movable film formation layer, disposed on the pressure chamber and that includes a movable film defining a top surface portion of the pressure chamber,

a piezoelectric element that includes a lower electrode disposed on the movable film, a piezoelectric film formed on the lower electrode, and an upper electrode formed on the piezoelectric film,

a hydrogen barrier film that covers, in a front surface of the piezoelectric element, at least entireties of side surfaces of the upper electrode and the piezoelectric film,

an interlayer insulating film formed on the movable film formation layer so as to cover the hydrogen barrier film,

a wiring that is formed on the interlayer insulating film and that is connected to the piezoelectric element,

a passivation film that is formed on the interlayer insulating film and that covers the wiring, and

a liquid contact film formed so as to cover an upper surface of the upper electrode.

With the present arrangement, the liquid contact film formed so as to cover the upper surface of the upper electrode is included, which makes it possible to restrain the piezoelectric element from being degraded by ink.

A2. The inkjet printing head according to “A1.,” wherein a laminated film that constitutes the hydrogen barrier film, the interlayer insulating film, and the passivation film and that has an opening that exposes a part of the upper surface of the upper electrode is formed on the upper surface of the upper electrode, and

the liquid contact film is formed so as to come into contact with the upper surface of the laminated film and with an entire inner surface of the opening.

A3. The inkjet printing head according to “A1.,” wherein the hydrogen barrier film is formed on the upper surface of the upper electrode, and

a laminated film that constitutes the interlayer insulating film and the passivation film and that has an opening that exposes a part of the hydrogen barrier film is formed on the hydrogen barrier film of the upper surface of the upper electrode, and

the liquid contact film is formed so as to come into contact with the upper surface of the laminated film and with an entire inner surface of the opening.

A4. The inkjet printing head according to “A2.” or “A3.,” wherein the liquid contact film is formed on an entirety of the upper surface of the passivation film in a region other than a region above the upper surface of the upper electrode.

A5. The inkjet printing head according to any one of “A1.” to “A4.,” wherein the lower electrode includes a main electrode portion that contacts a lower surface of the piezoelectric film and an extension portion that extends from the main electrode portion to a region outside the piezoelectric film, and

the hydrogen barrier film covers entireties of side surfaces of the upper electrode, the piezoelectric film, and the lower electrode, a part of the upper surface of the upper electrode, and an entirety of an upper surface of the extension portion.

A6. The inkjet printing head according to “A5.,” wherein the hydrogen barrier film is also formed on an entire lower surface of the lower electrode.

A7. The inkjet printing head according to any one of “A1.” to “A6.,” wherein the wiring includes an upper wiring connected to the upper electrode and a lower wiring connected to the lower electrode.

A8. The inkjet printing head according to “A7.,” wherein an upper contact hole that exposes a part of the upper surface of the upper electrode is formed in the hydrogen barrier film formed on the upper surface of the upper electrode and the interlayer insulating film, and an end portion of the upper wiring is connected to the upper electrode via the upper contact hole, and

a lower contact hole that exposes a part of the upper surface of the lower electrode is formed in the hydrogen barrier film formed on the upper surface of the lower electrode and the interlayer insulating film, and an end portion of the lower wiring is connected to the lower electrode via the lower contact hole.

A9. The inkjet printing head according to any one of “A1.” to “A8.,” wherein the liquid contact film is a SiTaO film or a TaO film.

A10. The inkjet printing head according to “A9.,” wherein the liquid contact film has a thickness of not less than 5 nm and not more than 100 nm.

A11. The inkjet printing head according to “A9.,” wherein the liquid contact film has a thickness of not less than 10 nm and not more than 50 nm.

A12. A method for manufacturing an inkjet printing head, including,

a step of forming a piezoelectric element constituted of a lower electrode, a piezoelectric film formed on the lower electrode, and an upper electrode formed on the piezoelectric film on a substrate,

a step of forming a hydrogen barrier film that covers the piezoelectric element on the substrate,

a step of forming an interlayer insulating film that covers the hydrogen barrier film on the substrate,

a wiring formation step of forming an upper wiring one end of which is connected to the upper electrode and a lower wiring one end of which is connected to the lower electrode on the interlayer insulating film,

a step of forming a passivation film that covers the upper wiring and the lower wiring on a front surface of the interlayer insulating film,

a step of forming an opening that exposes a part of an upper surface of the upper electrode in the hydrogen barrier film on the upper electrode, the interlayer insulating film, and the passivation film, and

a step of forming a liquid contact film on an entire inner surface of the opening and on an upper surface of the passivation film.

A13. A method for manufacturing an inkjet printing head, including,

a step of forming a piezoelectric element constituted of a lower electrode, a piezoelectric film formed on the lower electrode, and an upper electrode formed on the piezoelectric film on a substrate,

a step of forming a hydrogen barrier film that covers the piezoelectric element on the substrate,

a step of forming an interlayer insulating film that covers the hydrogen barrier film on the substrate,

a wiring formation step of forming an upper wiring one end of which is connected to the upper electrode and a lower wiring one end of which is connected to the lower electrode on the interlayer insulating film,

a step of forming a passivation film that covers the upper wiring and the lower wiring on a front surface of the interlayer insulating film,

a step of forming an opening that exposes a part of an upper surface of the upper electrode in the interlayer insulating film and the passivation film among the hydrogen barrier film on the upper electrode, the interlayer insulating film, and the passivation film, and

a step of forming a liquid contact film on an entire inner surface of the opening and on an upper surface of the passivation film.

A14. The method for manufacturing an inkjet printing head according to “A12.” or “A13.,” wherein the wiring formation step includes

a step of forming an upper contact hole that exposes a part of the upper surface of the upper electrode and a lower contact hole that exposes a part of an upper surface of the lower electrode, the upper and lower contact holes penetrating continuously through the interlayer insulating film and the hydrogen barrier film,

a step of forming a wiring film on the interlayer insulating film including an inside of the upper contact hole and the lower contact hole, and

a step of patterning the wiring film to form the upper wiring and the lower wiring.

### [3] With Respect to Third Disclosure

A third disclosure described below can be extracted from the description of the specification concerning the preferred embodiment of the first disclosure mentioned above and from the description of FIGS. 1 to 15.

### [3-1] Object of Third Disclosure

An object of the third disclosure is to provide an inkjet printing head capable of simplifying a step of bonding the protective substrate to the actuator substrate and to provide a method for manufacturing the inkjet printing head.

### [3-2] Arrangement of Third Disclosure

B1. An inkjet printing head including,

an actuator substrate that has an ink flow passage including a pressure chamber,

a movable film formation layer that is disposed on the pressure chamber and that includes a movable film defining a top surface portion of the pressure chamber,

a piezoelectric element disposed on the movable film, and

a protective substrate bonded to the actuator substrate so as to cover the piezoelectric element,

wherein the protective substrate is bonded to the actuator substrate via the adhesive layer, and

the adhesive layer includes an adhesion strengthening layer formed on an actuator substrate side and a photosensitive adhesive agent layer formed on the adhesion strengthening layer.

With the present arrangement, it becomes possible to simplify a step of bonding the protective substrate to the actuator substrate.

B2. The inkjet printing head according to “B1.,” wherein the protective substrate has a housing concave that is opened toward the actuator substrate and that houses the piezoelectric element and an ink passage in communication with the ink flow passage.

B3. The inkjet printing head according to “B1.” or “B2.,” further including,

a hydrogen barrier film covering at least a part of a front surface of the piezoelectric element,

an interlayer insulating film formed on the movable film formation layer so as to cover the hydrogen barrier film,

a wiring that is formed on the interlayer insulating film and that is connected to the piezoelectric element, and

a covering insulating film that is formed on the interlayer insulating film and that covers the wiring,

wherein the adhesion strengthening layer is formed on the covering insulating film.

B4. The inkjet printing head according to “B3.,” wherein the covering insulating film includes

a passivation film that is formed on the interlayer insulating film and that covers the wiring, and

a liquid contact film formed on the passivation film.

B5. The inkjet printing head according to any one of “B1.” to “B4.,” wherein the piezoelectric element includes a lower electrode disposed on the movable film, a piezoelectric film formed on the lower electrode, and an upper electrode formed on the piezoelectric film, and

the wiring includes an upper wiring connected to the upper electrode and a lower wiring connected to the lower electrode.

B6. The inkjet printing head according to “B5.,” wherein an upper contact hole that exposes a part of an upper surface of the upper electrode is formed in the hydrogen barrier film formed on the upper surface of the upper electrode and the interlayer insulating film, and an end portion of the upper wiring is connected to the upper electrode via the upper contact hole, and

a lower contact hole that exposes a part of an upper surface of the lower electrode is formed in the hydrogen barrier film formed on the upper surface of the lower electrode and the interlayer insulating film, and an end portion of the lower wiring is connected to the lower electrode via the lower contact hole.

B7. The inkjet printing head according to any one of “B1.” to “B6.,” further including a nozzle substrate that is bonded to a front surface of the actuator substrate at an opposite side of a front surface on the movable film side, that defines a bottom surface portion of the pressure chamber, and that has a nozzle hole in communication with the pressure chamber.

B8. A method for manufacturing an inkjet printing head, the method including,

a step of forming a piezoelectric element constituted of a lower electrode, a piezoelectric film formed on the lower electrode, and an upper electrode formed on the piezoelectric film on an actuator substrate,

a step of forming a hydrogen barrier film that covers the piezoelectric element on the actuator substrate,

a step of forming an interlayer insulating film that covers the hydrogen barrier film on the actuator substrate,

a wiring formation step of forming an upper wiring one end of which is connected to the upper electrode and a lower wiring one end of which is connected to the lower electrode on the interlayer insulating film,

an insulating film formation step of forming a covering insulating film that covers the upper wiring and the lower wiring on a front surface of the interlayer insulating film,

a first application step of applying an adhesion strengthening agent onto the covering insulating film by a spin coating method,

a second application step of applying a photosensitive adhesive agent onto the liquid contact film by the spin coating method,

a step of patterning the photosensitive adhesive agent by the photosensitive adhesive agent being exposed and developed, and

a step of bonding a protective substrate that covers the piezoelectric element to the actuator substrate via the photosensitive adhesive agent.

B9. The method for manufacturing an inkjet printing head according to “B8.,” further including,

a first baking step of baking the adhesion strengthening agent after completing the first application step, and

a second baking step of baking the photosensitive adhesive agent after completing the second application step.

B10. The method for manufacturing an inkjet printing head according to “B8.” or “B9.,” wherein the insulating film formation step includes

a step of forming a passivation film that covers the upper wiring and the lower wiring on the front surface of the interlayer insulating film, and

a step of forming a liquid contact film on an upper surface of the passivation film, and

wherein the covering insulating film includes a laminated film constituted of the passivation film and the liquid contact film.

B11. The method for manufacturing an inkjet printing head according to “B8.” or “B9.,” wherein the insulating film formation step includes

a step of forming a passivation film that covers the upper wiring and the lower wiring on the front surface of the interlayer insulating film,

a step of forming an opening that exposes a part of an upper surface of the upper electrode in the hydrogen barrier film on the upper electrode, the interlayer insulating film, and the passivation film, and

a step of forming a liquid contact film on an entire inner surface of the opening and on the upper surface of the passivation film, and

wherein the covering insulating film includes a laminated film constituted of the passivation film and the liquid contact film.

B12. The method for manufacturing an inkjet printing head according to any one of “B8.” to “B11.,” wherein the wiring formation step includes

a step of forming an upper contact hole that exposes a part of the upper surface of the upper electrode and a lower contact hole that exposes a part of an upper surface of the lower electrode, the upper and lower contact holes penetrating continuously through the interlayer insulating film and the hydrogen barrier film,

a step of forming a wiring film on the interlayer insulating film including an inside of the upper contact hole and the lower contact hole, and

a step of patterning the wiring film to form the upper wiring and the lower wiring.

B13. The method for manufacturing an inkjet printing head according to any one of “B8.” to “B12.,” further including a step of bonding a nozzle substrate that defines a bottom surface portion of the pressure chamber and that has a nozzle hole in communication with the pressure chamber to a front surface of the actuator substrate at an opposite side of a front surface on the movable film side.

Although, in the preferred embodiment described above, the first liquid contact film 31 is formed on the passivation film 30, the first liquid contact film 31 may be omitted. In that case, the passivation film 30 serves as an example of the “covering insulating film” of the third disclosure.

### [4] With Respect to Fourth Disclosure

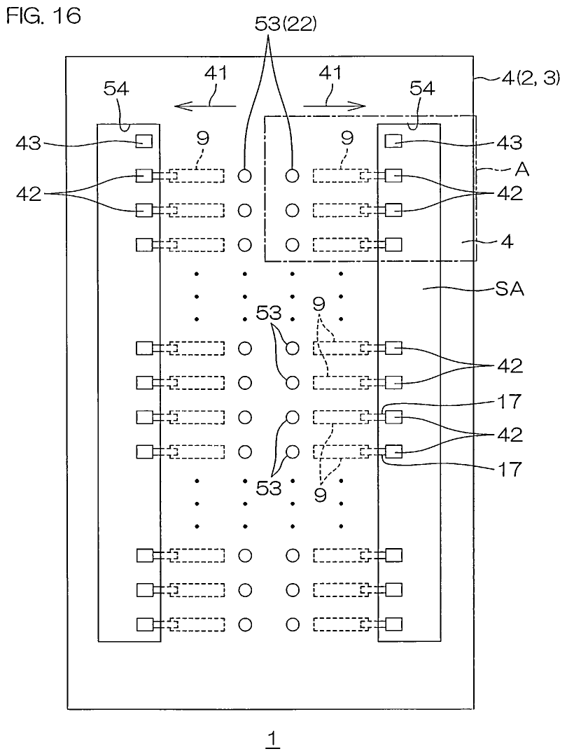

The fourth disclosure will be hereinafter described with reference to FIG. 16 to FIG. 31. Reference signs shown in FIG. 16 to FIG. 31 have no relation to reference signs shown in FIG. 1 to FIG. 15.

### [4-1] Object of Fourth Disclosure

Japanese Patent Application Publication No. 2018-69685 discloses an inkjet printing head. The inkjet printing head of Japanese Patent Application Publication No. 2018-69685 includes an actuator substrate having a pressure chamber serving as an ink flow passage, a movable film formed on the actuator substrate, and a piezoelectric element provided on the movable film. The inkjet printing head of Japanese Patent Application Publication No. 2018-69685 further includes a nozzle substrate that is bonded to a lower surface of the actuator substrate and that has a nozzle hole in communication with the pressure chamber, and a protective substrate that is bonded to an upper surface of the actuator substrate and that covers the piezoelectric element. The piezoelectric element is constituted of a lower electrode formed on the movable film, an upper electrode disposed on the lower electrode, and a piezoelectric film sandwiched therebetween.

The nozzle substrate of Japanese Patent Application Publication No. 2018-69685 includes a silicon substrate having a first front surface and a second front surface, a silicon oxide film formed on the second front surface of the silicon substrate, and a water-repellent film formed on a front surface of the silicon oxide film. The nozzle substrate has a nozzle hole that penetrates through the nozzle substrate in a thickness direction.

In an inkjet type recording apparatus including this type of inkjet printing head, ink adheres to the second front surface of the nozzle substrate in some cases, and therefore this apparatus includes a wiping mechanism that wipes the second front surface with a wiping member, such as a wiper.

However, there has been a concern that the water-repellent film formed on the second front surface will be damaged, and will be degraded when the second front surface of the nozzle substrate is wiped by the wiping mechanism. A problem resides in that a contact angle, a contact perimeter length, etc., with respect to the inner surface of the nozzle hole of a meniscus will change, and ink-discharging performance will change if the water-repellent film is degraded.

An object of the fourth disclosure is to provide a nozzle substrate capable of preventing a change in ink-discharging performance and to restrain a method for manufacturing the nozzle substrate.

Also, an object of the fourth disclosure is to provide an inkjet printing head including a nozzle substrate capable of restraining a change in ink-discharging performance.

### [4-2] Arrangement of Fourth Disclosure

C1. A nozzle substrate including,

a main substrate that has a first front surface and a second front surface and that has a nozzle hole penetrating through in a thickness direction,

an adhesion layer formed at a part of an exposed surface of the main substrate, and

a water-repellent film formed on a front surface of the adhesion layer on a side opposite to the main substrate side,

wherein the nozzle hole is constituted of a concave portion formed in the first front surface of the main substrate, and an ink discharge passage that is formed in a bottom surface of the concave portion, that penetrates through a bottom wall of the concave portion, and that has an ink discharge port on the second front surface side of the main substrate, and

the adhesion layer has a main adhesion layer formed on the second front surface, and an adhesion-layer entry portion that enters into an inside of the ink discharge passage from a peripheral edge portion of the ink discharge port of the main adhesion layer and that is formed on an inner surface of an ink discharge port side end portion of the ink discharge passage, and

the water-repellent film has a main water-repellent film formed on a front surface of the main adhesion layer, and a water-repellent film entry portion that extends from a peripheral edge portion of the ink discharge port of the main water-repellent film along a front surface of the adhesion-layer entry portion and a part of which enters into an inside of the ink discharge port.

With the present arrangement, the water-repellent film has the main water-repellent film formed on the front surface of the main adhesion layer and the water-repellent film entry portion that extends from the peripheral edge portion of the ink discharge port of the main water-repellent film along the front surface of the adhesion-layer entry portion and the part of which enters into the inside of the ink discharge port, and therefore it is possible to restrain a change in ink-discharging performance.

C2. The nozzle substrate according to “C1.,” wherein an entry length of a portion entering into the ink discharge passage of the water-repellent film entry portion is not less than 0.1 μm and not more than 3 μm.

C3. The nozzle substrate according to “C1.” or “C2.,” wherein the concave portion has a cylindrical shape, and the ink discharge passage has a cylindrical shape that is concentric with the concave portion and that has a cross section smaller than the concave portion.

C4. The nozzle substrate according to “C1.” or “C2.,” wherein the concave portion is formed in a circular cone shape whose cross section gradually becomes smaller from the first front surface side toward the second front surface side of the main substrate, and the ink discharge passage is formed in a cylindrical shape concentric with the concave portion.

C5. The nozzle substrate according to any one of “C1.” to “C4.,” wherein the main substrate is a silicon substrate, and the adhesion layer is a SiOC layer, and the water-repellent film is constituted of a FDTS film.

C6. The nozzle substrate according to “C5.,” wherein the silicon substrate has a thickness of not less than 40 μm and not more than 200 μm.

C7. The nozzle substrate according to “C6.,” wherein the adhesion layer has a thickness of not less than 100 Å and not more than 200 Å.

C8. The nozzle substrate according to “C7.,” wherein the water-repellent film has a thickness of not less than 30 Å and not more than 80 Å.

C9. The nozzle substrate according to “C7.” or “C8.,” wherein a laminated film constituted of the adhesion layer and the water-repellent film has a thickness of not less than 100 Å and not more than 300 Å.

C10. An inkjet printing head including,

an actuator substrate that has an ink flow passage including a pressure chamber,

a movable film formation layer that is disposed on the pressure chamber and that includes a movable film defining a top surface portion of the pressure chamber,

a piezoelectric element formed on the movable film, and

a nozzle substrate that is bonded to a front surface of the actuator substrate at an opposite side of a front surface on the movable film side, that defines a bottom surface portion of the pressure chamber, and that has a nozzle hole in communication with the pressure chamber,

wherein the nozzle substrate is the nozzle substrate of any one according to “C1.” to “C9.,” and the first front surface of the main substrate is bonded to a front surface of the actuator substrate at an opposite side of a front surface on the movable film side.

C11. The inkjet printing head according to “C10,” further including a protective substrate that is bonded to the actuator substrate so as to cover the piezoelectric element,

wherein the protective substrate has a housing concave that is opened toward the actuator substrate side and that houses the piezoelectric element, and an ink supply passage that is formed in a region outside one end of the housing concave and that is in communication with one end portion of the ink flow passage in a plan view.

C12. A method for manufacturing a nozzle substrate including,

a first step of forming a main substrate that has a first front surface and a second front surface and that has a nozzle hole constituted of a concave portion opened in the first front surface and an ink discharge passage penetrating through a bottom wall of the concave portion and having an ink discharge port on the second front surface side,

a second step of forming an adhesion layer and a water-repellent film in this order on an entirety of the exposed surface of the main substrate including the first front surface, the front second surface, and an inner surface of the nozzle hole,

a third step of affixing a masking tape constituted of a base material film and a gluing agent formed on one side of the base material film onto an outer front surface of the laminated film formed on the second front surface of the main substrate so as to cover a laminated film constituted of the adhesion layer formed on the second front surface of the main substrate and the water-repellent film and the ink discharge port in the ink discharge passage and so as to allow the gluing agent to enter into an inside of an ink discharge port side end portion of the ink discharge passage,

a fourth step of removing a part, which excludes a first part formed on the second front surface of the main substrate and a second part formed in the inner surface of the ink discharge port side end portion of the ink discharge passage, of the laminated film by etching the laminated film using the masking tape as a mask, and

a fifth step of removing the masking tape.

C13. The method for manufacturing a nozzle substrate according to “C12.,” wherein an entry length of a portion entering into the ink discharge passage of the second part is not less than 0.1 μm and not more than 3 μm.

C14. The method for manufacturing a nozzle substrate according to “C12.” or “C13.,” wherein the concave portion has a cylindrical shape, and the ink discharge passage has a cylindrical shape that is concentric with the concave portion and that has a cross section smaller than the concave portion.

C15. The method for manufacturing a nozzle substrate according to “C12.” or “C13.,” wherein the concave portion is formed in a circular cone shape whose cross section gradually becomes smaller from the first front surface side toward the second front surface side of the main substrate, and the ink discharge passage is formed in a cylindrical shape concentric with the concave portion.

C16. The method for manufacturing a nozzle substrate according to any one of “C12.” to “C15.,” wherein the main substrate is a silicon substrate, and the adhesion layer is a SiOC layer, and the water-repellent film is constituted of a FDTS film.

### [4-3] Preferred Embodiment of Fourth Disclosure

A preferred embodiment of the fourth disclosure will be hereinafter described in detail with reference to FIG. 16 to FIG. 31.

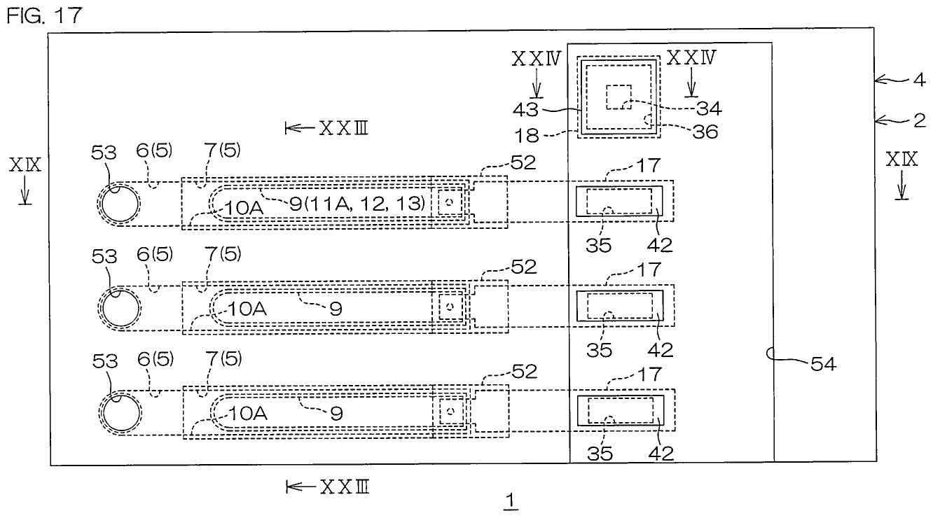

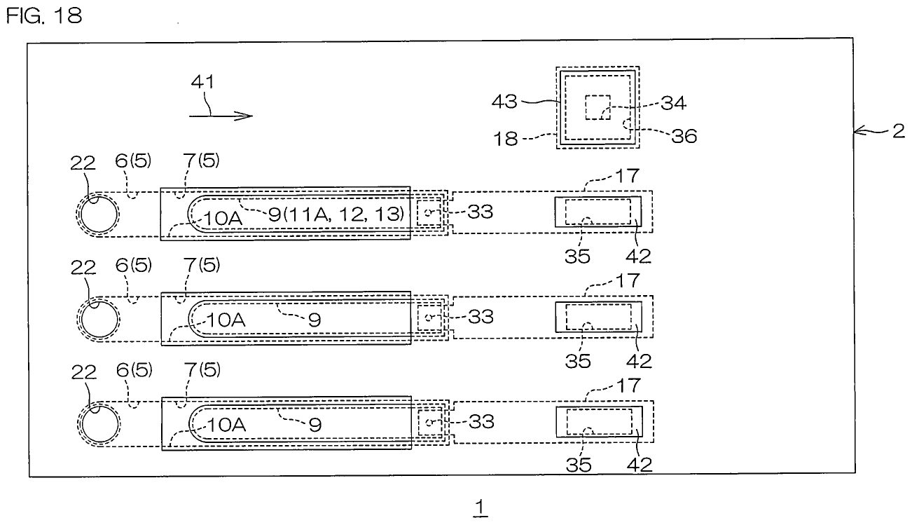

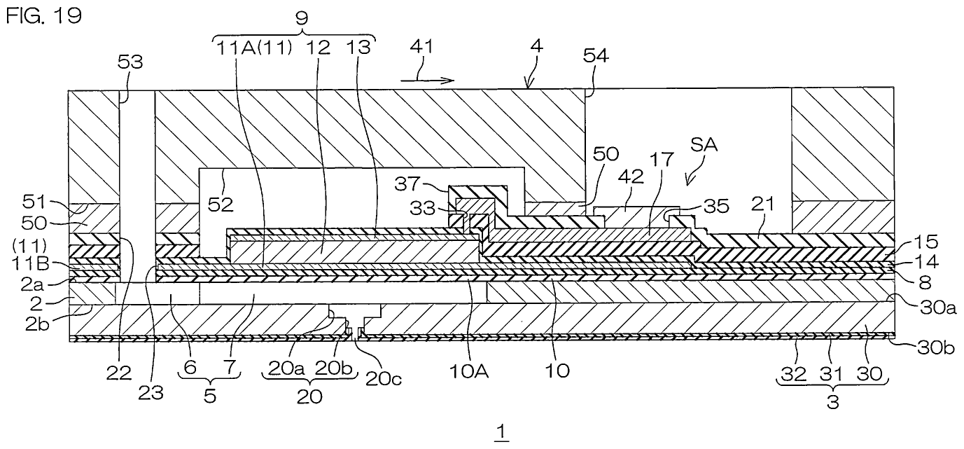

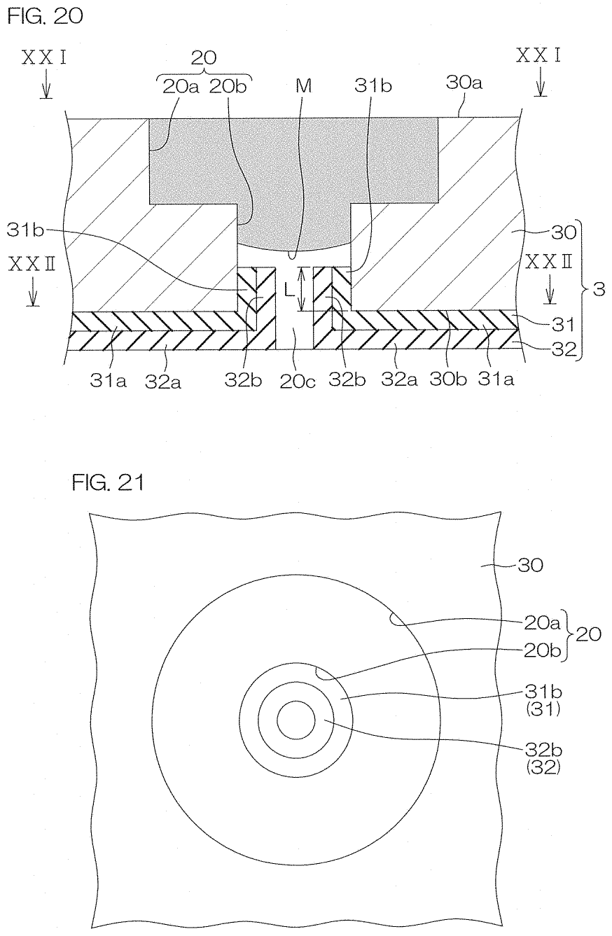

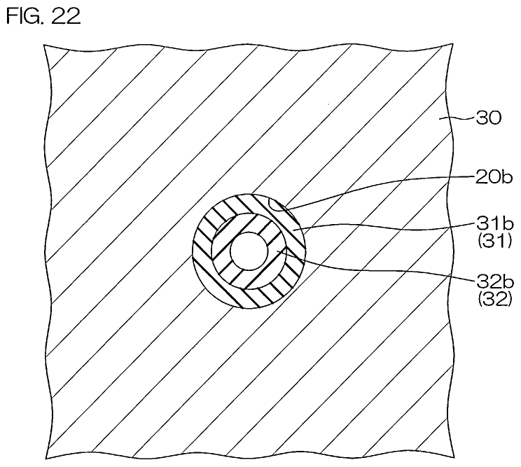

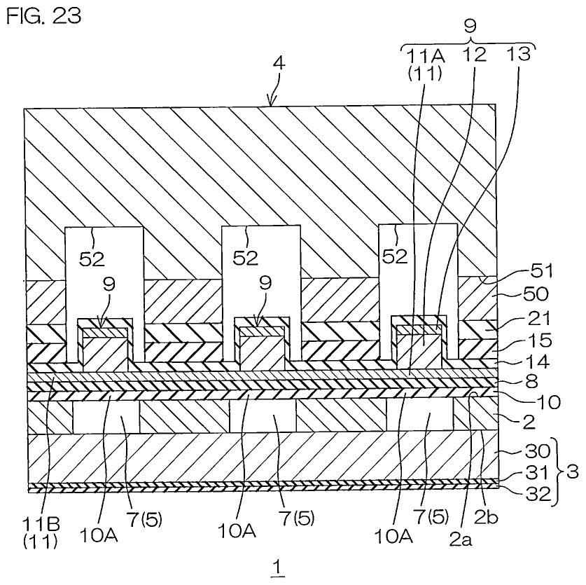

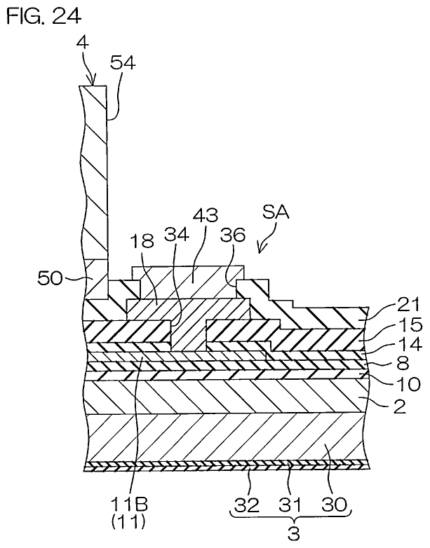

FIG. 16 is an illustrative plan view for describing an arrangement of an inkjet printing head according to a preferred embodiment of the fourth disclosure. FIG. 17 is an illustrative partially enlarged plan view showing an A portion of FIG. 16 in enlarged manner, and is a plan view that includes a protective substrate. FIG. 18 is an illustrative partially enlarged plan view showing the A portion of FIG. 16 in enlarged manner, and is a plan view from which the protective substrate is omitted. FIG. 19 is an illustrative sectional view taken along line XIX-XIX in FIG. 17. FIG. 20 is an enlarged sectional view showing a nozzle hole of FIG. 19 in enlarged manner. FIG. 21 is a plan view as viewed from arrow-line XXI-XXI of FIG. 20. FIG. 22 is an illustrative sectional view taken along line XXII-XXII in FIG. 20. FIG. 23 is an illustrative sectional view taken along line XXIII-XXIII in FIG. 17. FIG. 24 is an illustrative sectional view taken along line XXIV-XXIV in FIG. 17.

The arrangement of an inkjet printing head 1 will be roughly described with reference to FIG. 19.

The inkjet printing head 1 includes an actuator substrate assembly SA including an actuator substrate 2 and a piezoelectric element 9, a nozzle substrate 3, and a protective substrate 4. The actuator substrate assembly SA is hereinafter referred to as a substrate assembly SA.

A movable film formation layer 10 is laminated on a front surface 2a of the actuator substrate 2. An ink flow passage (ink reservoir) 5 is formed in the actuator substrate 2. In the present preferred embodiment, the ink flow passage 5 is formed so as to penetrate through the actuator substrate 2. The ink flow passage 5 is formed so as to be elongate along an ink flow direction 41 indicated by an arrow in FIG. 19. The ink flow passage 5 is constituted of an ink inflow portion 6 at an upstream side end portion (left end portion in FIG. 19) in the ink flow direction 41 and a pressure chamber 7 in communication with the ink inflow portion 6. In FIG. 19, a boundary between the ink inflow portion 6 and the pressure chamber 7 is indicated by an alternate long and two short dashed line.

The nozzle substrate 3 includes a first front surface 30a that is a front surface on the pressure chamber 7 side, a second front surface 30b that is a front surface on a side opposite to the pressure chamber 7 side, and a silicon substrate 30 having a nozzle hole 20 penetrating through in a thickness direction as shown in FIG. 19 to FIG. 22. The silicon substrate 30 is an example of a “main substrate” in the present invention. The nozzle substrate 3 further includes an adhesion layer 31 formed on a part of an exposed surface excluding the first front surface 30a of the silicon substrate 30 and a water-repellent film 32 formed on a front surface of the adhesion layer 31 on a side opposite to the silicon substrate 30. In FIG. 20, M designates a meniscus that is a front surface of ink inside the nozzle hole 20.

The nozzle substrate 3 is adhered to a rear surface 2b of the actuator substrate 2 in a state in which the first front surface 30a of the silicon substrate 30 faces the rear surface 2b of the actuator substrate 2. The nozzle substrate 3, together with the actuator substrate 2 and the movable film formation layer 10, defines the ink flow passage 5. More specifically, the nozzle substrate 3 defines a bottom surface portion of the ink flow passage 5.

The nozzle hole 20 is constituted of a concave portion 20a facing the pressure chamber 7 and an ink discharge passage 20b formed in a bottom surface of the concave portion 20a. The concave portion 20a is formed in the first front surface 30a of the silicon substrate 30. The ink discharge passage 20b is formed in a bottom surface of the concave portion 20a, and penetrates through a bottom wall of the concave portion 20a. The ink discharge passage 20b has an ink discharge port 20c on the second front surface 30b side of the silicon substrate 30.

The concave portion 20a has a cylindrical shape having a circular cross section. The ink discharge passage 20b has a cylindrical shape having a circular cross section concentric with the concave portion 20a. The diameter of the cross section of the ink discharge passage 20b is smaller than the diameter of the cross section of the concave portion 20a. In other words, an area of the cross section of the ink discharge passage 20b is smaller than an area of the cross section of the concave portion 20a. A thickness of the silicon substrate 30 is, for example, not less than 40 μm and not more than 200 μm, and is approximately 50 μm in the present preferred embodiment. A depth of the concave portion 20a is approximately 40 μm, and a depth of the ink discharge passage 20b is approximately 10 μm. The diameter of the cross section of the concave portion 20a is approximately 92.2 μm, and the diameter of the cross section of the ink discharge passage 20b is approximately 28.9 μm.

The adhesion layer 31 is constituted of a main adhesion layer 31a and an adhesion-layer entry portion 31b. The main adhesion layer 31a is formed on the second front surface 30b of the silicon substrate 30. The adhesion-layer entry portion 31b enters into the inside of the ink discharge passage 20b from a peripheral edge portion of the ink discharge port 20c of the main adhesion layer 31a, and is formed on an inner peripheral surface of an ink discharge port side end portion of the ink discharge passage 20b (in FIG. 20, of an end portion of the silicon substrate 30, which corresponds to a lowest end of the discharge passage 20b). The adhesion layer 31 covers the second front surface 30b of the silicon substrate 30, the inner peripheral surface of the ink discharge port side end portion of the ink discharge passage 20b, and an edge at which the inner peripheral surface of the ink discharge passage 20b and the second front surface 30b of the silicon substrate 30 intersect each other.

The water-repellent film 32 is constituted of a main water-repellent film 32a and a water-repellent film entry portion 32b. The main water-repellent film 32a is formed on a front surface of the main adhesion layer 31a. The water-repellent film entry portion 32b extends from a peripheral edge portion of the ink discharge port 20c of the main water-repellent film 32a along a front surface of the adhesion-layer entry portion 31b, and a part of the water-repellent film entry portion 32b enters into the inside of the ink discharge passage 20b. The water-repellent film 32 covers a front surface of the adhesion layer 31 on a side opposite to the silicon substrate 30.

The adhesion layer 31 is a layer provided to raise the adhesive properties of the water-repellent film 32 to the silicon substrate 30, and is constituted of an oxide film or the like. In the present preferred embodiment, the adhesion layer 31 is constituted of a silicon oxide film (SiOC film) including carbon (C). The water-repellent film 32 is formed to keep the meniscus M in an appropriate state. In the present preferred embodiment, the water-repellent film 32 is constituted of a FDTS film (perfluorodecyltrichlorosilane film). The water-repellent film 32 may be a perfluorooctyltrichlorosilane film.

The adhesion layer 31 has a thickness, for example, of not less than 100 Å (10 nm) and not more than 200 Å (20 nm), and is approximately 150 Å (15 nm) in the present preferred embodiment. The water-repellent film 32 has a thickness, for example, of not less than 30 Å (3 nm) and not more than 80 Å (8 nm), and is approximately 50 Å (5 nm) in the present preferred embodiment. A laminated film constituted of the adhesion layer 31 and the water-repellent film 32 has a thickness, for example, of not less than 100 Å (10 nm) and not more than 300 Å (30 nm). Preferably, the entry length L of the portion entering into the ink discharge passage 20b of the water-repellent film entry portion 32b is not less than 0.1 μm and not more than 3 μm.

When a volume change occurs in the pressure chamber 7, ink retained in the pressure chamber 7 passes through the ink discharge passage 20b, and is discharged from the ink discharge port 20c.

Referring to FIG. 19, a top roof portion of the pressure chamber 7 in the movable film formation layer 10 constitutes a movable film 10A. The movable film 10A (movable film formation layer 10) is constituted, for example, of a silicon oxide (SiO₂) film formed on the actuator substrate 2. In the present specification, the movable film 10A refers to a top roof portion of the movable film formation layer 10 that defines the top surface portion of the pressure chamber 7. Therefore, portions of the movable film formation layer 10 besides the top roof portion of the pressure chamber 7 do not constitute the movable film 10A.

The movable film 10A has a thickness of, for example, 0.4 μm to 2 μm. If the movable film 10A is constituted of a silicon oxide film, the thickness of the silicon oxide film may be approximately 1.2 μm.

The pressure chamber 7 is defined by the movable film 10A, the actuator substrate 2, and the nozzle substrate 3 and is formed to a substantially rectangular parallelepiped shape in the present preferred embodiment. The pressure chamber 7 may, for example, have a length of approximately 800 μm and a width of approximately 55 μm. The ink inflow portion 6 is in communication with one end portion in a longitudinal direction of the pressure chamber 7.

A metallic barrier film 8 is formed on a front surface of the movable film formation layer 10. The metallic barrier film 8 is constituted, for example, of Al₂O₃ (alumina). The metallic barrier film 8 has a thickness of approximately 50 nm to 100 nm. A piezoelectric element 9 is disposed at a position above the metallic barrier film 8 and above the movable film 10A. The piezoelectric element 9 includes a lower electrode 11 formed on the metallic barrier film 8, a piezoelectric film 12 formed on the lower electrode 11, and an upper electrode 13 formed on the piezoelectric film 12. In other words, the piezoelectric element 9 is arranged by sandwiching the piezoelectric film 12 from above and below by the upper electrode 13 and the lower electrode 11.

The upper electrode 13 may be a single film of platinum (Pt) or may have a laminated structure, for example, in which a conductive oxide film (for example, an IrO₂ (iridium oxide) film) and a metal film (for example, an Ir (iridium) film) are laminated. The upper electrode 13 may have a thickness, for example, of approximately 0.2 μm.

As the piezoelectric film 12, for example, a PZT (PbZrₓTi₁₋ₓO₃: lead zirconate titanate) film formed by a sol-gel method or a sputtering method may be applied. Such a piezoelectric film 12 is constituted of a sintered body of a metal oxide crystal. The piezoelectric film 12 is formed to be of the same shape as the upper electrode 13 in a plan view. The piezoelectric film 12 has a thickness of approximately 1 μm. The overall thickness of the movable film 10A is preferably approximately the same as the thickness of the piezoelectric film 12 or approximately ⅔ the thickness of the piezoelectric film 12. The aforementioned metallic barrier film 8 mainly prevents the escaping of metal elements (Pb, Zr, and Ti in the case where the piezoelectric film 12 is PZT) from the piezoelectric film 12 to keep the piezoelectric properties of the piezoelectric film 12 in a satisfactory state, and prevents a metal from diffusing into the movable film 10A when the piezoelectric film 12 is formed. The metallic barrier film 8 also has a function for preventing degradation of characteristics of the piezoelectric film 12 due to hydrogen reduction.

The lower electrode 11 has, for example, a two-layer structure with a Ti (titanium) film and a Pt (platinum) film being laminated successively from the metallic barrier film 8 side. Besides this, the lower electrode 11 may be formed of a single film that is an Au (gold) film, a Cr (chromium) layer, or an Ni (nickel) layer, etc. The lower electrode 11 has a main electrode portion 11A, in contact with a lower surface of the piezoelectric film 12, and an extension portion 11B extending to a region outside the piezoelectric film 12. The lower electrode 11 may have a thickness, for example, of approximately 0.2 μm.

A hydrogen barrier film 14 is formed on the piezoelectric element 9, on the extension portion 11B of the lower electrode 11, and on the metallic barrier film 8. The hydrogen barrier film 14 is constituted, for example, of Al₂O₃ (alumina). The hydrogen barrier film 14 has a thickness of approximately 50 nm to 100 nm. The hydrogen barrier film 14 is provided to prevent degradation of characteristics of the piezoelectric film 12 due to hydrogen reduction.

An insulating film 15 is laminated on the hydrogen barrier film 14. The insulating film 15 is constituted, for example, of SiO₂ or low-hydrogen SiN, etc. The insulating film 15 has a thickness of approximately 500 nm. An upper wiring 17 and a lower wiring 18 (see FIG. 17 and FIG. 24) are formed on the insulating film 15. These wirings may be constituted of a metal material including A1 (aluminum). These wirings have each a thickness, for example, of approximately 1000 nm (1 μm).

One end portion of the upper wiring 17 is disposed above one end portion (downstream side end portion in the ink flow direction 41) of the upper electrode 13. A contact hole 33, penetrating continuously through the hydrogen barrier film 14 and the insulating film 15, is formed between the upper wiring 17 and the upper electrode 13. The one end portion of the upper wiring 17 enters into the contact hole 33 and is connected to the upper electrode 13 inside the contact hole 33. From above the upper electrode 13, the upper wiring 17 crosses an outer edge of the pressure chamber 7 and extends outside the pressure chamber 7. The lower wiring 18 will be described later.

A passivation film 21, covering the upper wiring 17, the lower wiring 18, and the insulating film 15, is formed on the insulating film 15. The passivation film 21 is constituted, for example, of SiN (silicon nitride). The passivation film 21 may have a thickness, for example, of approximately 800 nm.

A pad opening 35 that exposes a part of the upper wiring 17 is formed in the passivation film 21. The pad opening 35 is formed in a region outside a pressure chamber 7 and is formed, for example, at a tip portion (end portion at an opposite side of the contact portion with the upper electrode 13) of the upper wiring 17. An upper electrode pad 42 that covers a pad opening 35 is formed on the passivation film 21. The upper electrode pad 42 enters into the pad opening 35 and is connected to the upper wiring 17 inside the pad opening 35. A lower electrode pad 43 is likewise provided for the lower wiring 18 (see FIG. 17 and FIG. 24), and the lower electrode pad 43 will be described later.

An ink supply penetrating hole 22 penetrating through the passivation film 21, the insulating film 15, the hydrogen barrier film 14, the lower electrode 11, the metallic barrier film 8, and the movable film formation layer 10 is formed at a position corresponding to an end portion of the ink flow passage 5 at the ink inflow portion 6 side. A penetrating hole 23 that includes an ink supply penetrating hole 22 and that is larger than the ink supply penetrating hole 22 is formed in the lower electrode 11. The hydrogen barrier film 14 enters into a gap between the penetrating hole 23 in the lower electrode 11 and the ink supply penetrating hole 22. The ink supply penetrating hole 22 is in communication with the ink inflow portion 6.

The protective substrate 4 is constituted, for example, of a silicon substrate. The protective substrate 4 is disposed on the substrate assembly SA so as to cover the piezoelectric element 9. The protective substrate 4 is bonded to the substrate assembly SA via an adhesive 50. The protective substrate 4 has a housing recess 52 in a facing surface 51 that faces the substrate assembly SA. The piezoelectric element 9 is housed inside the housing recess 52. Further, the protective substrate 4 has formed therein an ink supply passage 53 in communication with the ink supply penetrating hole 22, and an opening portion 54 to expose the pads 42 and 43. The ink supply passage 53 and the opening portion 54 penetrate through the protective substrate 4. An ink tank (not shown) storing ink is disposed above the protective substrate 4.

The piezoelectric element 9 is formed at a position facing a pressure chamber 7 across the movable film 10A and the metallic barrier film 8. That is, the piezoelectric element 9 is formed to contact a front surface of the metallic barrier film 8 on a side opposite to the pressure chamber 7. The pressure chamber 7 is filled with ink by the ink being supplied from the ink tank to the pressure chamber 7 through the ink supply passage 53, the ink supply penetrating hole 22, and the ink inflow portion 6. The movable film 10A defines the top surface portion of the pressure chamber 7 and faces the pressure chamber 7. The movable film 10A is supported by a peripheral portion of the pressure chamber 7 of the actuator substrate 2 and has flexibility enabling deformation in a direction facing the pressure chamber 7 (in other words, in the thickness direction of the movable film 10A).

The lower wiring 18 (see FIG. 17 and FIG. 24) and the upper wiring 17 are connected to a drive circuit (not shown). Specifically, the upper electrode pad 42 and the drive circuit are connected via a connecting metal member (not shown). The lower electrode pad 43 (see FIG. 17 and FIG. 24) and the drive circuit are connected via a connecting metal member (not shown). When a drive voltage is applied from the drive circuit to the piezoelectric element 9, the piezoelectric film 12 deforms due to an inverse piezoelectric effect. The movable film 10A is thereby made to deform together with the piezoelectric element 9 to thereby bring about a volume change of the pressure chamber 7 and the ink inside the pressure chamber 7 is pressurized. The pressurized ink passes through the ink discharge passage 20b and is discharged as microdroplets from the ink discharge port 20c.

The arrangement of the inkjet printing head 1 will be described in more detail with reference to FIG. 16 to FIG. 24. In the following description, the left side of FIG. 16 is referred to as “left,” the right side of FIG. 16 is referred to as “right,” the lower side of FIG. 16 is referred to as “front,” and the upper side of FIG. 16 is referred to as “rear.”

As shown in FIG. 16, the shape in a plan view of the inkjet printing head 1 is an oblong shape that is long in a front-rear direction. In the present preferred embodiment, the planar shapes and sizes of the actuator substrate 2, the protective substrate 4, and the nozzle substrate 3 are substantially the same as the planar shape and size of the inkjet printing head 1.

In a plan view, a plurality of columns, each of which is a column of a plurality of piezoelectric elements 9 aligned in stripe form at intervals in a front-rear direction (hereinafter, referred to as “piezoelectric element column”), are provided at intervals in a left-right direction on the actuator substrate 2. For descriptive convenience, let it be supposed that two piezoelectric element columns are provided in the present preferred embodiment.

The ink flow passage 5 (pressure chamber 7) is formed for each piezoelectric element 9 in the actuator substrate 2 as shown in FIG. 17 and FIG. 18. Therefore, in a plan view, two ink flow passage columns (pressure chamber columns), each of which is constituted of a plurality of the ink flow passages 5 (pressure chambers 7) aligned in stripe form at intervals in the front-rear direction, are provided at intervals in the left-right direction in the actuator substrate 2.

A pattern of an ink flow passage column corresponding to a left-hand piezoelectric element column of FIG. 16 and a pattern of an ink flow passage column corresponding to a right-hand piezoelectric element column of FIG. 16 are patterns that are right-left symmetrical with respect to a segment connecting centers between the columns. Therefore, the ink inflow portion 6 is on the right side with respect to the pressure chamber 7 in the ink flow passage 5 included in the left-hand ink flow passage column, whereas the ink inflow portion 6 is on the left side with respect to the pressure chamber 7 in the ink flow passage 5 included in the right-hand ink flow passage column. Therefore, between the left-hand and right-hand ink flow passage columns, the ink flow directions 41 mutually opposite directions.

An ink supply penetrating hole 22 is provided for each of the plurality of ink flow passages 5 of each ink flow passage column. The ink supply penetrating hole 22 is disposed on the ink inflow portion 6. Therefore, the ink supply penetrating hole 22 for the ink flow passage 5 included in the left-hand ink flow passage column is disposed on a right end portion of the ink flow passage 5, and the ink supply penetrating hole 22 for the ink flow passage 5 included in the right-hand ink flow passage column is disposed on a left end portion of the ink flow passage 5.

In each ink flow passage column, the plurality of ink flow passages 5 are formed at equal intervals that are minute intervals (for example, of approximately 30 μm to 350 μm) in a width direction thereof. Each ink flow passage 5 is elongate along the ink flow direction 41. The ink flow passage 5 is constituted of the ink inflow portion 6 in communication with an ink supply penetrating hole 22 and the pressure chamber 7 in communication with the ink inflow portion 6. In a plan view, the pressure chamber 7 has an oblong shape that is elongate along the ink flow direction 41. That is, the top surface portion of the pressure chamber 7 has two side edges along the ink flow direction 41 and two end edges along a direction orthogonal to the ink flow direction 41. In a plan view, the ink inflow portion 6 has substantially the same width as the pressure chamber 7. An inner surface of an end portion, which is on a side opposite to the pressure chamber 7, of the ink inflow portion 6 is formed in a semicircular shape in a plan view. The ink supply penetrating hole 22 is circular in a plan view (see especially FIG. 18).

The piezoelectric element 9 has a rectangular shape that is long in the longitudinal direction of the pressure chamber 7 (movable film 10A) in a plan view. A length in a longitudinal direction of the piezoelectric element 9 is shorter than a length in the longitudinal direction of the pressure chamber 7 (movable film 10A). Respective end edges along a lateral direction of the piezoelectric element 9 are disposed at inner sides at predetermined intervals respectively from the respective corresponding end edges of the movable film 10A, as shown in FIG. 18. Also, a width in the lateral direction of the piezoelectric element 9 is narrower than a width in a lateral direction of the movable film 10A. Respective side edges along the longitudinal direction of the piezoelectric element 9 are disposed at inner sides at predetermined intervals respectively from the respective corresponding side edges of the movable film 10A.

The lower electrode 11 is formed on substantially an entirety of a front surface of the movable film formation layer 10 except a peripheral edge portion of the front surface of the movable film formation layer 10. The lower electrode 11 is a common electrode used in common for the plurality of piezoelectric elements 9. The lower electrode 11 includes the main electrode portion 11A of rectangular shape in a plan view that constitute the piezoelectric element 9 and the extension portion 11B led out from the main electrode portion 11A in a direction along the front surface of the movable film formation layer 10 to extend outside the peripheral edge of the top surface portion of the pressure chamber 7.

A length in a longitudinal direction of the main electrode portion 11A is shorter than the length in a longitudinal direction of the movable film 10A. Respective end edges of the main electrode portion 11A are disposed at inner sides at predetermined intervals respectively from the respective corresponding end edges of the movable film 10A. Also, a width in a lateral direction of the main electrode portion 11A is narrower than the width in the lateral direction of the movable film 10A. Respective side edges of the main electrode portion 11A are disposed at inner sides at predetermined intervals from the respective corresponding side edges of the movable film 10A. The extension portion 11B is a region of the entire region of the lower electrode 11 excluding the main electrode portion 11A.

In a plan view, the upper electrode 13 is formed to a rectangular shape of the same pattern as the main electrode portion 11A of the lower electrode 11. That is, a length in a longitudinal direction of the upper electrode 13 is shorter than the length in the longitudinal direction of the movable film 10A. Respective end edges of the upper electrode 13 are disposed at inner sides at predetermined intervals respectively from the respective corresponding end edges of the movable film 10A. Also, a width in a lateral direction of the upper electrode 13 is narrower than the width in the lateral direction of the movable film 10A. Respective side edges of the upper electrode 13 are disposed at inner sides at predetermined intervals from the respective corresponding side edges of the movable film 10A.

In a plan view, the piezoelectric film 12 is formed to a rectangular shape of the same pattern as the upper electrode 13. That is, a length in a longitudinal direction of the piezoelectric film 12 is shorter than the length in the longitudinal direction of the movable film 10A. Respective end edges of the piezoelectric film 12 are disposed at inner sides at predetermined intervals respectively from the respective corresponding end edges of the movable film 10A. Also, a width in a lateral direction of the piezoelectric film 12 is narrower than the width in the lateral direction of the movable film 10A. Respective side edges of the piezoelectric film 12 are disposed at inner sides at predetermined intervals from the respective corresponding side edges of the movable film 10A. A lower surface of the piezoelectric film 12 contacts an upper surface of the main electrode portion 11A of the lower electrode 11 and an upper surface of the piezoelectric film 12 contacts a lower surface of the upper electrode 13.

The upper wiring 17 extends from an upper surface of one end portion (downstream side end portion in the ink flow direction 41) of the piezoelectric element 9, along an end surface of the piezoelectric element 9 continuous to the upper surface, and extends further along a front surface of the extension portion 11B of the lower electrode 11 in a direction along the ink flow direction 41. A tip portion of the upper wiring 17 is disposed inside the opening portion 54 of the protective substrate 4.

An upper electrode pad opening 35 that exposes a central portion of a front surface of the tip portion of the upper wiring 17 is formed in the passivation film 21. An upper electrode pad 42 is provided on the passivation film 21 so as to cover the upper electrode pad opening 35. The upper electrode pad 42 is connected to the upper wiring 17 in the upper electrode pad opening 35. A plurality of the upper electrode pads 42 corresponding to the plurality of piezoelectric elements 9 in the left-hand piezoelectric element column are arranged side by side in a line in the front-rear direction at the left side of the left-hand piezoelectric element column in a plan view as shown in FIG. 16. Also, a plurality of the upper electrode pads 42 corresponding to the plurality of piezoelectric elements 9 in the right-hand piezoelectric element column are arranged side by side in a line in the front-rear direction at the right side of the right-hand piezoelectric element column in a plan view.

Referring to FIG. 16, FIG. 17, FIG. 18, and FIG. 24, the lower wiring 18 is disposed at a rear position of a left-hand pad column for the upper electrode and at a rear position of a right-hand pad column for the upper electrode in a plan view. The lower wiring 18 has a quadrangular shape in a plan view. The extension portion 11B of the lower electrode 11 is present below the lower wiring 18. A contact hole 34 that penetrates continuously through the hydrogen barrier film 14 and the insulating film 15 is formed between the lower wiring 18 and the extension portion 11B of the lower electrode 11. The lower wiring 18 enters into the contact hole 34, and is connected to the extension portion 11B of the lower electrode 11 inside the contact hole 34.

A pad opening 36 that exposes a central portion of a front surface of the lower wiring 18 is formed in the passivation film 21. The lower electrode pad 43 that covers the pad opening 36 is formed on the passivation film 21. The lower electrode pad 43 enters into the pad opening 36, and is connected to the lower wiring 18 inside the pad opening 36.

A plurality of ink supply passages 53 (hereinafter, each referred to as “first ink supply passage 53” if necessary) in communication with a plurality of the ink supply penetrating holes 22 with respect to the left-hand ink flow passage column and a plurality of ink supply passages 53 (hereinafter, each referred to as “second ink supply passage 53” if necessary) in communication with a plurality of the ink supply penetrating holes 22 with respect to the right-hand ink flow passage column are formed in the protective substrate 4 as shown in FIG. 16, FIG. 17, and FIG. 19. The first ink supply passages 53 are disposed in a line at intervals in the front-rear direction at a position that leftwardly deviates with respect to a widthwise center of the protective substrate 4 in a plan view. The second ink supply passages 53 are disposed in a line at intervals in the front-rear direction at a position that rightwardly deviates with respect to the widthwise center of the protective substrate 4 in a plan view. The ink supply passage 53 has a circular shape having a pattern same as that of the ink supply penetrating hole 22 on the actuator substrate 2 side in a plan view. The ink supply passage 53 matches the ink supply penetrating hole 22 in a plan view.

Also, the protective substrate 4 has the opening portion 54 formed to expose all the upper electrode pads 42 corresponding to the left-hand piezoelectric element column and the left-hand lower electrode pad 43. Also, the protective substrate 4 has the opening portion 54 formed to expose all the upper electrode pads 42 corresponding to the right-hand piezoelectric element column and the right-hand lower electrode pad 43. These opening portions 54 are formed in a rectangular shape that is long in the front-rear direction in a plan view.

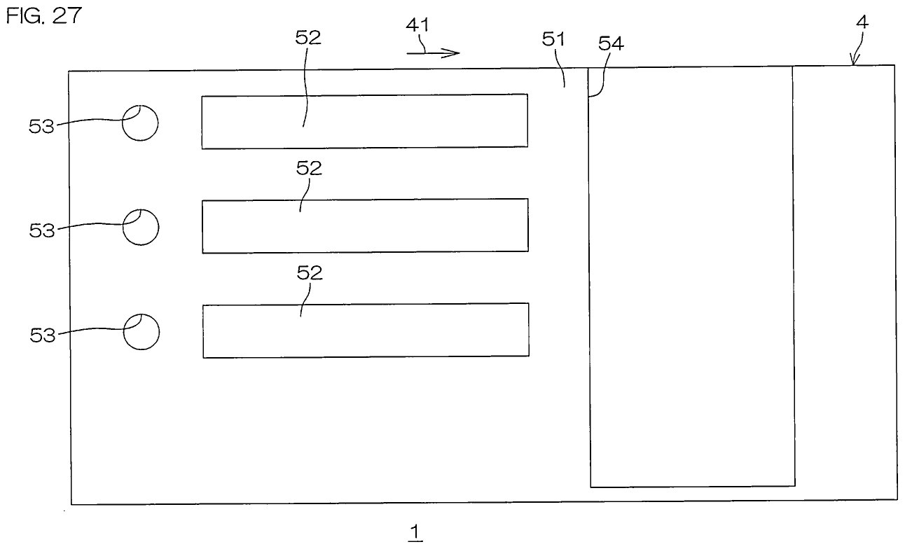

FIG. 27 is a bottom view of a region shown in FIG. 17 of the protective substrate.

As shown in FIG. 19, FIG. 23, and FIG. 27, the housing recess 52 are formed in the facing surface 51 of the protective substrate 4 respectively at positions facing the piezoelectric elements 9 inside the respective piezoelectric element columns. With respect to each housing recesses 52, the ink supply passage 53 is disposed at the upstream side in the ink flow direction 41 and the opening portion 54 is disposed at the downstream side. In a plan view, each housing recess 52 is formed to a rectangular shape slightly larger than a pattern of the upper electrode 13 of the corresponding piezoelectric element 9. The corresponding piezoelectric element 9 is housed in each housing recess 52.

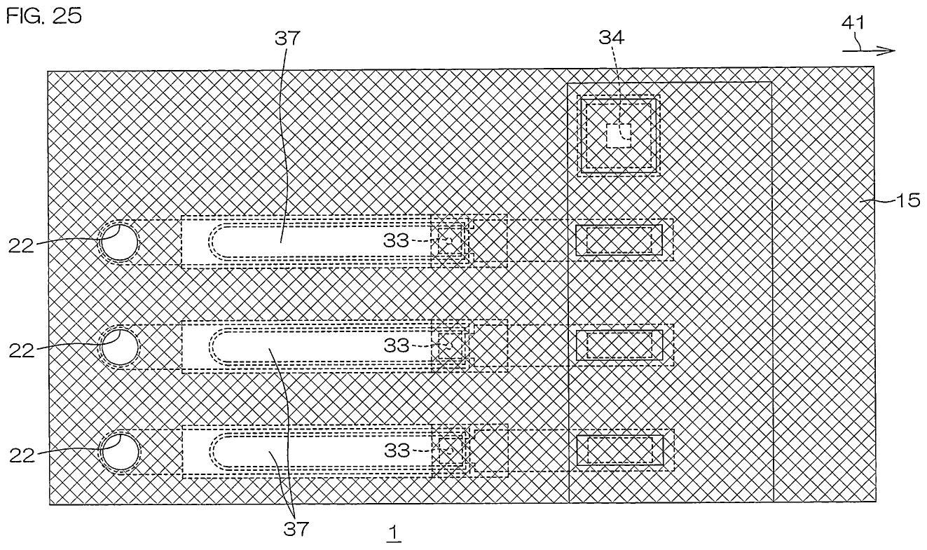

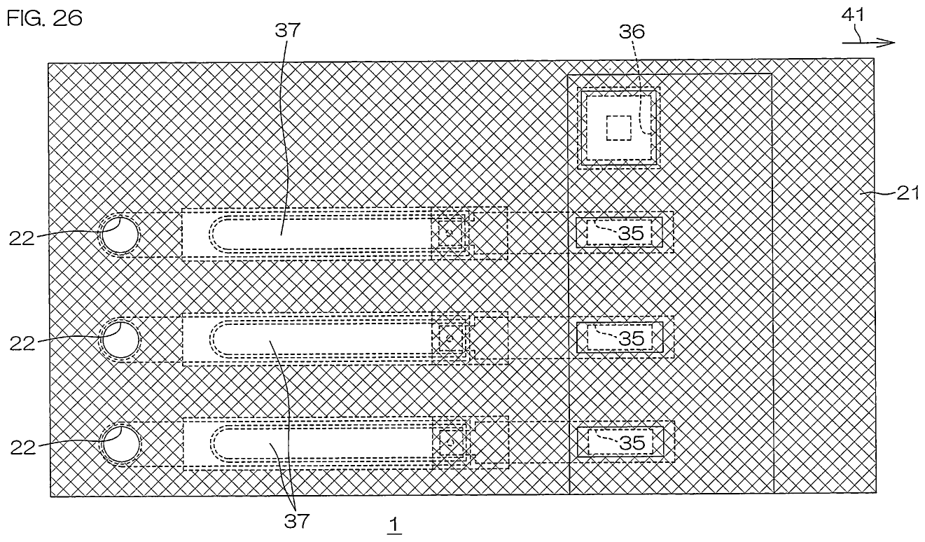

FIG. 25 is an illustrative plan view showing a pattern example of an insulating film of the inkjet printing head mentioned above. FIG. 26 is an illustrative plan view showing a pattern example of a passivation film of the inkjet printing head mentioned above.

In the present preferred embodiment, above the actuator substrate 2, the insulating film 15 and the passivation film 21 are formed on substantially an entirety of a region of the protective substrate 4 outside the housing recesses 52 in a plan view. However, in this region, the ink supply penetrating holes 22 and the contact hole 34 are formed in the insulating film 15. In this region, the ink supply penetrating holes 22, the pad openings 35 and 36 are formed in the passivation film 21.

In the region of the protective substrate 4 at an inner side of the housing recess 52, the insulating film and the passivation film 21 are formed only in one end portion (upper wiring region) in which the upper wiring 17 is present. In this region, the passivation film 21 is formed to cover the upper surface and the side surface of the upper wiring 17 on the insulating film 15. In other words, in the insulating film 15 and the passivation film 21, an opening 37 is formed in a region, within the inner side region of the housing recess 52 in a plan view, that excludes the upper wiring region. The contact holes 33 are further formed in the insulating film 15.

A description will be given of an outline of a method for manufacturing the inkjet printing head 1.

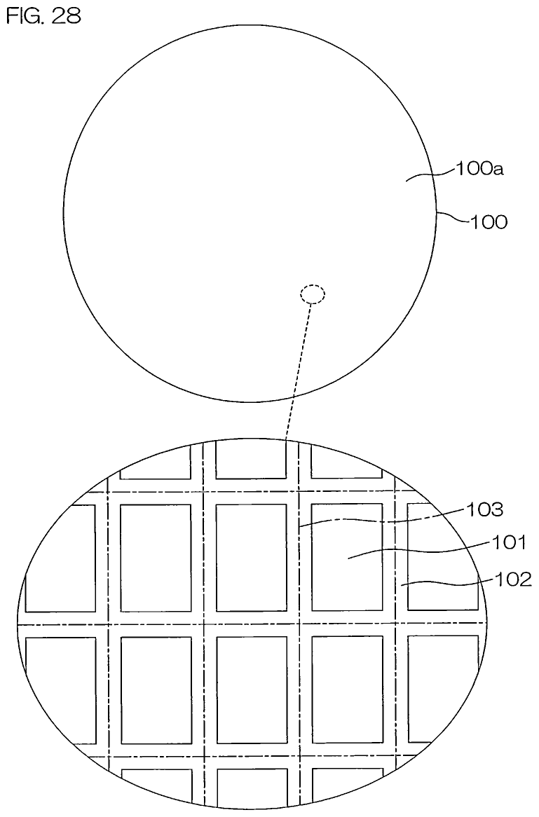

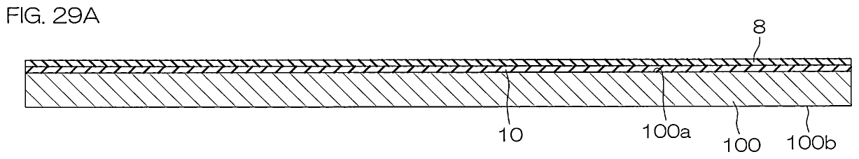

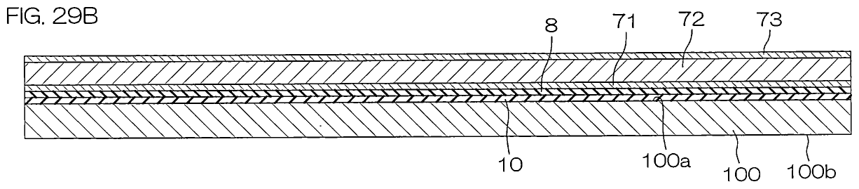

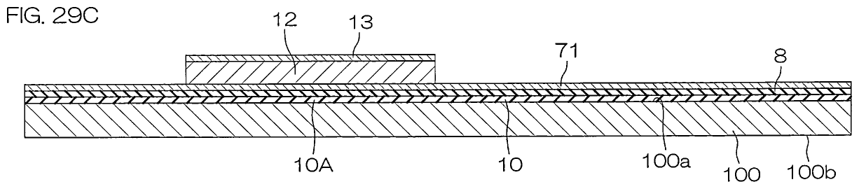

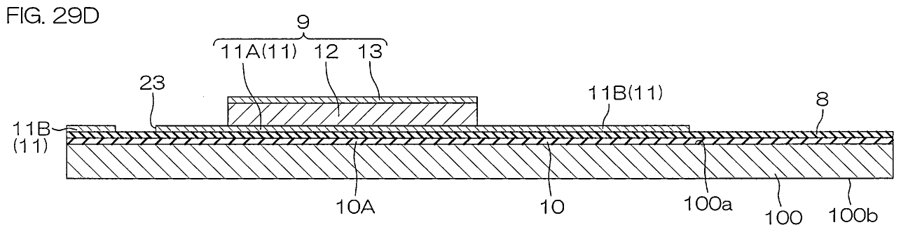

FIG. 28 is a plan view of a semiconductor wafer serving as an original substrate of an actuator substrate, and a partial region of the semiconductor wafer is shown in enlarged manner.

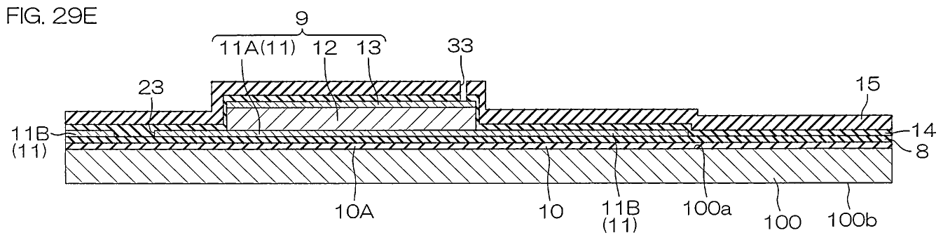

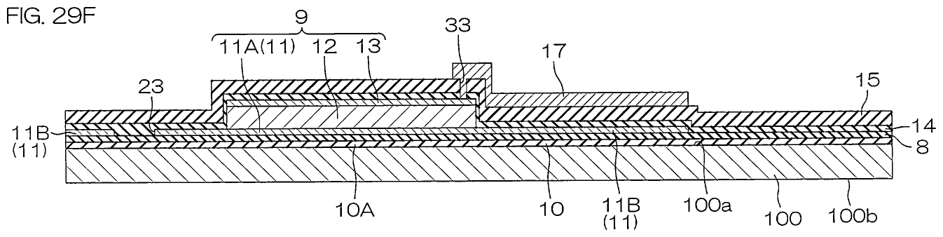

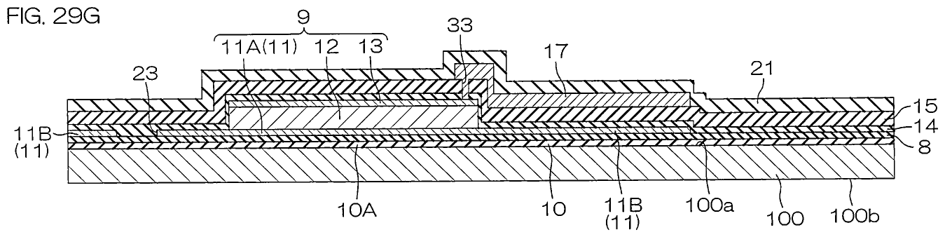

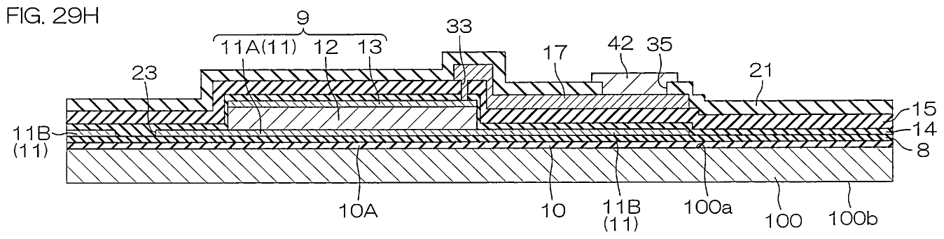

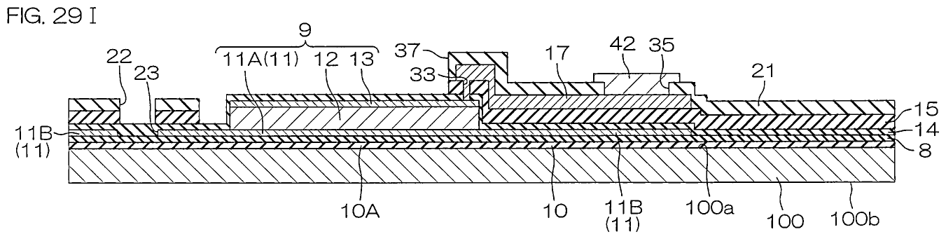

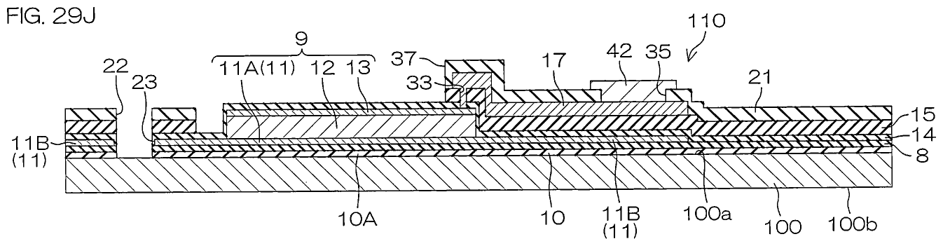

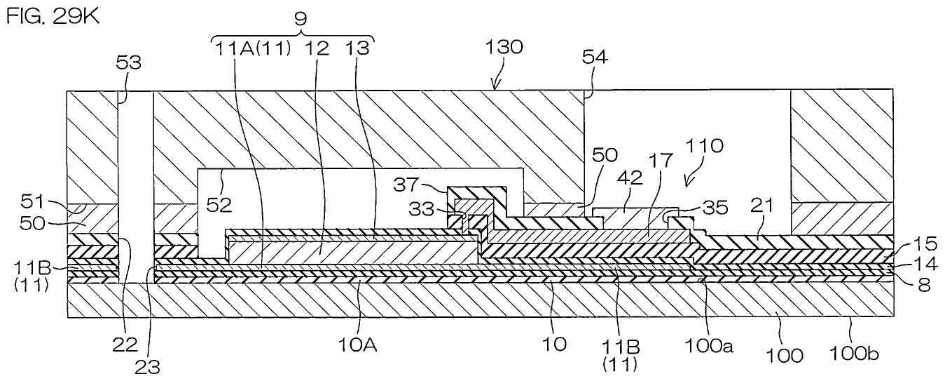

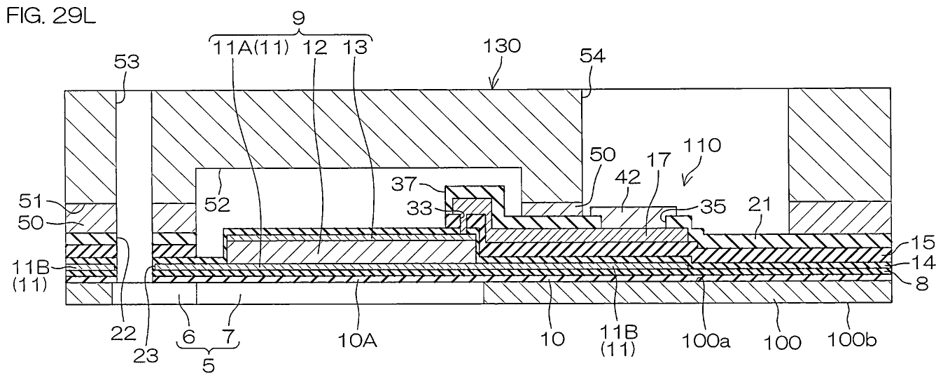

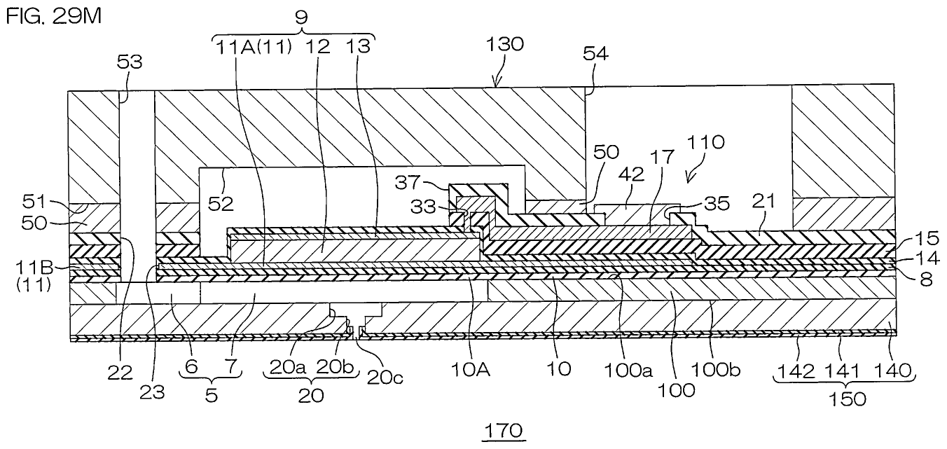

A semiconductor wafer (actuator wafer) 100 serving as an original substrate of the actuator substrate 2 is constituted, for example, of a silicon wafer. A front surface 100a of the actuator wafer 100 corresponds to a front surface 2a of the actuator substrate. A plurality of functional-element forming regions 101 are aligned and set in a matrix manner on the front surface 100a of the actuator wafer 100. A scribe region 102 (boundary region) is provided between the adjoining functional-element forming regions 101. The scribe region 102 is a belt-shaped region having a substantially constant width, and extends in two directions that perpendicularly intersect each other, and is formed in a grid-shaped manner. An intended cutting line 103 is set in the scribe region 102. A substrate assembly aggregate (SA aggregate) 110 (see FIG. 29J), in which an arrangement of substrate assemblies SA is formed although the ink flow passage 5 is not formed, is created on each of the functional-element forming regions 101 by applying a necessary process onto the actuator wafer 100.

A protective substrate aggregate 130 (see FIG. 29K) that integrally includes a plurality of protective substrates 4 corresponding to each of the functional-element forming regions 101 of the substrate assembly aggregate 110 is prepared beforehand. The protective substrate aggregate 130 is created by applying a necessary process onto a semiconductor wafer (wafer for the protective substrate) serving as an original substrate of the protective substrate 4. The wafer for the protective substrate is constituted, for example, of a silicon wafer.

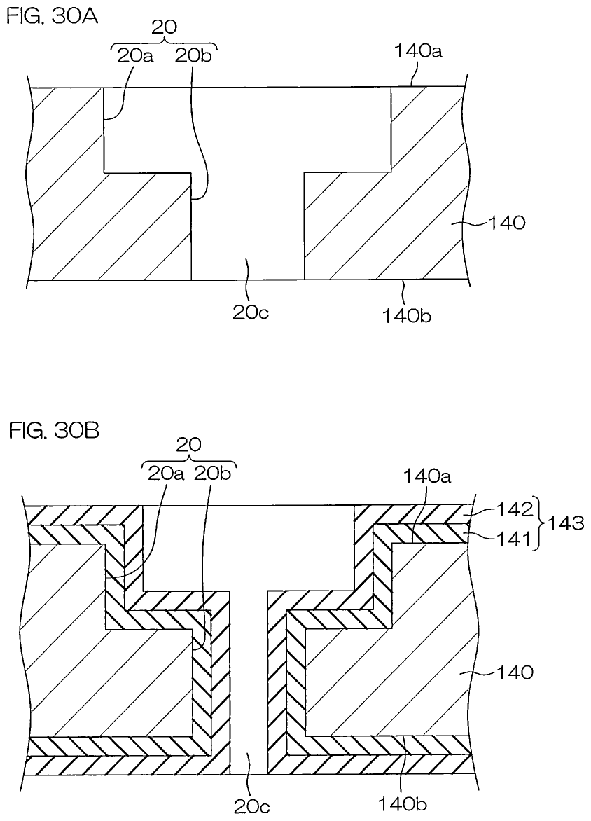

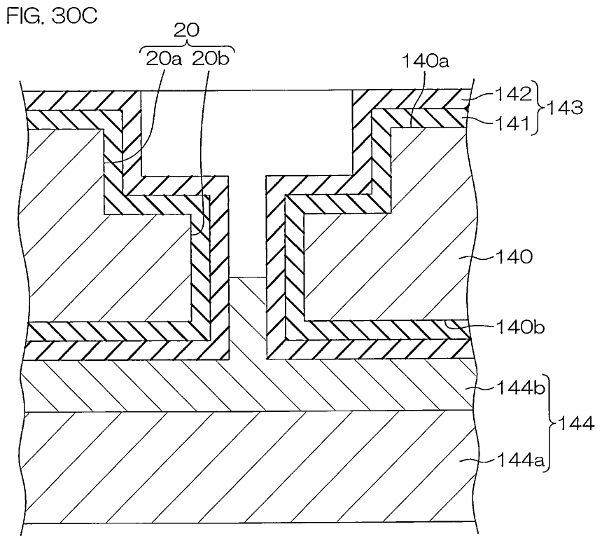

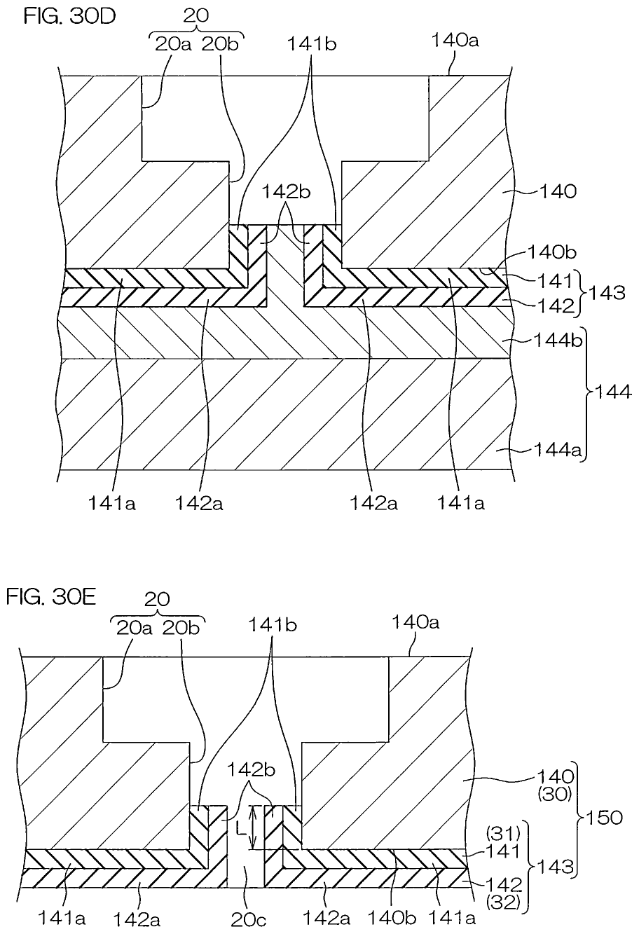

Also, a nozzle substrate aggregate 150 (see FIG. 29M and FIG. 30E) that integrally includes a plurality of nozzle substrates 3 corresponding to each of the functional-element forming regions 101 of the substrate assembly aggregate 110 is prepared beforehand. The nozzle substrate aggregate 150 is created by applying a necessary process onto a semiconductor wafer (nozzle wafer) serving as an original substrate of the nozzle substrate 3. The nozzle wafer is constituted, for example, of a silicon wafer. The nozzle substrate aggregate 150 is constituted of a nozzle wafer 140, an adhesion material film 141 that is a material film of the adhesion layer 31 formed on a part of an exposed surface of the nozzle wafer 140, and a water-repellent material film 142 that is a material film of the water-repellent film 32 formed on a front surface of the adhesion material film 141 as shown in FIG. 29M and FIG. 30E.

When the substrate assembly aggregate 110 is created, the protective substrate aggregate 130 is bonded to the substrate assembly aggregate 110. Next, the ink flow passage 5 is formed in the substrate assembly aggregate 110. Next, the nozzle substrate aggregate 150 is bonded to the substrate assembly aggregate 110. An inkjet printing head aggregate 170 (see FIG. 29M) constituted of the substrate assembly aggregate 110, the protective substrate aggregate 130, and the nozzle substrate aggregate 150 is thereby obtained. Thereafter, the inkjet printing head aggregate 170 is cut (diced) by a dicing blade along the intended cutting line 103 (see FIG. 28). Individual inkjet printing heads (chips) 1 including the functional-element forming region 101 are thereby cut out. As a result, the inkjet printing head 1 has the scribe region 102 at a peripheral edge portion, and has the functional-element forming region 101 in a central region surrounded by the scribe region 102 (see FIG. 28).

A method for manufacturing the inkjet printing head 1 will be hereinafter described in detail.

FIG. 29A to FIG. 29M are sectional views each of which shows a manufacturing process of the inkjet printing head 1 and each of which is a sectional view corresponding to the cutting plane of FIG. 19.

First, the actuator wafer 100 is prepared as shown in FIG. 29A. Note that a wafer has a thickness thicker than a thickness of an end-product actuator substrate 2 is used as the actuator wafer 100. Then, the movable film formation layer 10 is formed on the front surface 100a of the actuator wafer 100. Specifically, a silicon oxide film (for example, of 1.2 μm thickness) is formed on the front surface 100a of the actuator wafer 100.

Next, the metallic barrier film 8 is formed on the movable film formation layer 10. The metallic barrier film 8 is constituted, for example, of an Al₂O₃ film (for example, of 50 nm to 100 nm thickness). The metallic barrier film 8 prevents metal elements from escaping from the piezoelectric film 12 to be formed later. When metal elements escape, the piezoelectric film 12 may degrade in piezoelectric characteristics. Also, when metal elements that have escaped become mixed in the silicon layer constituting each movable film 10A, the movable film 10A may degrade in durability.

Next, as shown in FIG. 29B, a lower electrode film 71, which is a material layer of the lower electrode 11, is formed on the metallic barrier film 8. The lower electrode film 71 is constituted, for example, of a Pt/Ti laminated film having a Ti film (for example, of 10 nm to nm thickness) as a lower layer and a Pt film (for example, of 10 nm to 400 nm thickness) as an upper layer. Such a lower electrode film 71 may be formed by a sputtering method.

Next, a piezoelectric material film 72, which is a material of the piezoelectric film 12, is formed on an entire surface on the lower electrode film 71. Specifically a piezoelectric material film 72 of 1 μm to 3 μm thickness is formed, for example, by a sol-gel method. Such a piezoelectric material film 72 is constituted of a sintered body of metal oxide crystal grains.

Next, an upper electrode film 73, which is a material of the upper electrode 13, is formed on an entire surface of the piezoelectric material film 72. The upper electrode film 73 may, for example, be a single film of platinum (Pt). The upper electrode film 73 may, for example, be an IrO₂/Ir laminated film having an IrO₂ film (for example, of 40 nm to 160 nm thickness) as a lower layer and an Ir film (for example, of 40 nm to 160 nm thickness) as an upper layer. Such an upper electrode film 73 may be formed by the sputtering method.

Next, patterning of the upper electrode film 73, the piezoelectric material film 72, and the lower electrode film 71 is performed as shown in FIG. 29C and FIG. 29D. First, a resist mask with a pattern of the upper electrode 13 is formed by photolithography. Then, as shown in FIG. 29C, the upper electrode film 73 and the piezoelectric material film 72 are etched successively using the resist mask as a mask to form the upper electrode 13 and the piezoelectric film 12 of the predetermined pattern.

Next, after peeling off the resist mask, a resist mask with a pattern of the lower electrode 11 is formed by photolithography. Then, as shown in FIG. 29D, the lower electrode film 71 is etched using the resist mask as a mask to form the lower electrode 11 of the predetermined pattern. The lower electrode 11, constituted of the main electrode portion 11A and the extension portion 11B having the penetrating hole 23, is thereby formed. The piezoelectric element 9, constituted of the main electrode portion 11A of the lower electrode 11, the piezoelectric film 12, and the upper electrode 13, is thereby formed.

Next, after peeling off the resist mask, the hydrogen barrier film 14 covering the entire surface is formed as shown in FIG. 29E. The hydrogen barrier film 14 may be an Al₂O₃ film formed by the sputtering method and may have a film thickness of 50 nm to 100 nm. Thereafter, the insulating film 15 is formed on the entire surface of the hydrogen barrier film 14. The insulating film 15 may be an SiO₂ film and may have a film thickness of 200 nm to 300 nm. Next, the contact holes 33 and 34 are formed by successively etching the insulating film 15 and the hydrogen barrier film 14. In FIG. 29E, the contact hole 34 is not shown because of being placed in the far-back direction of the figure.

Next, as shown in FIG. 29F, a wiring film that constitutes the upper wirings 17 and the lower wiring 18 is formed by the sputtering method on the insulating film 15 including an inside of each of the contact holes 33 and 34. Thereafter, the wiring film is patterned by photolithography and etching to form the upper wiring 17 and the lower wiring 18 at the same time. In FIG. 29F, the lower wiring 18 is not shown because of being placed in the far-back direction of the figure.

Next, as shown in FIG. 29G, the passivation film 21 that covers each of the wirings 17 and 18 is formed on the front surface of the insulating film 15. The passivation film 21 is constituted, for example, of SiN. The passivation film 21 is formed, for example, by plasma CVD.

Next, a resist mask, having openings corresponding to the pad openings 35 and 36, is formed by photolithography, and the passivation film 21 is etched using the resist mask as a mask. The pad openings 35 and 36 are thereby formed in the passivation film 21 as shown in FIG. 29H. After peeling off the resist mask, the upper electrode pad 42 and the lower electrode pad 43 are formed on the passivation film 21 via the pad openings 35 and 36. In FIG. 29H, the pad opening 36 and the lower electrode pad 43 are not shown because of being placed in the far-back direction of the figure.

Next, a resist mask, having openings corresponding to the openings 37 and the ink supply penetrating hole 22, is formed by photolithography, and the passivation film 21 and the insulating film 15 are etched successively using the resist mask as a mask. The opening 37 and the ink supply penetrating hole 22 are thereby formed in the passivation film 21 and the insulating film 15 as shown in FIG. 29I.

Next, the resist mask is peeled off. A resist mask, having opening corresponding to the ink supply penetrating hole 22, is then formed by photolithography, and the hydrogen barrier film 14, the metallic barrier film 8, and the movable film formation layer 10 are etched using the resist mask as a mask. The ink supply penetrating hole 22 is thereby formed in the hydrogen barrier film 14, the metallic barrier film 8, and the movable film formation layer 10 as shown in FIG. 29J. The substrate assembly aggregate 110 is thereby created.

Next, as shown in FIG. 29K, the adhesive 50 is applied onto the facing surface 51 of the protective substrate aggregate 130 and the protective substrate aggregate 130 is fixed onto the substrate assembly aggregate 110 so that the ink supply passage 53 and the ink supply penetrating hole 22 corresponding thereto are matched.

Next, as shown in FIG. 29L, rear surface grinding for thinning the actuator wafer 100 is performed. The actuator wafer 100 is made thin by the actuator wafer 100 being ground from the rear surface 100b. For example, the actuator wafer 100 with a thickness of approximately 670 μm in the initial state may be thinned to a thickness of approximately 75 μm. Thereafter, a resist mask, having an opening corresponding to the ink flow passage 5 (the ink inflow portion 6 and the pressure chamber 7), is formed on the rear surface 100b side of the actuator wafer 100 by photolithography, and the actuator wafer 100 is etched from its rear surface 100b using the resist mask as a mask. The ink flow passage 5 (the ink inflow portion 6 and the pressure chamber 7) is thereby formed in the actuator wafer 100.

In the etching process, the metallic barrier film 8 formed on the front surface of the movable film formation layer 10 prevents the escaping of metal elements (Pb, Zr, and Ti in the case of PZT) from the piezoelectric film 12 and keeps the piezoelectric characteristics of the piezoelectric film 12 in a satisfactory state. Also as mentioned above, the metallic barrier film 8 contributes to maintaining the durability of the silicon layer that forms the movable film 10A.

Thereafter, the nozzle substrate aggregate 150 is adhered to the rear surface 100b of the actuator wafer 100 as shown in FIG. 29M. The inkjet printing head aggregate 170 constituted of the substrate assembly aggregate 110, the protective substrate aggregate 130, and the nozzle substrate aggregate 150 is thereby obtained. Thereafter, the inkjet printing head aggregate 170 is cut by the dicing blade along the intended cutting line 103 (see FIG. 28). That is, a step of individually cutting out the inkjet printing head 1 is performed.

When this step is completed, the actuator wafer 100 in the substrate assembly aggregate 110 becomes the actuator substrate 2 of each individual inkjet printing head 1. Also, the protective substrate aggregate 130 becomes the protective substrate 4 of each individual inkjet printing head 1. Also, the nozzle wafer 140, the adhesion material film 141, and the water-repellent material film 142 in the nozzle substrate aggregate 150 become the silicon substrate 30, the adhesion layer 31, and the water-repellent film 32, respectively, in the nozzle substrate 3 of each individual inkjet printing head 1. An individual piece of the inkjet printing head 1 having a structure shown in FIG. 16 to FIG. 24 is thus obtained.

In the inkjet printing head 1 obtained in this way, the side surface of the actuator substrate 2 and the side surface of the nozzle substrate 3 become flush with each other in all directions in a plan view (i.e., flush with each other over the entire periphery). That is, in the present preferred embodiment, the inkjet printing head 1 that has no difference in level between the actuator substrate 2 and the nozzle substrate 3 is obtained. Also, in the present preferred embodiment, the side surface of the actuator substrate 2 and the side surface of the protective substrate 4 likewise become flush with each other in all directions in a plan view (i.e., flush with each other over the entire periphery). That is, in the present preferred embodiment, the inkjet printing head 1 that likewise has no difference in level between the actuator substrate 2 and the protective substrate 4 is obtained.

In a method for manufacturing an inkjet printing head according to the present preferred embodiment, the nozzle substrate aggregate 150 is bonded to the substrate assembly aggregate 110 to which the protective substrate aggregate 130 is fixed for creating the inkjet printing head aggregate 170. Then, the inkjet printing head aggregate 170 is diced for individually cutting out the inkjet printing head 1. Therefore, it is possible to manufacture the inkjet printing head 1 more efficiently than, for example, in a case in which each individual substrate assembly SA is manufactured, and then the nozzle substrate 3 is individually bonded to each individual substrate assembly SA for manufacturing the inkjet printing head.

FIG. 30A to FIG. 30E are sectional views each of which schematically shows a manufacturing process of the nozzle substrate aggregate 150.

First, the semiconductor wafer (nozzle wafer) 140 serving as an original substrate of the nozzle substrate 3 is prepared as shown in FIG. 30A. The nozzle wafer 140 is constituted of a silicon wafer. The nozzle wafer 140 has a front surface (first front surface) 140a on the side on which the front surface 140a is allowed to face the rear surface 2b of the actuator substrate 2 and a rear surface (second front surface) 140b on the opposite side.

A resist mask, having an opening corresponding to the concave portion 20a, is formed by photolithography, and the nozzle wafer 140 is etched using the resist mask as a mask to form the concave portion 20a in the first front surface 140a of the nozzle wafer 140. Thereafter, the cylindrical ink discharge passage 20b is formed by, for example, a Bosch process. The ink discharge passage 20b has the ink discharge port 20c on the second front surface 140b side of the nozzle wafer 140. The nozzle hole 20 constituted of the concave portion 20a and the ink discharge passage 20b is thereby formed in the nozzle wafer 140. Then, the resist mask is removed.

Next, the adhesion material film 141 that is a material film of the adhesion layer 31 and the water-repellent material film 142 that is a material film of the water-repellent film 32 are formed in this order on an entirety of the exposed surface of the nozzle wafer 140 including the first front surface 140a and the second front surface 140b of the nozzle wafer 140 and including the inner surface of the nozzle hole 20 as shown in FIG. 30B. A laminated film 143 constituted of the adhesion material film 141 and the water-repellent material film 142 is thereby formed on the entirety of the exposed surface of the nozzle wafer 140. The adhesion material film 141 and the water-repellent material film 142 are formed by, for example, CVD (chemical vapor deposition). The adhesion material film 141 and the water-repellent material film 142 may be formed by MCV (Molecular Vapor Deposition) (registered trademark) that is one procedure of the CVD method. In the present preferred embodiment, BTCSE (trichlorosilyl ethane) gas is used in order to form the adhesion material film 141, and FDTS (perfluorodecyltrichlorosilane) gas is used in order to form the water-repellent material film 142. The water-repellent material film 142 may be formed by use of perfluorooctyltrichlorosilane gas.

Next, a masking tape 144 is affixed onto the laminated film 143 formed on the second front surface 140b of the nozzle wafer 140 so as to cover the laminated film 143 formed on the second front surface 140b of the nozzle wafer 140 and the ink discharge port 20c as shown in FIG. 30C. The masking tape 144 is a tape in which a gluing agent 144b has been applied to one surface of a base material film 144a. The base material film 144a has a thickness of approximately 115 μm, and the gluing agent 144b has a thickness of approximately 15 μm.

A step of affixing the masking tape 144 onto the second front surface 140b of the nozzle wafer 140 is performed by an operator. For example, the operator performs the following operations. First, the tape is drawn out from a roll. Next, the wafer and the tape are brought into a closely attached state. Next, the tape is pressed against the wafer with a roller. Next, the tape is cut so as to be circular.

The masking tape 144 is affixed onto the laminated film 143 such that the gluing agent 144b of the masking tape 144 enters into an ink discharge port side end portion of the ink discharge passage 20b. The laminated film 143 formed on the inner surface of the ink discharge port side end portion of the ink discharge passage 20b is thereby covered with the gluing agent 144b.

Next, the laminated film 143 is etched by plasma etching using the masking tape 144 as a mask as shown in FIG. 30D. A part of the laminated film 143 is thereby removed excluding both a first part, which is formed on the second front surface 140b of the nozzle wafer 140, of the laminated film 143 and a second part, which is formed on the inner surface of the ink discharge port side end portion of the ink discharge passage 20b. The first part corresponds to a laminated film part constituted of a main adhesion layer 41a and a main water-repellent film 42a of FIG. 20, and the second part corresponds to a laminated film part constituted of an adhesion-layer entry portion 41b and a water-repellent film entry portion 42b of FIG. 20.

In FIG. 30D, reference sign 141a is assigned to a part, which corresponds to the main adhesion layer 41a, of the adhesion material film 141, and reference sign 141b is assigned to a part, which corresponds to the adhesion-layer entry portion 41b, of the adhesion material film 141. Likewise, reference sign 142a is assigned to a part, which corresponds to the main water-repellent film 42a, of the water-repellent material film 142, and reference sign 142b is assigned to a part, which corresponds to the water-repellent film entry portion 42b, of the water-repellent material film 142.

Finally, the masking tape 144 is peeled off as shown in FIG. 30E. The nozzle substrate aggregate 150 is thereby obtained, which is constituted of the nozzle wafer 140 having the nozzle hole 20, the adhesion material film 141 formed in a predetermined region of the exposed surface of the nozzle wafer 140, and the water-repellent material film 142 formed on the front surface on a side opposite to the nozzle wafer 140 of the adhesion material film 141.

The nozzle substrate aggregate 150 obtained in this way is affixed to the rear surface 100b of the actuator wafer 100 of the substrate assembly aggregate 110.

In the present preferred embodiment, the adhesion layer 31 has the main adhesion layer 31a formed on the second front surface 30b of the silicon substrate 30 and the adhesion-layer entry portion 31b that enters into the inside of the ink discharge passage 20b from a peripheral edge portion of the ink discharge port 20c of the main adhesion layer 31a and that is formed on the inner surface of the ink discharge port side end portion of the ink discharge passage 20b. Also, the water-repellent film 32 has the main water-repellent film 32a formed on the front surface of the main adhesion layer 31 and the water-repellent film entry portion 32b that extends from the peripheral edge portion of the ink discharge port 20c of the main water-repellent film 32a along the front surface of the adhesion-layer entry portion 31b and a part of which enters into the inside of the ink discharge passage 20b.

There is a concern that the main water-repellent film 32a formed on the second front surface 30b will be degraded by the second front surface 30b of the silicon substrate 30 being wiped by the wiping mechanism. However, the portion entering into the inside of the ink discharge passage 20b of the water-repellent film entry portion 32b is not wiped out by the wiping mechanism even when the second front surface 30b of the silicon substrate 30 is wiped out by the wiping mechanism, and therefore that part is not easily degraded. This makes it more difficult to change a contact angle or a contact perimeter length with respect to the inner surface of the nozzle hole of a meniscus than in the conventional example described in Patent Literature 1. It is thereby possible to restrain a change in ink-discharging performance.

Preferably, the entry length L of the portion entering into the ink discharge passage 20b of the water-repellent film entry portion 32b is not less than 0.1 μm and not more than 3 μm as already described. If the entry length L exceeds 3 μm, a difference will be made to the volume of a drop of ink discharged as microdroplets from the ink discharge port 20c by being pressurized, and therefore this is undesirable. If the entry length L is below 0.1 μm, there is a concern that the water-repellent film entry portion 32b will be adversely affected by the wiping mechanism, and therefore this is undesirable.

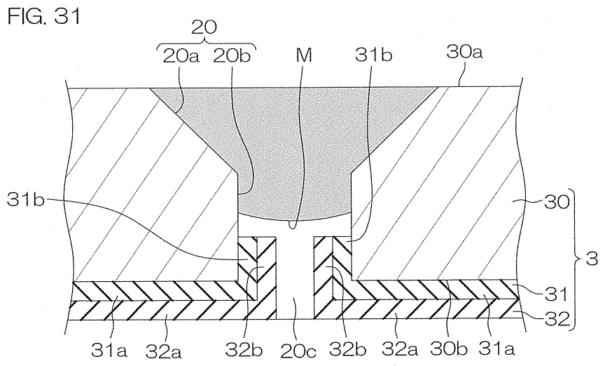

The fourth disclosure can be embodied in other modes although the preferred embodiment of the fourth disclosure has been described as above. The concave portion 20a may be formed in a circular cone shape whose cross section gradually becomes smaller from the first front surface 30a of the silicon substrate 30 toward the second front surface 30b as shown in FIG. 31 although the concave portion 20a is formed in a cylindrical shape in the present preferred embodiment described above. The ink discharge passage 20b has a cylindrical shape concentric with the concave portion 20a. FIG. 31 is a sectional view corresponding to the cutting plane of FIG. 20.

Also, the number of piezoelectric element columns (pressure chamber columns) provided at the actuator substrate 2 is two, only one piezoelectric element column (pressure chamber column) or three or more piezoelectric element columns may be provided.

Also, although in the preferred embodiment described above, the insulating film 15 is formed on a part of the front surface of the hydrogen barrier film 14, the insulating film 15 may instead be formed on the entirety of the front surface of the hydrogen barrier film 14.

Also, although in the preferred embodiment described above, the insulating film 15 is formed on a part of the front surface of the hydrogen barrier film 14, the insulating film 15 may be omitted.

Also, although in the preferred embodiment described above, PZT was cited as an example of the material of the piezoelectric film, a piezoelectric material besides this that is constituted of a metal oxide as represented by lead titanate (PbPO₃), potassium niobate (KNbO₃), lithium niobate (LiNbO₃), lithium tantalate (LiTaO₃), etc., may be applied instead.

Although the preferred embodiments of the present disclosure have been described in detail, these preferred embodiments are merely concrete examples used to clarify the technical contents of the present disclosure, and the present disclosure should not be understood by being limited to these concrete examples, and the scope of the present disclosure is limited solely by the appended claims.

This application corresponds to Japanese Patent Applications No. 2020-120873, No. 2020-120871, and No. 2020-120872 filed with the Japan Patent Office on Jul. 14, 2020, and corresponds to Japanese Patent Application No. 2020-157862 filed with the Japan Patent Office on Sep. 18, 2020, the entire disclosure of which is incorporated herein by reference.

### REFERENCE SIGNS LIST

1 Inkjet printing head
2 Actuator substrate
2a Front surface
2b Rear surface
3 Nozzle substrate
3a Nozzle hole
3b Ink discharge port
4 Protective substrate
4a Oxide film
5 Movable film formation layer
5A Movable film
6 Ink flow passage
7 Ink inflow portion
8 Pressure chamber
9 Ink outflow portion
10 Piezoelectric element
11 Lower electrode
11A Main electrode portion
11B Extension portion
12 Piezoelectric film
13 Upper electrode
21 First hydrogen barrier film
22 Second hydrogen barrier film
22a Outer peripheral end surface
23 Hydrogen barrier film
24 Interlayer insulating film
25 First interlayer insulating film
26 Second interlayer insulating film
27 Upper wiring
27A First upper contact portion
27B Second upper contact portion
27C Upper connection wiring portion
27D Upper pad portion
28 Lower wiring
28A Lower contact portion
28B Lower connection wiring portion
28C Lower pad portion
29 Dummy wiring
30 Passivation film
31 First liquid contact film
35 Opening
41 First upper contact hole
42 Second upper contact hole
43 Lower contact hole
44 Upper pad opening
45 Lower pad opening
50 Ink flow direction
51 Upper electrode pad
52 Lower electrode pad
53 First ink inflow passage
54 First ink outflow passage
61 Adhesion strengthening film
62 Adhesive agent layer
63 Adhesive layer
65 Second liquid contact film
66 Water-repellent film
71 Facing surface
72 Housing concave
73 Second ink inflow passage
74 Second ink outflow passage
75 First opening portion
76 Second opening portion
81 Lower electrode film
82 Piezoelectric material film
83 Upper electrode film
84 Wiring film
85 Metal film
86 Resist mask
87 Adhesive-agent material layer
100 Actuator wafer
100a Front surface
100b Rear surface
101 Functional-element forming region
102 Scribe region
103 Intended cutting line
110 Substrate assembly aggregate
130 Protective substrate aggregate
140 Nozzle wafer
150 Nozzle substrate aggregate
170 Inkjet printing head aggregate
SA Substrate assembly

1. An inkjet printing head comprising:
an actuator substrate that has an ink flow passage including a pressure chamber;
a movable film formation layer that is disposed on the pressure chamber and that includes a movable film defining a top surface portion of the pressure chamber;
a piezoelectric element that includes a lower electrode disposed on the movable film, a piezoelectric film formed on the lower electrode, and an upper electrode formed on the piezoelectric film;
a hydrogen barrier film that covers, in a front surface of the piezoelectric element, at least, entireties of side surfaces of the upper electrode, the piezoelectric film, and the lower electrode, at least a part of an upper surface of the upper electrode, and an upper surface of the lower electrode;
a first interlayer insulating film formed on a front surface other than an end surface of the hydrogen barrier film;
a second interlayer insulating film formed so as to cover the end surface of the hydrogen barrier film and the first interlayer insulating film; and
a wiring that is formed on the second interlayer insulating film and that is connected to the piezoelectric element.

2. The inkjet printing head according to claim 1, wherein the lower electrode includes a main electrode portion that contacts a lower surface of the piezoelectric film and an extension portion that extends from the main electrode portion to a region outside the piezoelectric film.

3. The inkjet printing head according to claim 1, wherein the wiring includes an upper wiring connected to the upper electrode and a lower wiring connected to the lower electrode.

4. The inkjet printing head according to claim 3, wherein an upper contact hole that exposes a part of the upper surface of the upper electrode is formed in the hydrogen barrier film formed on the upper surface of the upper electrode, the first interlayer insulating film, and the second interlayer insulating film, and an end portion of the upper wiring is connected to the upper electrode via the upper contact hole, and
a lower contact hole that exposes a part of the upper surface of the lower electrode is formed in the hydrogen barrier film formed on the upper surface of the lower electrode, the first interlayer insulating film, and the second interlayer insulating film, and an end portion of the lower wiring is connected to the lower electrode via the lower contact hole.

5. The inkjet printing head according to claim 1, wherein the hydrogen barrier film is also formed on a lower surface of the lower electrode.

6. The inkjet printing head according to claim 1, further comprising a passivation film that is formed on the second interlayer insulating film and that covers the wiring.

7. The inkjet printing head according to claim 1, wherein the top surface portion of the pressure chamber has a rectangular shape that is long in a predetermined first direction in a plan view as viewed from a normal direction with respect to a principal surface of the movable film, and
the upper electrode and the piezoelectric film each have a rectangular shape that is long in the first direction, and each have a peripheral edge receded further toward the interior of the pressure chamber than the movable film.

8. The inkjet printing head according to claim 7, wherein the lower electrode has a rectangular shape that is long in the first direction in the plan view, and
a length in a longitudinal direction of the lower electrode is longer than a length in a longitudinal direction of the piezoelectric film, and is shorter than a length in a longitudinal direction of the movable film, and
both end edges of the lower electrode are disposed at inner sides at intervals respectively from the respective corresponding end edges of the movable film, and
a length in a lateral direction of the lower electrode is longer than a length in a lateral direction of the piezoelectric film, and is longer than a length in a lateral direction of the movable film, and
both side edges of the lower electrode are disposed at outer sides at intervals respectively from the respective corresponding side edges of the movable film.

9. The inkjet printing head according to claim 7, wherein a plurality of the pressure chambers are provided, and
the piezoelectric element is provided for each of the pressure chambers, and
in the plan view, the actuator substrate has a plurality of pressure chamber columns formed therein at intervals in the first direction, with each pressure chamber column being constituted of a plurality of the pressure chambers provided at intervals in a second direction orthogonal to the first direction.

10. The inkjet printing head according to claim 1, further comprising:
a nozzle substrate that is bonded to a front surface of the actuator substrate at an opposite side of a front surface on the movable film side, that defines a bottom surface portion of the pressure chamber, and that has a nozzle hole in communication with the pressure chamber; and
a protective substrate that is disposed on a side opposite to the nozzle substrate with respect to the actuator substrate and that is bonded to the actuator substrate so as to cover the piezoelectric element,
wherein the protective substrate has a housing concave that is opened toward the actuator substrate and that houses the piezoelectric element and an ink passage in communication with the ink flow passage.

11. A method for manufacturing an inkjet printing head, the method comprising:
a step of forming a first hydrogen barrier material film, a lower electrode film, a piezoelectric material film, and an upper electrode film in this order on a substrate;
a step of patterning the upper electrode film and the piezoelectric material film to an upper electrode pattern to form an upper electrode and a piezoelectric film;
a step of patterning the lower electrode film and the first hydrogen barrier material film to a lower electrode pattern to form a lower electrode and a first hydrogen barrier film;
a step of forming a second hydrogen barrier material film that covers an entire surface on the substrate and then forming a first interlayer insulation material film on an entire surface on the second hydrogen barrier material film;
a step of patterning the second hydrogen barrier material film and the first interlayer insulation material film to a predetermined second hydrogen barrier film pattern to form a second hydrogen barrier film and a first interlayer insulating film;
a step of forming a second interlayer insulating film that covers the second hydrogen barrier film and the first interlayer insulating film on the substrate; and
a wiring formation step of forming an upper wiring one end of which is connected to the upper electrode and a lower wiring one end of which is connected to the lower electrode on the second interlayer insulating film.

12. The method for manufacturing an inkjet printing head according to claim 11, wherein the wiring formation step includes:
a step of forming an upper contact hole that exposes a part of an upper surface of the upper electrode and a lower contact hole that exposes a part of an upper surface of the lower electrode, the upper and lower contact holes penetrating continuously through the second interlayer insulating film, the first interlayer insulating film, and the second hydrogen barrier film;
a step of forming a wiring film on the second interlayer insulating film including an inside of the upper contact hole and the lower contact hole; and
a step of patterning the wiring film to form the upper wiring and the lower wiring.

13. The method for manufacturing an inkjet printing head according to claim 11, further comprising a step of, after completing the wiring formation step, forming a passivation film that covers the upper wiring and the lower wiring on a front surface of the second interlayer insulating film.
